(19) United States
(12) Patent Application Publication
(10) Pub. No.: US 2025/0189896 A1
(43) Pub. Date: Jun. 12, 2025

(54) RESIST UNDERLAYER FILM FORMATION COMPOSITION

(71) Applicant: NISSAN CHEMICAL CORPORATION, Tokyo (JP)

(72) Inventors: Yuki MITSUTAKE, Toyama-shi (JP); Hikaru TOKUNAGA, Toyama-shi (JP)

(73) Assignee: NISSAN CHEMICAL CORPORATION, Tokyo (JP)

(21) Appl. No.: 18/842,182

(22) PCT Filed: Feb. 6, 2023
(86) PCT No.: PCT/JP2023/003846

§ 371 Date: Aug. 28, 2024

(30) Foreign Application Priority Data
Feb. 28, 2022 (JP) 2022-030162
Jun. 9, 2022 (JP) 2022-093831

(51) Int. Cl. G03F 7/11; G03F 7/16; H01L 21/027; H01L 21/033; H01L 21/308

(52) U.S. Cl. CPC G03F 7/11; G03F 7/167; H01L 21/0275; H01L 21/0276; H01L 21/0337; H01L 21/3081; H01L 21/3086

(57) ABSTRACT

A resist underlayer film-forming composition for use in a lithography process for producing a semiconductor device wherein the composition contains a polymer having a unit structure of the following Formula (I) or Formula (I′):

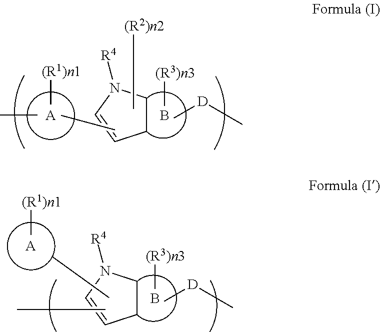

(each of n1, n2, and n3 is an integer of 0, rings A and are benzene or naphthalene rings, and D is a divalent organic group containing a structure of the following Formula (II) and/or (III):

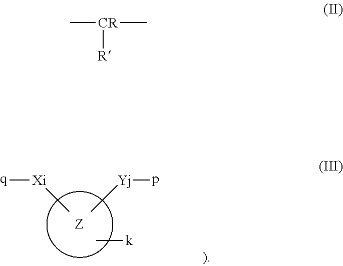

The semiconductor device is produced by forming an underlayer film on a semiconductor substrate from the resist underlayer film-forming composition; forming a hard mask on the formed film; forming another resist film on the hard mask; forming a resist pattern; etching the hard mask with the formed resist pattern; etching the underlayer film with the patterned hard mask; and processing the semiconductor substrate with the patterned underlayer film.

### TECHNICAL FIELD

The present invention relates to a resist underlayer film-forming composition for lithography that is effective in semiconductor substrate processing, a method of forming a resist pattern using the resist underlayer film-forming composition, and a method of producing a semiconductor device.

### BACKGROUND ART

In the production of semiconductor devices, fine processing by lithography using a photoresist composition has conventionally been performed. The fine processing is a processing method in which a thin film of a photoresist composition is formed on a substrate to be processed such as a silicon wafer, active ray such as ultraviolet ray is irradiated thereonto through a mask pattern on which a semiconductor device pattern is drawn, developing is performed, and a substrate to be processed such as a silicon wafer is etched using the obtained photoresist pattern as a protective film. However, in recent years, as semiconductor devices have become highly integrated, the wavelength of active ray used has been shortened from that of a KrF excimer laser (248 nm) to that of an ArF excimer laser (193 nm). Accordingly, the influence of disuse reflection of the active ray on the substrate or the influence of standing waves has become a serious problem, and it is known that forming a resist pattern having a desired shape is not possible. Therefore, methods of reducing the influence of standing waves by providing an anti-reflective coating (bottom anti-reflective coating, BARC) between a photoresist and a substrate to be processed and controlling the optical constant have been widely studied.

As the formation of finer resist patterns is further pursued, resolution problems or problems such as collapse of resist patterns after development occur, and there is a demand for thinner resists. Therefore, it is difficult to obtain a resist pattern film thickness sufficient for substrate processing, and a process in which not only the resist pattern but also the resist underlayer film formed between the resist and the semiconductor substrate to be processed can function as a mask during substrate processing has become required. This process is a lithography process in which at least two resist underlayer film layers are formed, and the resist underlayer film is used as a mask material. Examples of materials for forming the at least two layers include organic resins (for example, acrylic resins, novolac resins, polyester resins, polyether resins, PEEK resins, and maleimide resins), organic compounds (for example, amorphous carbon), silicone resins (for example, organopolysiloxane), and inorganic silicon compounds (for example, SiON, SiO₂, and SiN). When dry etching is performed using the pattern formed from the organic layer as a mask, the pattern is required to have an excellent etching resistance against an etching gas (for example, fluorocarbons and oxygen) although it depends on processing conditions. In addition, due to the diversity of semiconductor producing processes, there are demands for materials that not only have the above properties but also have favorable coating properties with a small film thickness difference for various layouts in stepped substrates (flattening properties), embedding properties for fine patterns, and sufficient curing properties under a nitrogen atmosphere.

Examples of polymers for the resist underlayer film include the following examples.

A resist underlayer film-forming composition using polyvinylcarbazole is exemplified (refer to Patent Document 1, Patent Document 2, and Patent Document 3).

A resist underlayer film-forming composition using a fluorene phenol novolac resin has been disclosed (for example, refer to Patent Document 4).

A resist underlayer film-forming composition using a fluorene naphthol novolac resin has been disclosed (for example, refer to Patent Document 5).

A resist underlayer film-forming composition containing a resin having a fluorene phenol and an arylalkylene as repeating units has been disclosed (for example, refer to Patent Document 6 and Patent Document 7).

### PRIOR ART DOCUMENTS

### Patent Documents

Patent Document 1: JP H02-293850 A
Patent Document 2: JP H01-154050 A
Patent Document 3: JP H02-22657 A
Patent Document 4: JP 2005-128509 A
Patent Document 5: JP 2007-199653 A
Patent Document 6: JP 2007-178974 A
Patent Document 7: U.S. Pat. No. 7,378,217

### SUMMARY OF THE INVENTION

### Problem to be Solved by the Invention

The present invention provides a resist underlayer film-forming composition for use in a lithography process for producing a semiconductor device. In addition, the present invention provides a resist underlayer film for lithography which does not cause intermixing with a resist layer, allows an excellent resist pattern to be obtained, exhibits an excellent etching resistance, has favorable flattening properties and embedding properties with respect to a finely processed substrate, is resistant to a solvent even in a nitrogen atmosphere, and exhibits sufficient curing properties. In addition, the present invention can also impart an ability to effectively adsorb reflected light from the substrate when irradiated light with a wavelength of 248 nm, 193 nm, 157 nm, or the like is used for fine processing. Further, the present invention provides a method of forming a resist pattern using the resist underlayer film-forming composition. Therefore, the present invention provides a resist underlayer film-forming composition for forming a resist underlayer film that also has a thermal resistance.

### Means for Solving the Problem

The present invention provides, as a first aspect, a resist underlayer film-forming composition containing a polymer having a unit structure of the following Formula (I) or Formula (I′):

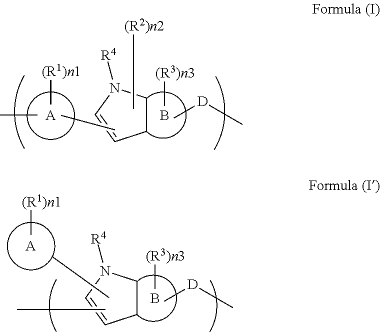

(in Formula (I) or Formula (I′), each of a ring A and a ring B is a C₆₋₈₀ aryl group which possibly contains a heteroatom and possibly has a ring structure containing an alkyl chain; each of R¹, R², and R³ is a substituent of hydrogen atoms in the ring, and is independently a halogen atom, a nitro group, a cyano group, an amino group, a hydroxyl group, a C₁₋₁₀ alkyl group, a C₁₋₁₀ alkoxy group, a C₂₋₁₀ alkenyl group, a C₂₋₁₀ alkynyl group, a C₆₋₈₀ aryl group, or any combination of these possibly containing an ether bond, a ketone bond, a sulfide bond, a sulfonyl group, a carboxyl group, or an ester bond; R⁴ is a C₂₋₁₀ alkynyl group; each of n1, n2, and n3 is an integer of 0 or more, and is an integer up to the possible maximum number of the substituents substituted on the ring; and D is a divalent organic group containing a structure of the following Formula (II) and/or (III):

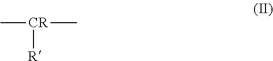

(in Formula (II), each of R and R′ is independently a hydrogen atom, a C₆₋₃₀ aromatic hydrocarbon group which possibly has a substituent, a C₃₋₃₀ heterocyclic group which possibly has a substituent, or a linear, branched, or cyclic alkyl group which possibly has a substituent and has a carbon atom number of 10 or less)

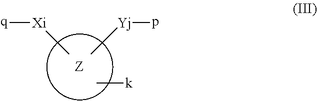

(in Formula (III), X and Y are possibly bonded to the same carbon atom on Z or possibly bonded to different carbon atoms, and each of X and Y is independently a C₆₋₃₀ aromatic hydrocarbon group which possibly has a substituent, a heteroatom, or a linear, branched, or cyclic alkyl group which possibly has a substituent and has a carbon atom number of 10 or less, Z is a 4- to 12-membered monocyclic, bicyclic, or tricyclic ring which is possibly condensed with an aromatic ring, possibly has a substituent, and possibly contains a heteroatom, each of i and j is independently 0 or 1, p, q, and k are the number of bonding hands, each of p and q is independently 0 or 1, p and q are not 0 at the same time, and k is an integer of 0 to 2)),

as a second aspect, the resist underlayer film-forming composition according to the first aspect, wherein the ring A and the ring B are benzene rings or naphthalene rings, n1+n2+n3 is 0 to 2, and R⁴ is a propargyl group,

as a third aspect, the resist underlayer film-forming composition according to the second aspect, wherein D is a divalent organic group containing a fluorene or fluorene derivative structure, and/or a C₆₋₃₀ aromatic hydrocarbon group which possibly has a substituent,

as a fourth aspect, the resist underlayer film-forming composition according to the first aspect, wherein the composition further contains a surfactant,

as a fifth aspect, the resist underlayer film-forming composition according to the first aspect, wherein the composition further contains a crosslinking agent,

as a sixth aspect, the resist underlayer film-forming composition according to the first aspect, wherein the composition further contains a surfactant and a crosslinking agent,

as a seventh aspect, the resist underlayer film-forming composition according to the first aspect, wherein the composition further contains an acid, and/or a salt thereof, and/or an acid generator,

as an eighth aspect, the resist underlayer film-forming composition according to the first aspect, wherein the composition further contains a surfactant, and an acid, and/or a salt thereof, and/or an acid generator,

as a ninth aspect, the resist underlayer film-forming composition according to the first aspect, wherein the composition further contains a crosslinking agent, and an acid, and/or a salt thereof, and/or an acid generator,

as a tenth aspect, the resist underlayer film-forming composition according to the first aspect, wherein the composition further contains a surfactant, a crosslinking agent, and an acid, and/or a salt thereof, and/or an acid generator,

as an eleventh aspect, a resist underlayer film obtained by applying the resist underlayer film-forming composition according to any one of the first aspect to tenth aspect onto a semiconductor substrate and baking the composition,

as a twelfth aspect, a method of producing a semiconductor device, comprising:

a step of forming an underlayer film on a semiconductor substrate from the resist underlayer film-forming composition according to any one of the first aspect to tenth aspect;

a step of forming a resist film on the formed underlayer film;

a step of forming a resist pattern by irradiating the formed resist film with light or an electron beam and developing the resist film;

a step of etching the underlayer film with the formed resist pattern; and

a step of processing the semiconductor substrate with the patterned underlayer film,

as a thirteenth aspect, the method of producing a semiconductor device according to the twelfth aspect, wherein the resist film is patterned by a nanoimprinting method or a self-assembled film,

as a fourteenth aspect, a method of producing a semiconductor device, comprising:

a step of forming an underlayer film on a semiconductor substrate from the resist underlayer film-forming composition according to any one of the first aspect to tenth aspect;

a step of forming a hard mask on the formed underlayer film;

a step of additionally forming a resist film on the formed hard mask;

a step of forming a resist pattern by irradiating the formed resist film with light or an electron beam and developing the resist film;

a step of etching the hard mask with the formed resist pattern;

a step of etching the underlayer film with the patterned hard mask;

a step of removing the hard mask; and

a step of processing the semiconductor substrate with the patterned underlayer film,

as a fifteenth aspect, the method of producing a semiconductor device according to the fourteenth aspect, wherein the resist film is patterned by a nanoimprinting method or a self-assembled film,

as a sixteenth aspect, the method of producing a semiconductor device according to the fifteenth aspect, further comprising:

a step of forming a vapor-deposited film (spacer) on the underlayer film from which the hard mask has been removed;

a step of processing the formed vapor-deposited film (spacer) by etching;

a step of removing the underlayer film; and

a step of processing the semiconductor substrate with the spacer, and

as a seventeenth aspect, the method of producing a semiconductor device according to the sixteenth aspect, wherein the step of removing the hard mask is performed by etching or with an alkaline chemical solution.

### Effects of the Invention

The resist underlayer film-forming composition of the present invention allows a favorable resist pattern shape to be formed without causing intermixing between the upper part of the resist underlayer film and the layer coated thereon.

The resist underlayer film-forming composition of the present invention can also impart an ability to efficiently reduce reflection from the substrate, and can also have the effect of an anti-reflective coating against exposure light.

The resist underlayer film-forming composition of the present invention can provide an excellent resist underlayer film which exhibits an excellent etching resistance, has favorable flattening properties and embedding properties with respect to a finely processed substrate, is resistant to a solvent even in a nitrogen atmosphere, and exhibits sufficient curing properties.

As resist patterns become finer, resists are made thinner in order to prevent the resist patterns from collapsing after development. For such thin-film resists, there is a process in which a resist pattern is transferred to an underlayer film in an etching process and a substrate is processed using the underlayer film as a mask. Further, there is a process in which a step where a resist pattern is transferred to an underlayer film in an etching process and additionally the above pattern is transferred to the underlying film below the above underlayer film with different gas compositions is repeated, and a substrate is finally processed. The resist underlayer film and the composition for forming the same of the present invention are effective in these processes, and when the resist underlayer film of the present invention is used to process a substrate, it has a sufficient etching resistance with respect to the processed substrate (for example, a silicon dioxide film (SiO₂ film), silicon nitride film (Si₃N₄ film), or polysilicon film on the substrate).

Here, the resist underlayer film of the present invention can be used as a planarization film having favorable flattening properties and embedding properties, a resist underlayer film, an anti-contamination film for a resist layer, and a film having a dry etch selectivity. Therefore, it is possible to easily and accurately form a resist pattern in a lithography process for semiconductor production.

There is a process in which a resist underlayer film is formed on a substrate using the resist underlayer film-forming composition according to the present invention, a hard mask is formed thereon, a resist film is formed thereon, a resist pattern is formed by exposure and development, the resist pattern is transferred to the hard mask, the resist pattern transferred to the hard mask is transferred to the resist underlayer film, and the resist underlayer film is used to process a semiconductor substrate. In this process, the hard mask may be applied using a coating type composition containing an organic polymer or an inorganic polymer and a solvent or by vacuum deposition of an inorganic substance. In vacuum deposition of an inorganic substance (for example, silicon oxynitride), vapor-deposited materials accumulate on the surface of the resist underlayer film, and the temperature of the surface of the resist underlayer film rises to around 400° C. in this case. Since the polymer used in the present invention is a polymer having a unit structure of Formula (I) or Formula (I′), it has a very high thermal resistance, and does not undergo thermal degradation even if vapor-deposited materials accumulate.

### MODES FOR CARRYING OUT THE INVENTION

The present invention relates to a resist underlayer film-forming composition containing a polymer having a unit structure of the following Formula (I) or Formula (I′).

In the present invention, the resist underlayer film-forming composition for lithography contains the polymer and a solvent. Here, the composition can contain a crosslinking agent and an acid, and can contain additives such as an acid generator and a surfactant as necessary. The solid content of the composition is 0.1 to 70% by mass or 0.1 to 60% by mass. The solid content is the content of all components excluding the solvent from the resist underlayer film-forming composition. The solid content may contain the polymer in a proportion of 1 to 100% by mass, 1 to 99.9% by mass, 50 to 99.9% by mass, 50 to 95% by mass, or 50 to 90% by mass.

The polymer used in the present invention has a weight average molecular weight of 600 to 1,000,000 or 600 to 200,000.

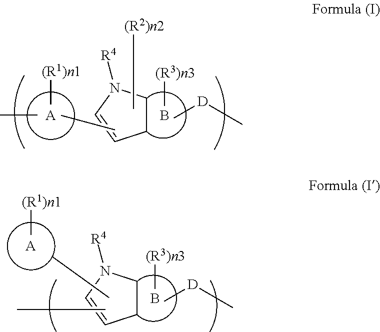

In Formula (I) or Formula (I′), each of a ring A and a ring B is a C₆₋₈₀ aryl group which possibly contains a heteroatom and possibly has a ring structure containing an alkyl chain. Each of R¹, R², and R³ is a substituent of hydrogen atoms in the ring, and is independently a halogen atom, a nitro group, a cyano group, an amino group, a hydroxyl group, a C₁₋₁₀ alkyl group, a C₁₋₁₀ alkoxy group, a C₂₋₁₀ alkenyl group, a C₂₋₁₀ alkynyl group, a C₆₋₈₀ aryl group, or any combination of these possibly containing an ether bond, a ketone bond, a sulfide bond, a sulfonyl group, a carboxyl group, or an ester bond. R⁴ is a C₂₋₁₀ alkynyl group. Each of n1, n2, and n3 is an integer of 0 or more, and is an integer up to the possible maximum number of the substituents substituted on the ring. D is a divalent organic group containing a structure of the following Formula (II) and/or (III).

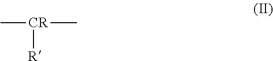

(in Formula (II), each of R and R′ is independently a hydrogen atom, a C₆₋₃₀ aromatic hydrocarbon group which possibly has a substituent, a C₃₋₃₀ heterocyclic group which possibly has a substituent, or a linear, branched, or cyclic alkyl group which possibly has a substituent and has a carbon atom number of 10 or less)

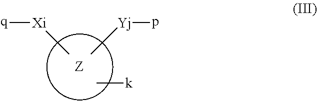

(in Formula (III), X and Y are possibly bonded to the same carbon atom on Z or possibly bonded to different carbon atoms, and each of X and Y is independently a C₆₋₃₀ aromatic hydrocarbon group which possibly has a substituent, a heteroatom, or a linear, branched, or cyclic alkyl group which possibly has a substituent and has a carbon atom number of 10 or less, Z is a 4- to 12-membered monocyclic, bicyclic, or tricyclic ring which is possibly condensed with an aromatic ring, possibly has a substituent, and possibly contains a heteroatom, each of i and j is independently 0 or 1, p, q, and k are the number of bonding hands, each of p and q is independently 0 or 1, p and q are not 0 at the same time, and k is an integer of 0 to 2).

In the definitions of R¹, R², and R³ in Formula (I) or Formula (I′), examples of C₁₋₁₀ alkyl groups include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group and 2-ethyl-3-methyl-cyclopropyl group.

Examples of C₂₋₁₀ alkenyl groups include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group and 3-cyclohexenyl group.

Examples of C₂₋₁₀ alkynyl groups include the following structures.

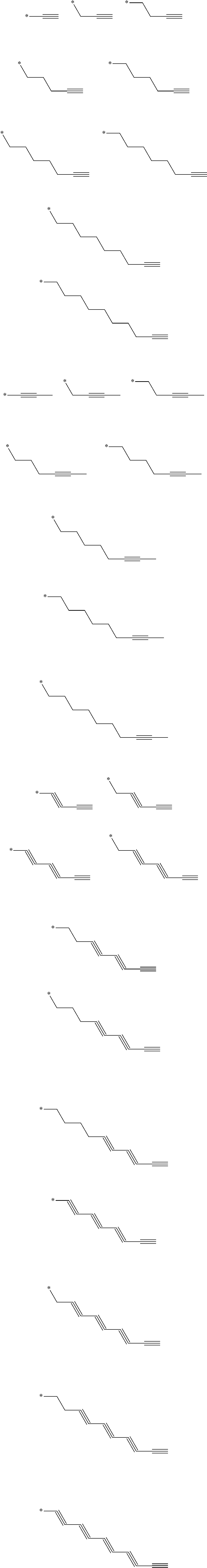

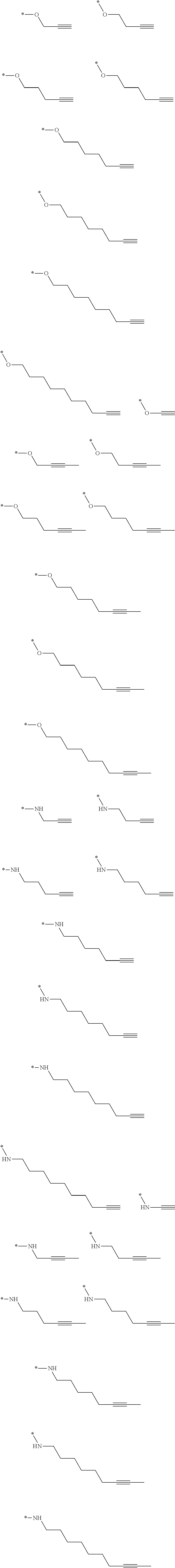

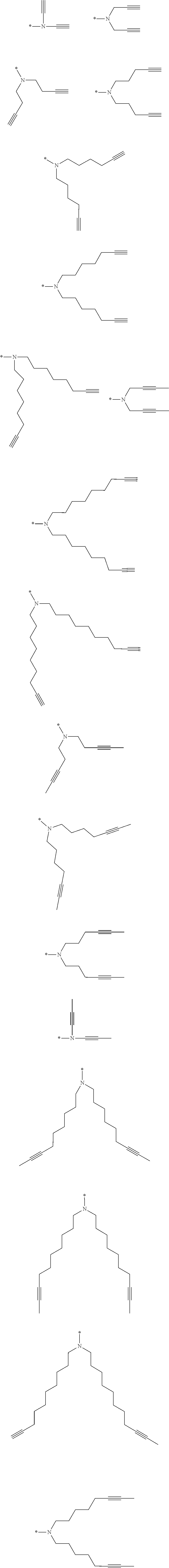

Examples of C₁₋₁₀ alkoxy groups include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group.

Examples of C₆₋₈₀ aryl groups include phenyl group, o-methyl phenyl group, m-methyl phenyl group, p-methyl phenyl group, o-chlorophenyl group, m-chlorophenyl group, p-chlorophenyl group, o-fluorophenyl group, p-fluorophenyl group, o-methoxyphenyl group, p-methoxyphenyl group, p-nitrophenyl group, p-cyanophenyl group, α-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group, 9-phenanthryl group, and 1-pyrenyl group.

The heterocyclic group is preferably an organic group composed of a 5- to 6-membered heterocyclic ring containing nitrogen, sulfur, or oxygen, and examples thereof include pyrrole group, furan group, thiophene group, imidazole group, oxazole group, thiazole group, pyrazole group, isooxazole group, isothiazole group, and pyridine group.

Examples of substituents include a halogen atom, a saturated or unsaturated linear, branched or cyclic hydrocarbon group which may contain a heteroatom, a hydroxyl group, an amino group, a carboxyl group, a cyano group, a nitro group, an alkoxyl group, an ester group, an amide group, a sulfonyl group, a sulfide group, an ether group, and an aryl group, but are not limited thereto as long as the effects of the present invention are not impaired.

In Formula (I) or Formula (I′), R⁴ has, for example, the following structures.

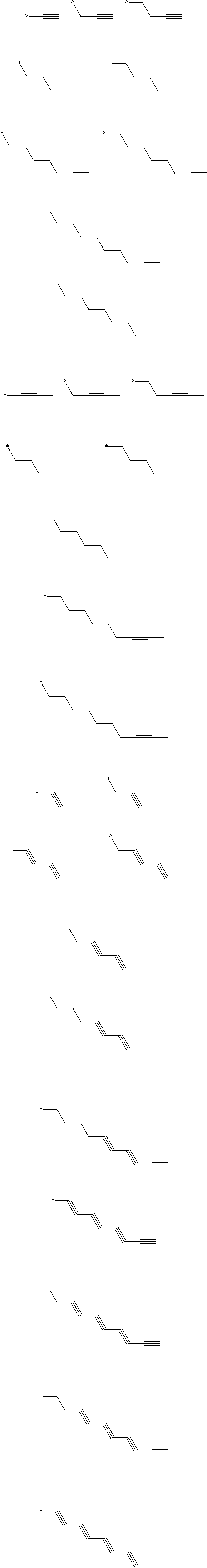

As the unit structure of Formula (I) or Formula (I′), for example, a unit structure in which a ring A and a ring B are benzene rings or naphthalene rings, n1+n2+n3 is 0 to 2, and R⁴ is preferably a propargyl group can be used.

In the definitions of R, and R′ in Formula (II), “substituent” and “heterocyclic group” are as described above.

The C₆₋₃₀ aromatic hydrocarbon group is a group derived by removing one or two hydrogen atoms from an aromatic hydrocarbon compound, and such an aromatic hydrocarbon compound may be any of benzene, a ring-condensed aromatic hydrocarbon compound, and a ring-linked aromatic hydrocarbon compound.

Specific examples of groups derived from benzene include benzene-1,2-diyl group, benzene-1,3-diyl group, benzene-1,4-diyl group, benzene-1,2,3-triyl group, benzene-1,2,4-triyl group, and benzene-1,3,5-triyl group.

Specific examples of groups derived from ring-condensed aromatic hydrocarbon compounds include, but are not limited to, groups derived from ring-condensed aromatic hydrocarbon compounds such as naphthalene-1,2-diyl group, naphthalene-1,3-diyl group, naphthalene-1,4-diyl group, naphthalene-1,5-diyl group, naphthalene-1,6-diyl group, naphthalene-1,7-diyl group, naphthalene-1,8-diyl group, naphthalene-2,3-diyl group, naphthalene-2,6-diyl group, naphthalene-2,7-diyl group, anthracene-1,2-diyl group, anthracene-1,3-diyl group, anthracene-1,4-diyl group, anthracene-1,5-diyl group, anthracene-1,6-diyl group, anthracene-1,7-diyl group, anthracene-1,8-diyl group, anthracene-1,9-diyl group, anthracene-1,10-diyl group, anthracene-2,3-diyl group, anthracene-2,6-diyl group, anthracene-2,7-diyl group, anthracene-2,9-diyl group, anthracene-2,10-diyl group, and anthracene-9,10-diyl group, and groups derived from ring-condensed aromatic hydrocarbon compounds such as naphthalene-1,2,3-triyl group, naphthalene-1,2,4-triyl group, naphthalene-1,2,5-triyl group, naphthalene-1,2,6-triyl group, naphthalene-1,2,7-triyl group, naphthalene-1,2,8-triyl group, naphthalene-1,3,5-triyl group, naphthalene-1,3,6-triyl group, naphthalene-1,3,7-triyl group, naphthalene-1,3,8-triyl group, naphthalene-1,4,5-triyl group, naphthalene-1,4,6-triyl group, naphthalene-1,4,7-triyl group, naphthalene-1,4,8-triyl group, naphthalene-2,3,5-triyl group, naphthalene-2,3,6-triyl group, naphthalene-2,3,7-triyl group, and naphthalene-2,3,8-triyl group.

Specific examples of groups derived from ring-linked aromatic hydrocarbon compounds include, but are not limited to, groups derived from ring-linked aromatic hydrocarbon compounds such as biphenyl-2,2′-diyl group, biphenyl-2,3′-diyl group, biphenyl-2,4′-diyl group, biphenyl-3,3′-diyl group, biphenyl-3,4′-diyl group, biphenyl-4,4′-diyl group, p-terphenyl-2,2′-diyl group, p-terphenyl-2,3′-diyl group, p-terphenyl-2,2″-diyl group, p-terphenyl-2,3″-diyl group, p-terphenyl-2,4″-diyl group, p-terphenyl-3,2′-diyl group, p-terphenyl-3,3′-diyl group, p-terphenyl-3,3″-diyl group, p-terphenyl-3,4″-diyl group, p-terphenyl-4,4″-diyl group, p-terphenyl-2′,3′-diyl group, p-terphenyl-2′,5′-diyl group, and p-terphenyl-2′,6′-diyl group, and groups derived from ring-linked aromatic hydrocarbon compounds such as biphenyl-2,3,2′-triyl group, biphenyl-2,3,3′-triyl group, biphenyl-2,3,4′-triyl group, biphenyl-2,4,2′-triyl group, biphenyl-2,4,3′-triyl group, biphenyl-2,4,4′-triyl group, biphenyl-2,5,2′-triyl group, biphenyl-2,5,3′-triyl group, biphenyl-2,5,4′-triyl group, biphenyl-2,6,2′-triyl group, biphenyl-2,6,3′-triyl group, biphenyl-2,6,4′-triyl group, biphenyl-3,4,2′-triyl group, biphenyl-3,4,3′-triyl group, biphenyl-3,4,4′-triyl group, biphenyl-3,5,2′-triyl group, biphenyl-3,5,3′-triyl group, and biphenyl-3,5,4′-triyl group.

In the definitions of R, and R′ in Formula (II), examples of “alkyl group” include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, 2-ethyl-3-methyl-cyclopropyl group, n-heptyl group, n-octyl group, n-nonyl group, and n-decyl group.

Preferably, each of R, and R′ is independently phenyl, naphthalenyl, anthracenyl, phenanthrenyl, naphthacenyl, or pyrenyl.

Some specific examples of the divalent organic group containing the structure of Formula (II) are as follows. One of two * marks indicates a bonding site with a pentazole group. Needless to say, structures including the exemplified structures as a part of the whole may be used.

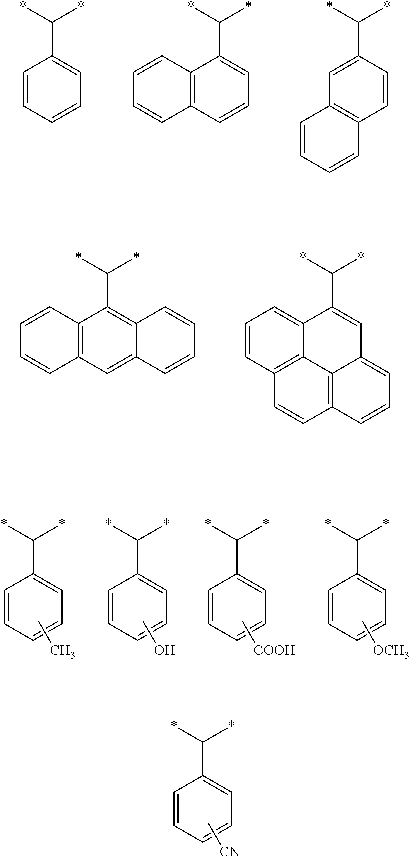

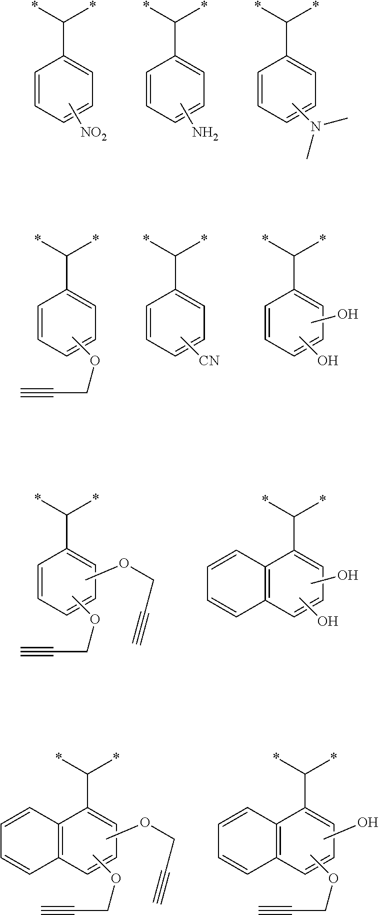

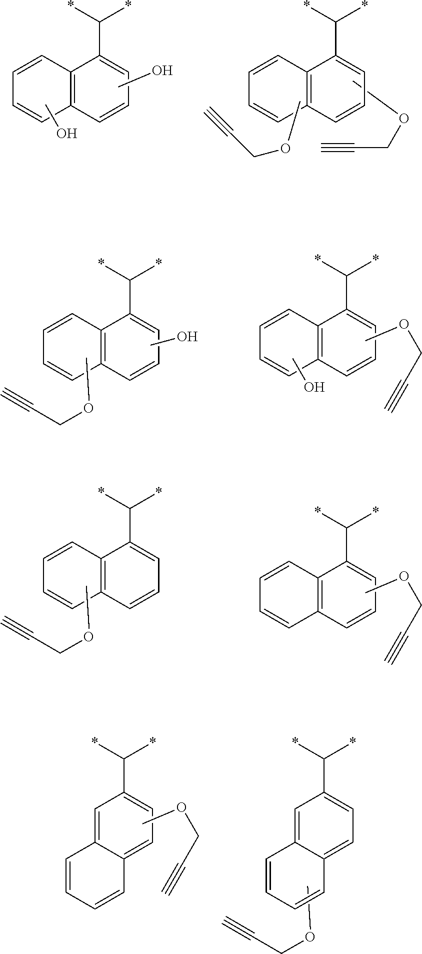

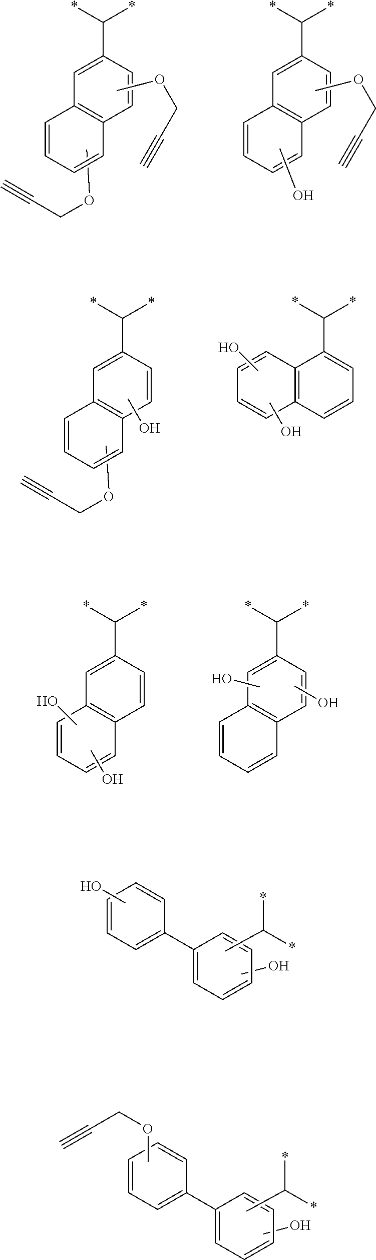

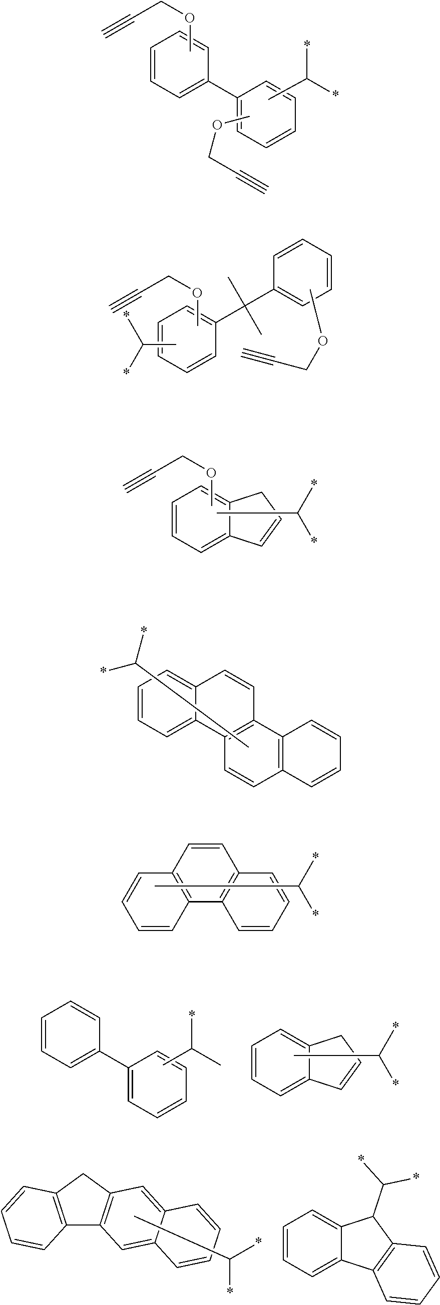

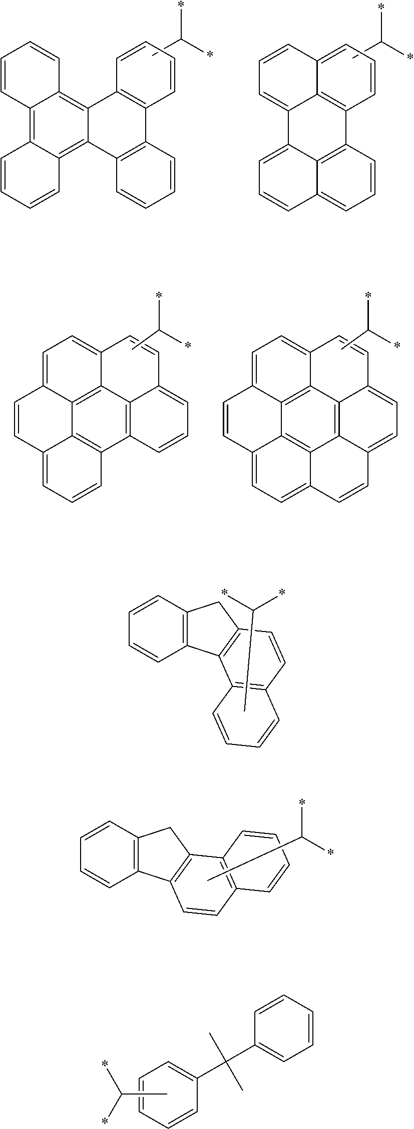

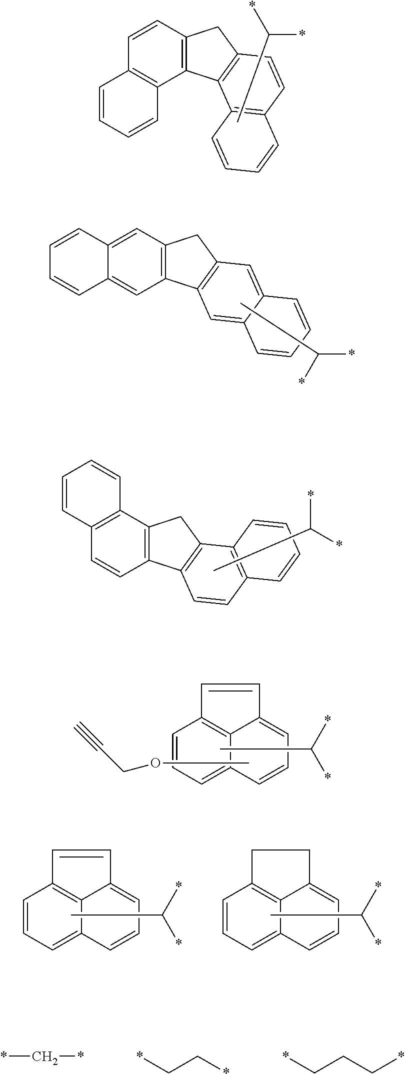

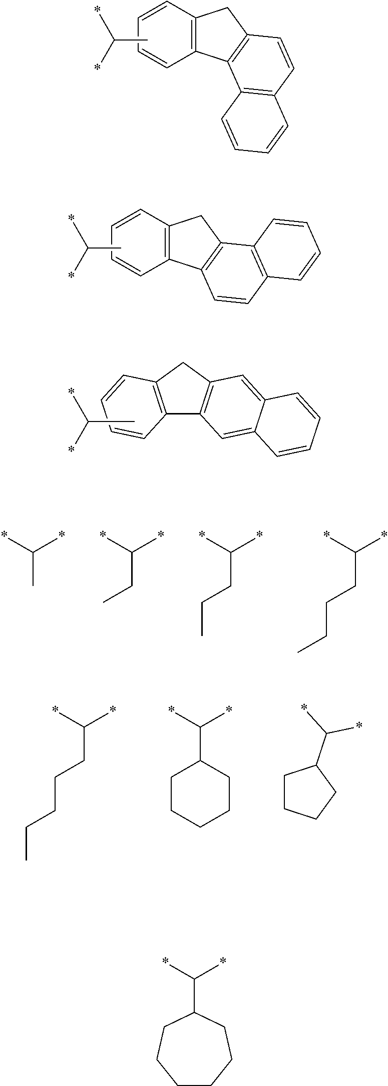

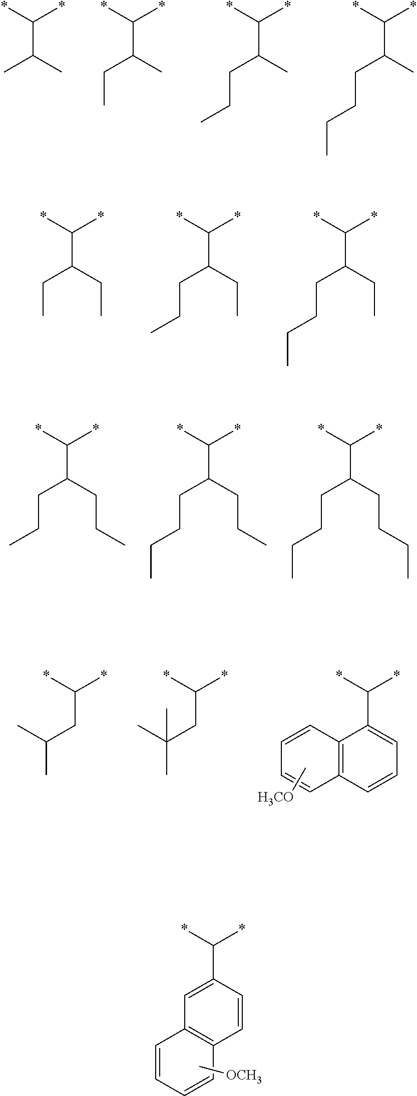

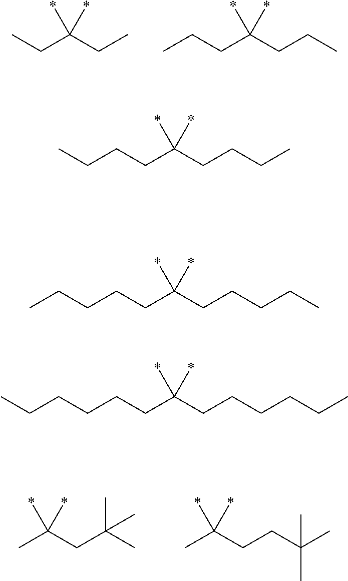

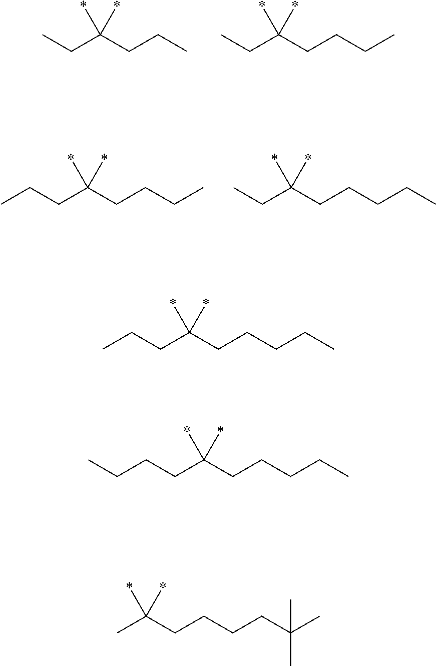

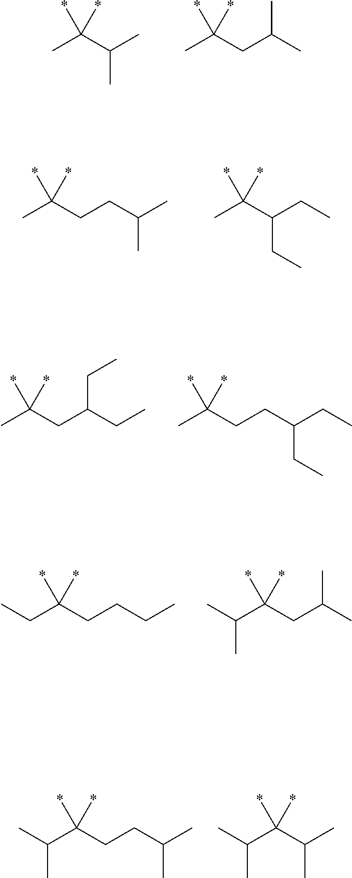

In Formula (III), X and Y are possibly bonded to the same carbon atom on Z or possibly bonded to different carbon atoms, and each of X and Y is independently a C₆₋₃₀ aromatic hydrocarbon group which possibly has a substituent, a heteroatom, or a linear, branched, or cyclic alkyl group which possibly has a substituent and has a carbon atom number of 10 or less, Z is a 4- to 12-membered monocyclic, bicyclic, or tricyclic ring which is possibly condensed with an aromatic ring, possibly has a substituent, and possibly contains a heteroatom, each of i and j is independently 0 or 1, p, q, and k are the number of bonding hands, each of p and q is independently 0 or 1, p and q are not 0 at the same time, and k is an integer of 0 to 2. The aromatic hydrocarbon group is divalent. “Aromatic hydrocarbon” is as described above.

In Formula (III), examples of rings in which Z is a 4- to 12-membered monocyclic ring include cyclopropane, cyclobutane, cyclopentane, cyclohexane, and cyclohexene, examples of bicyclic rings include bicyclopentane, bicyclooctane, and bicycloheptene, and examples of tricyclic rings include tricyclooctane, tricyclononane, and tricyclodecane.

Examples of aromatic rings which may be condensed to a monocyclic, bicyclic, or tricyclic ring include a benzene ring, a naphthalene ring, an anthracene ring, and a pyrene ring. These rings may be condensed to one, two or more rings.

Some specific examples of the divalent organic group containing the structure of Formula (III) are as follows. A bonding site with the group B is not particularly limited. Needless to say, structures including the exemplified structures as a part of the whole may be used.

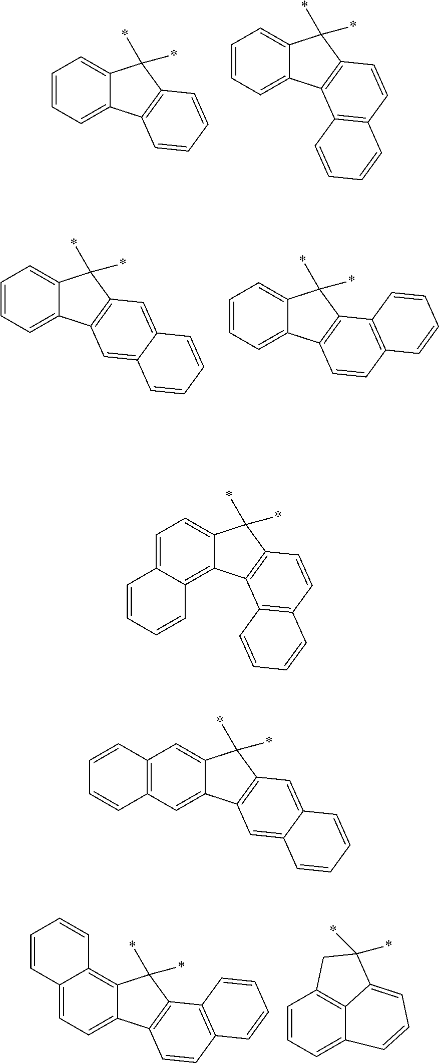

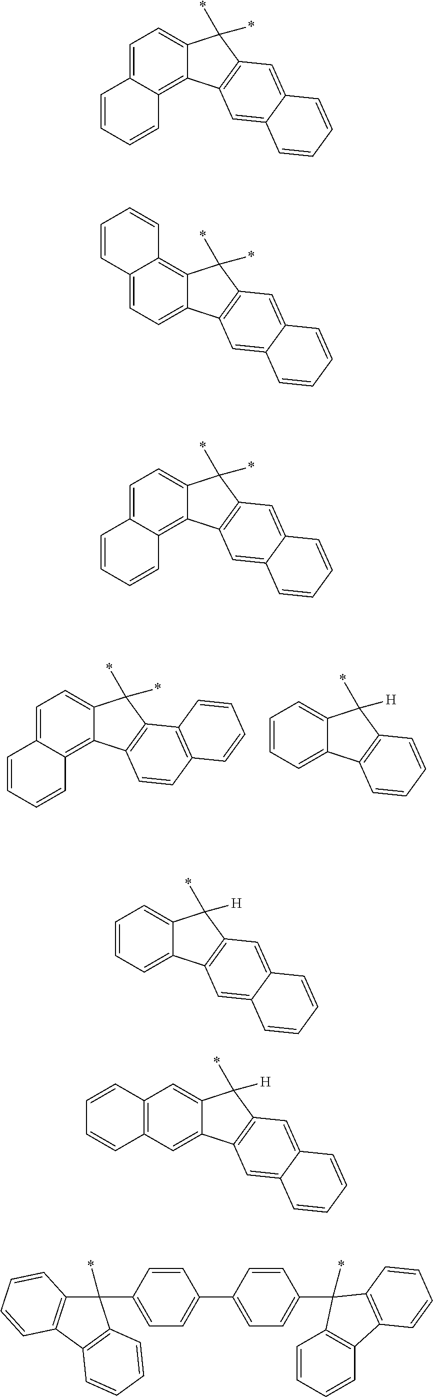

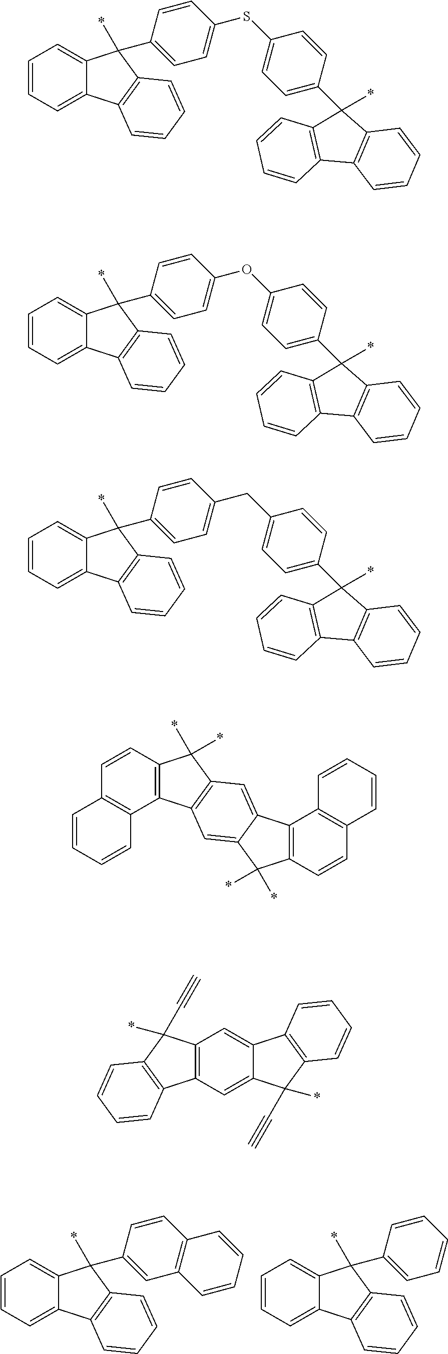

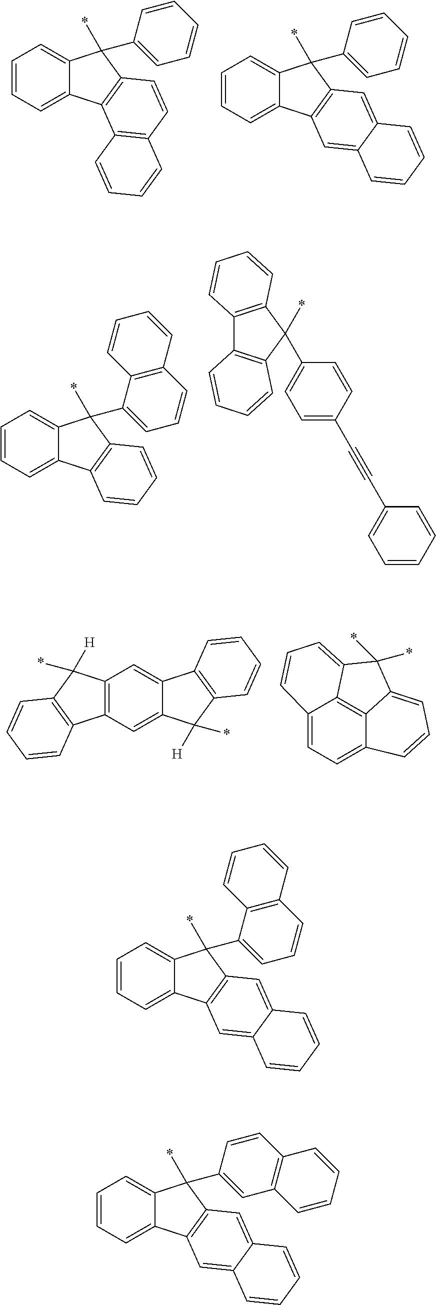

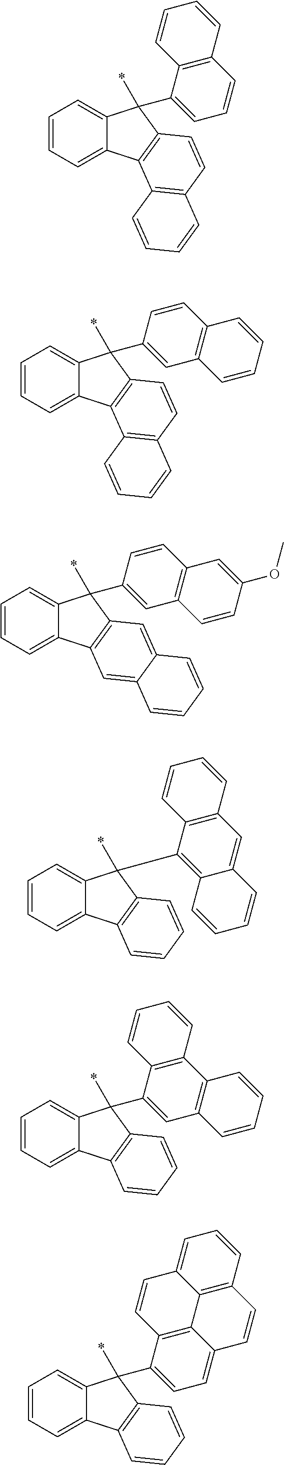

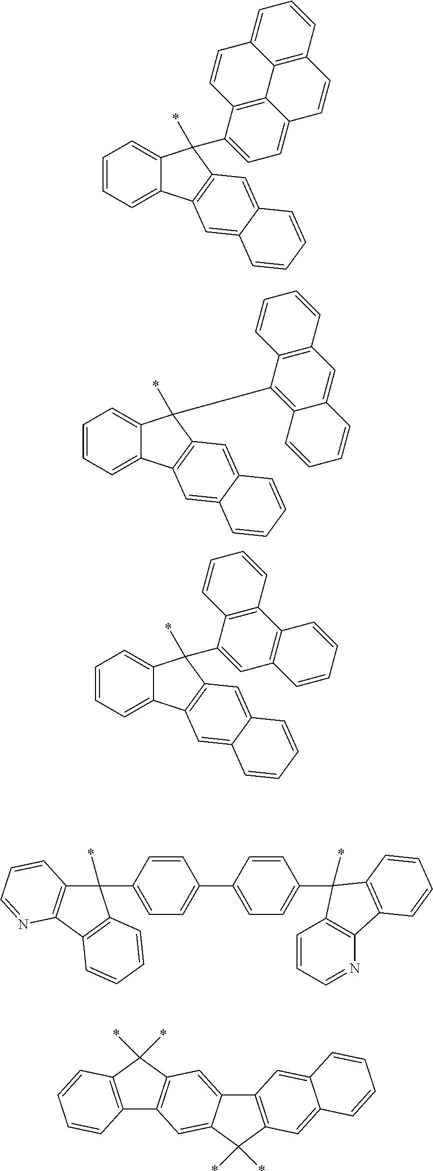

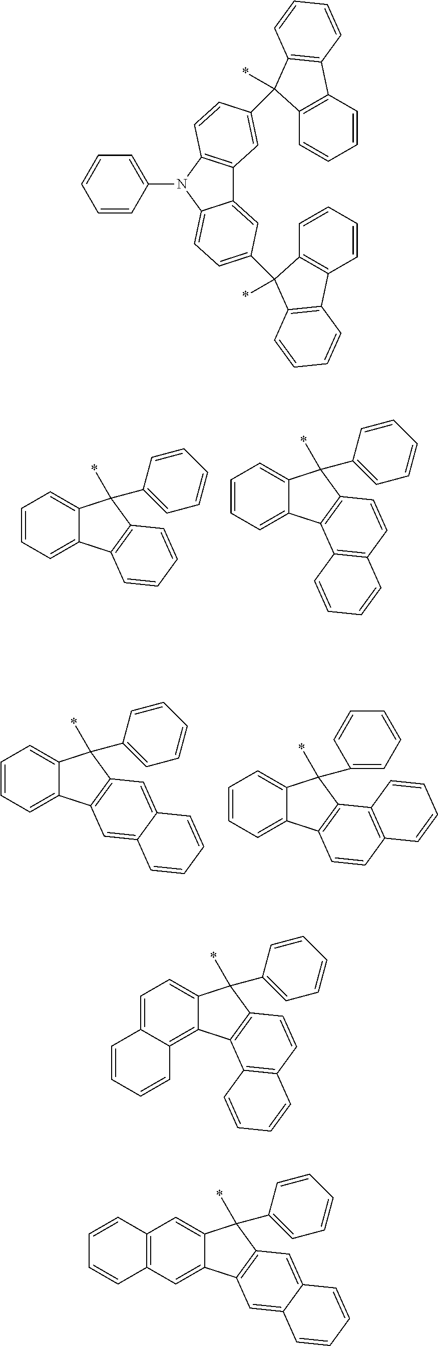

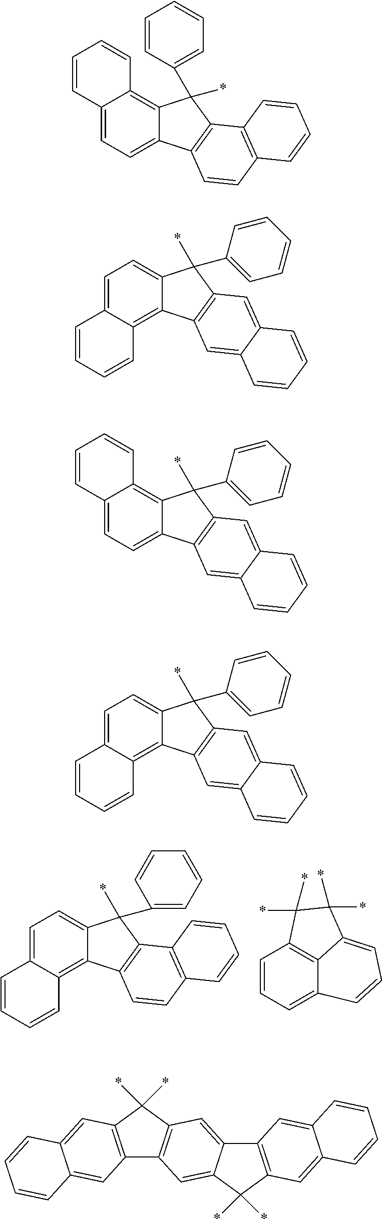

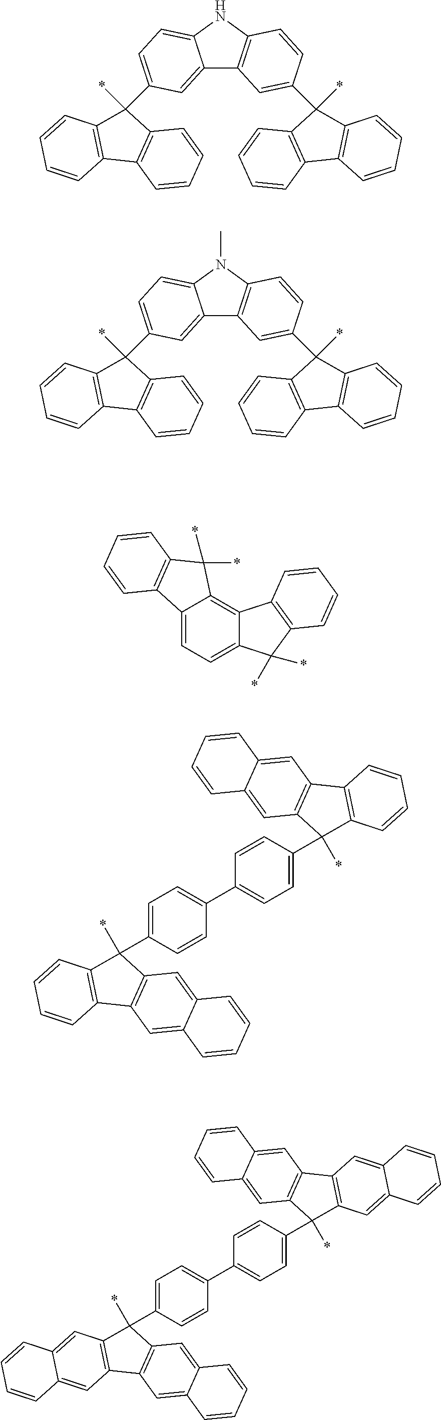 [SMILES: *C1(c2ccc3[nH]c4ccc(C5(*)c6ccccc6-c6ccccc65)cc4c3c2)c2ccccc2-c2ccccc21 ; *C1(c2ccc3c(c2)c2cc(C4(*)c5ccccc5-c5ccccc54)ccc2n3C)c2ccccc2-c2ccccc21 ; *C1(*)c2ccccc2-c2c1ccc1c2C(*)(*)c2ccccc2-1 ; *C1(c2ccc(-c3ccc(C4(*)c5ccccc5-c5cc6ccccc6cc54)cc3)cc2)c2ccccc2-c2cc3ccccc3cc21 ; *C1(c2ccc(-c3ccc(C4(*)c5cc6ccccc6cc5-c5cc6ccccc6cc54)cc3)cc2)c2cc3ccccc3cc2-c2cc3ccccc3cc21]

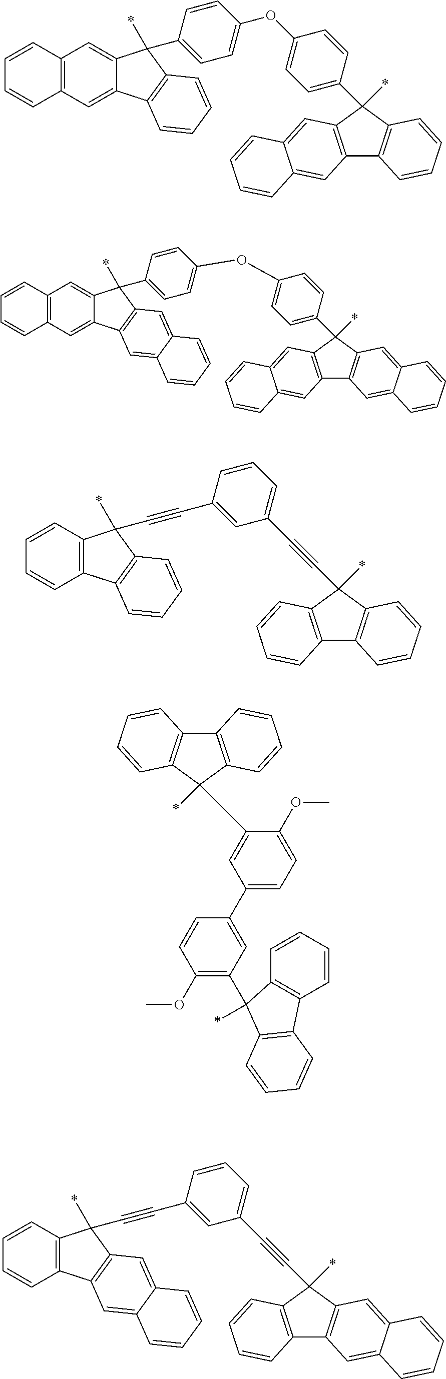 [SMILES: *C1(c2ccc(Oc3ccc(C4(*)c5ccccc5-c5cc6ccccc6cc54)cc3)cc2)c2ccccc2-c2cc3ccccc3cc21 ; *C1(c2ccc(Oc3ccc(C4(*)c5cc6ccccc6cc5-c5cc6ccccc6cc54)cc3)cc2)c2cc3ccccc3cc2-c2cc3ccccc3cc21 ; *C1(C#Cc2cccc(C#CC3(*)c4ccccc4-c4ccccc43)c2)c2ccccc2-c2ccccc21 ; *C1(c2cc(-c3ccc(OC)c(C4(*)c5ccccc5-c5ccccc54)c3)ccc2OC)c2ccccc2-c2ccccc21 ; *C1(C#Cc2cccc(C#CC3(*)c4ccccc4-c4cc5ccccc5cc43)c2)c2ccccc2-c2cc3ccccc3cc21]

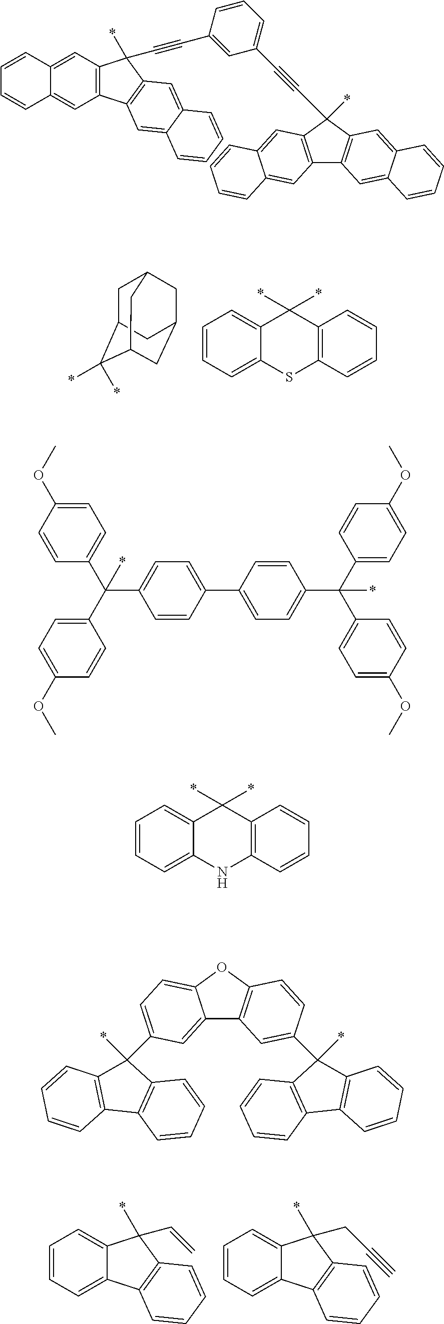

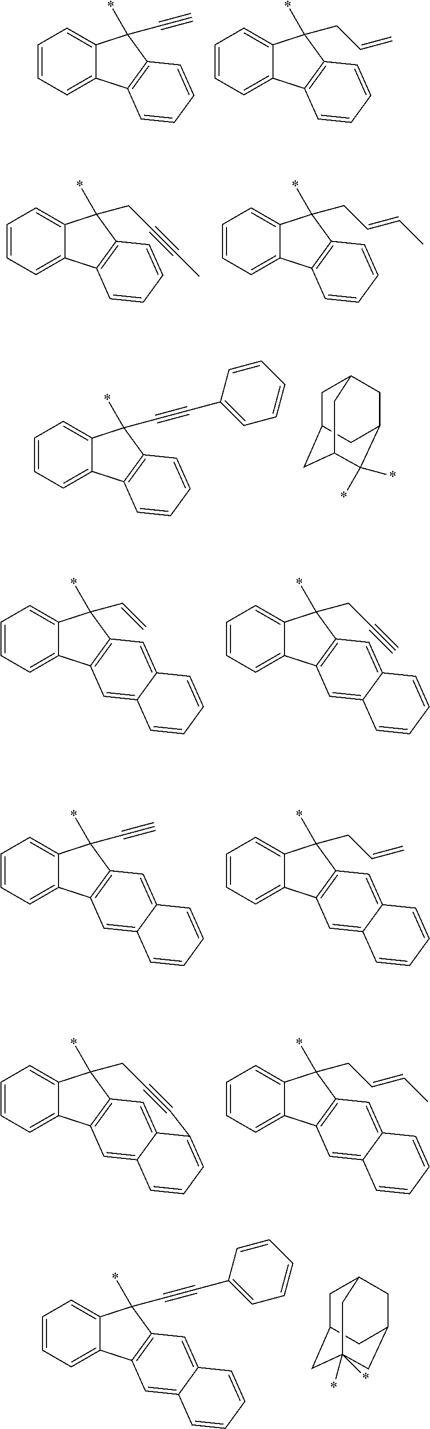

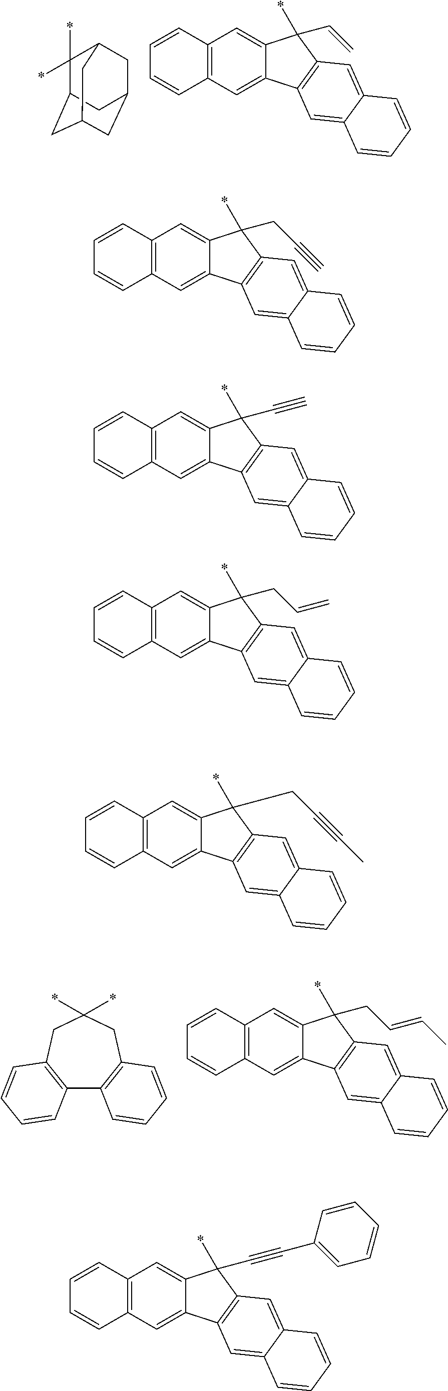

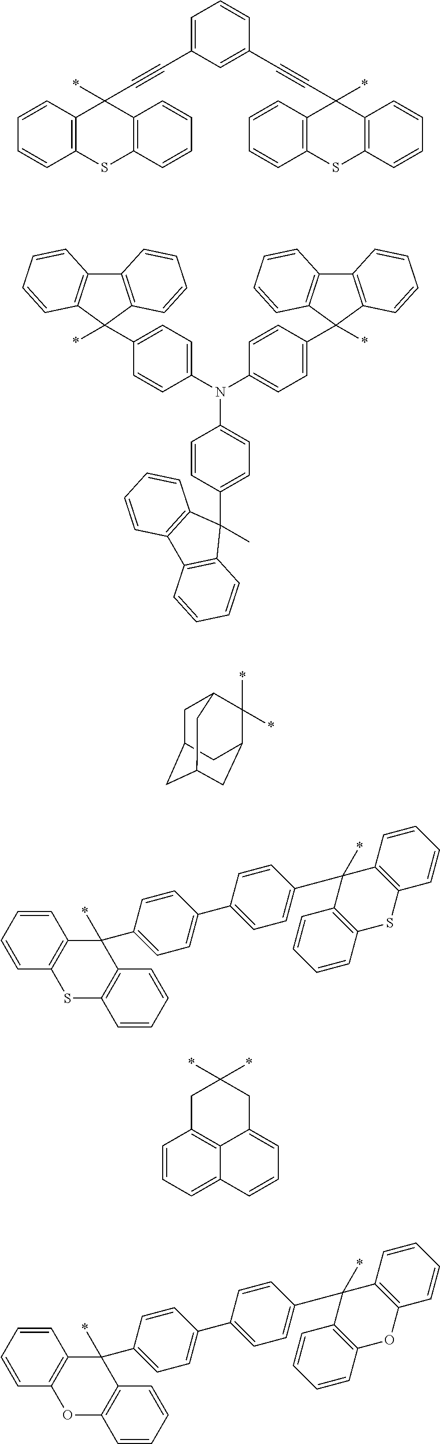 [SMILES: *C1(C#Cc2cccc(C#CC3(*)c4ccccc4Sc4ccccc43)c2)c2ccccc2Sc2ccccc21 ; *C1(c2ccc(N(c3ccc(C4(*)c5ccccc5-c5ccccc54)cc3)c3ccc(C4(C)c5ccccc5-c5ccccc54)cc3)cc2)c2ccccc2-c2ccccc21 ; *C1(*)C2CC3CC(C2)CC1C3 ; *C1(c2ccc(-c3ccc(C4(*)c5ccccc5Sc5ccccc54)cc3)cc2)c2ccccc2Sc2ccccc21 ; *C1(*)Cc2cccc3cccc(c23)C1 ; *C1(c2ccc(-c3ccc(C4(*)c5ccccc5Oc5ccccc54)cc3)cc2)c2ccccc2Oc2ccccc21]

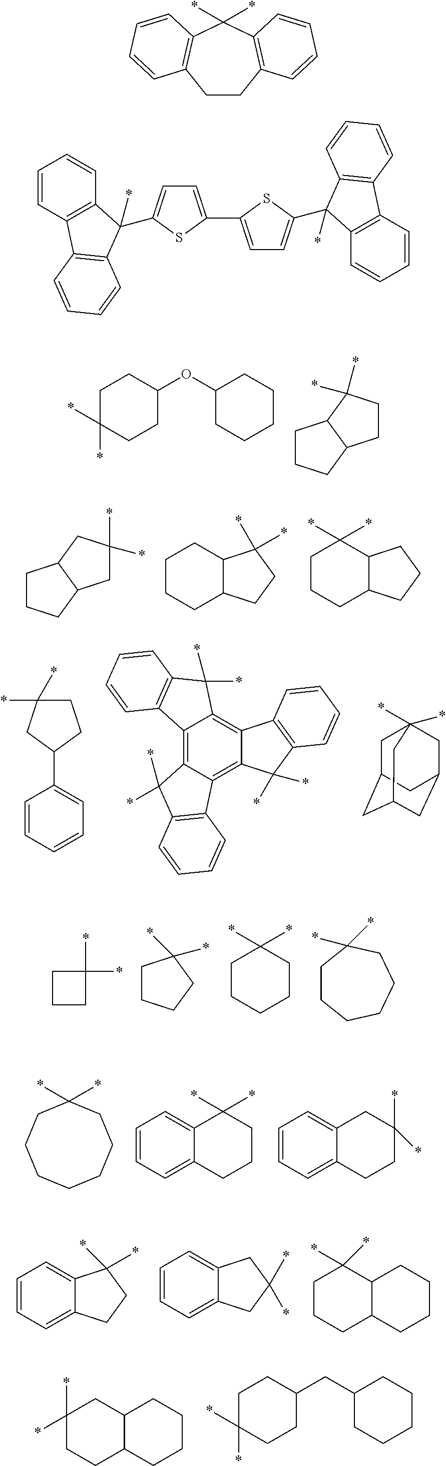

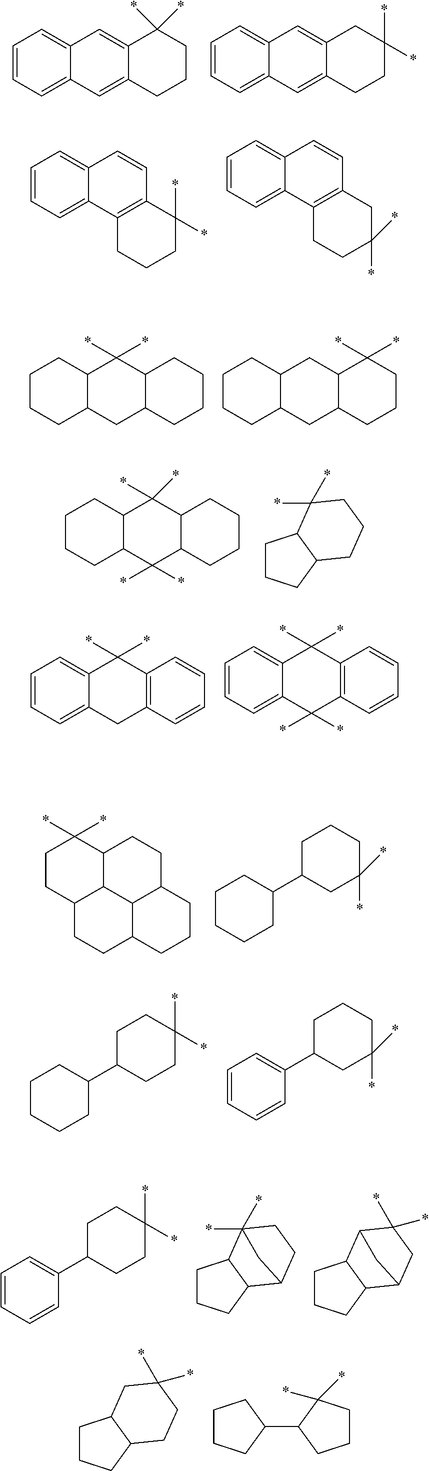

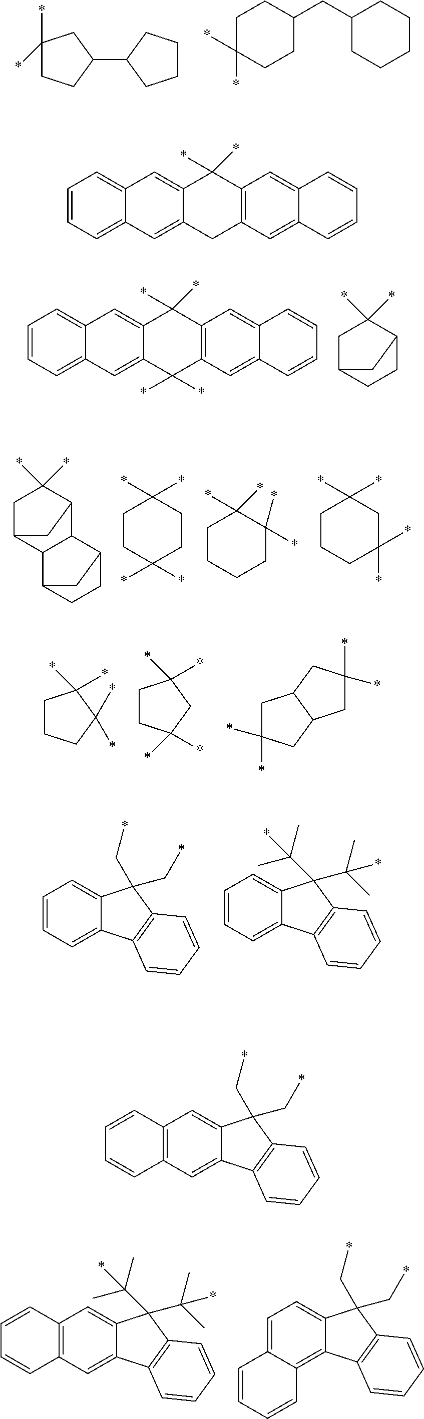

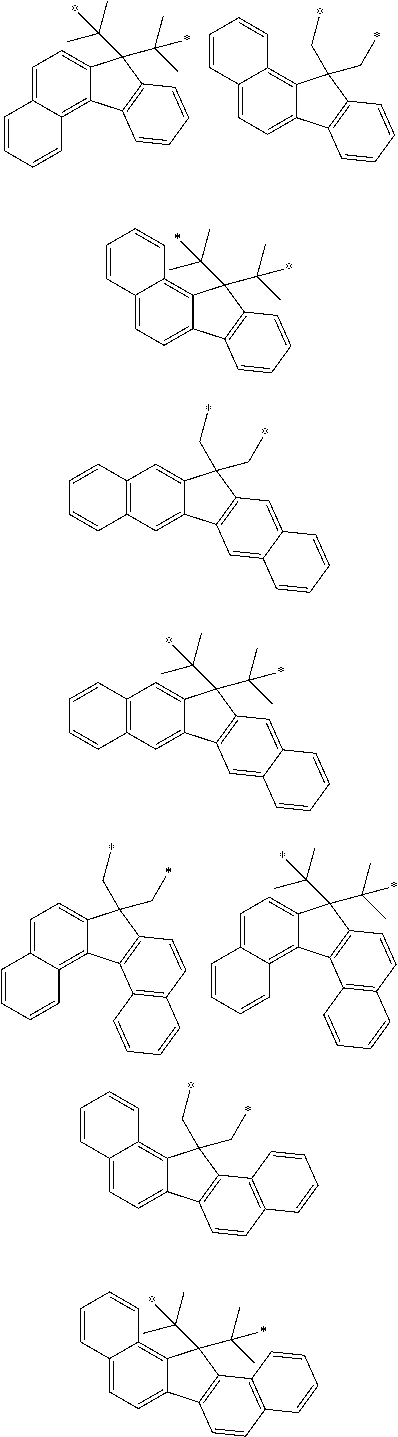

Regarding D in Formula (I) or Formula (I′), D is preferably a divalent organic group containing a fluorene or fluorene derivative structure, and/or a C₆₋₃₀ aromatic hydrocarbon group which possibly has a substituent. Here, the fluorene derivative structure refers to a structure having a fluorene skeleton.

D in Formula (I) or Formula (I′) has, for example, the following structure as a part of D.

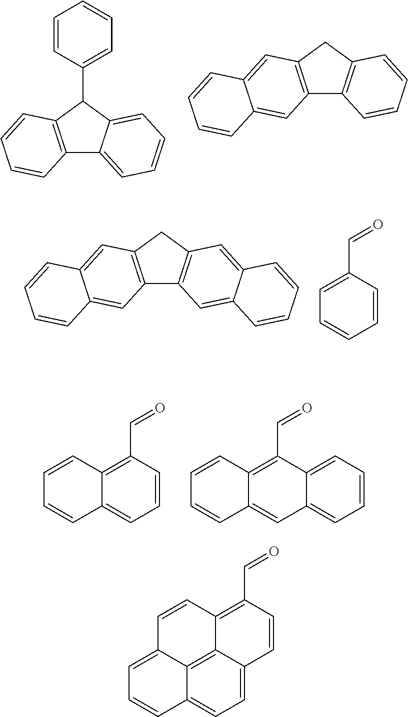

Examples of indole derivatives in Formula (I) or Formula (I′) (moieties other than D in Formula (I) or Formula (I′)) include the following examples, but are not limited to the following examples.

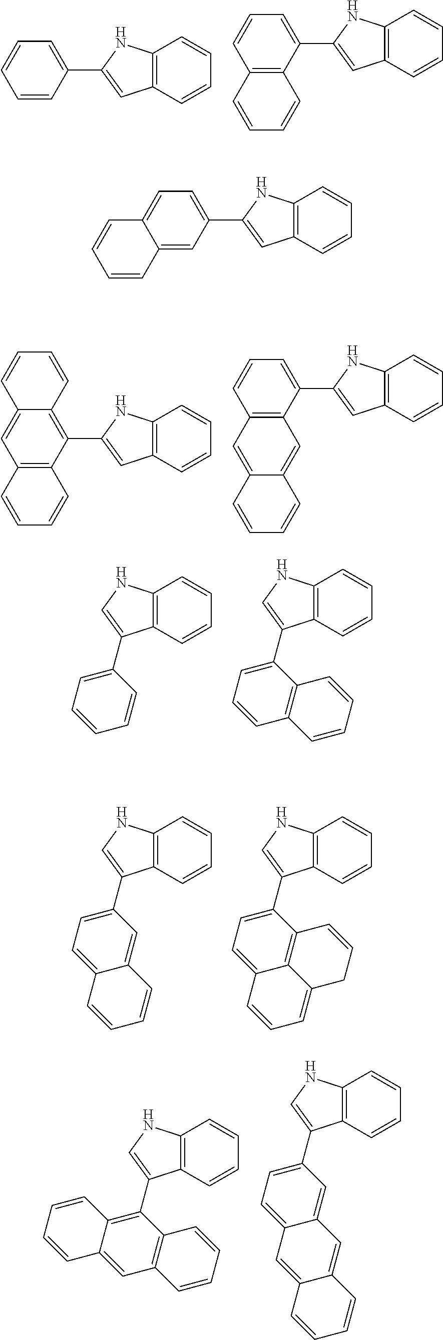

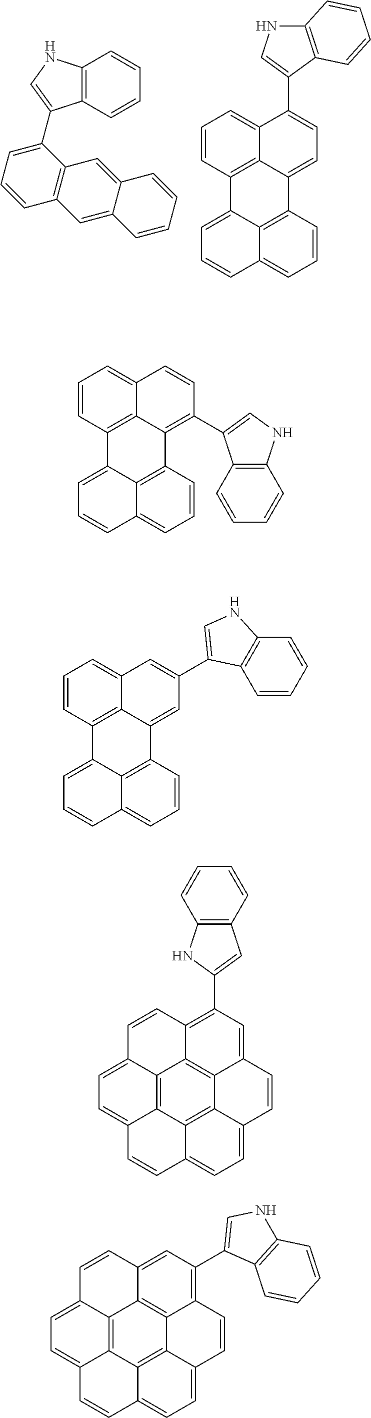

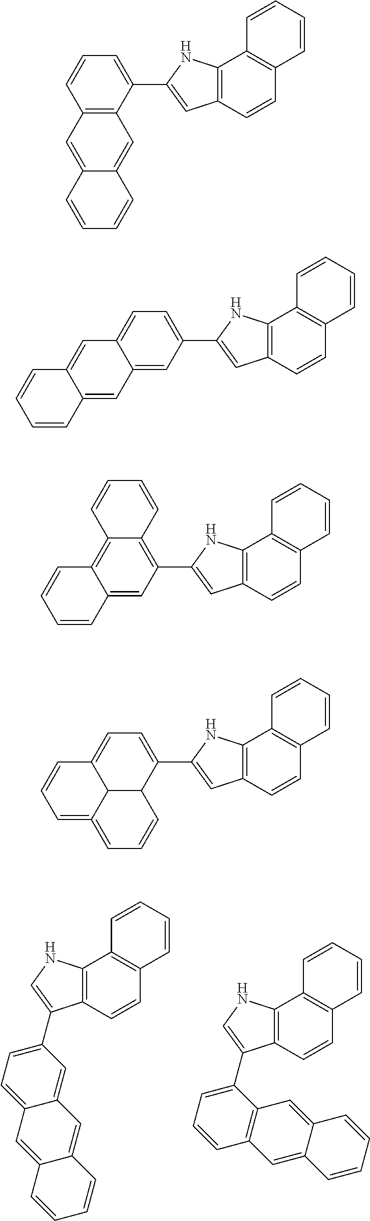

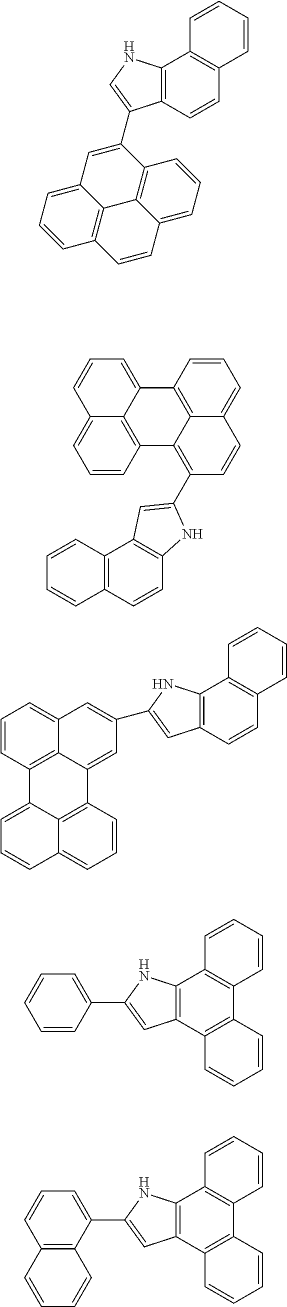 [SMILES: c1ccc2c(c1)ccc1c(-c3cc4cccc5ccc6cccc3c6c54)c[nH]c12 ; c1ccc2c(c1)ccc1[nH]c(-c3ccc4cccc5c6cccc7cccc(c3c45)c76)cc12 ; c1ccc2c(c1)ccc1cc(-c3cc4cccc5c6cccc7cccc(c(c3)c45)c76)[nH]c12 ; c1ccc(-c2cc3c4ccccc4c4ccccc4c3[nH]2)cc1 ; c1ccc2c(-c3cc4c5ccccc5c5ccccc5c4[nH]3)cccc2c1]

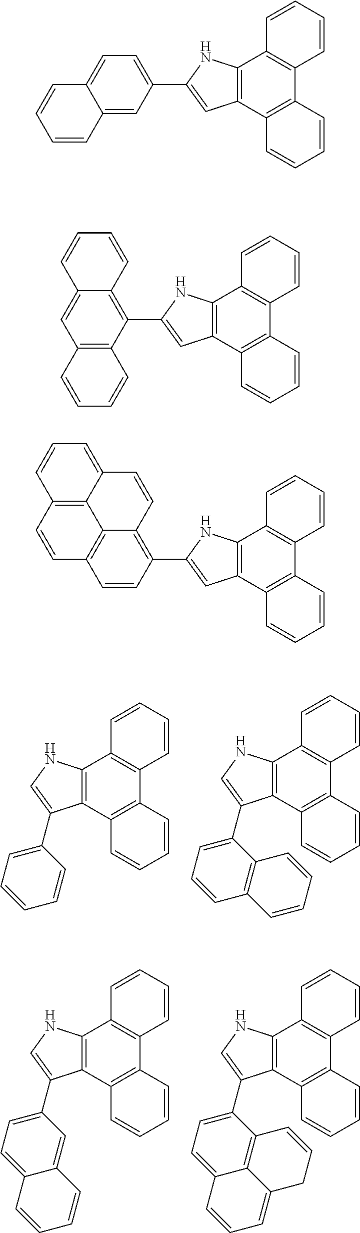

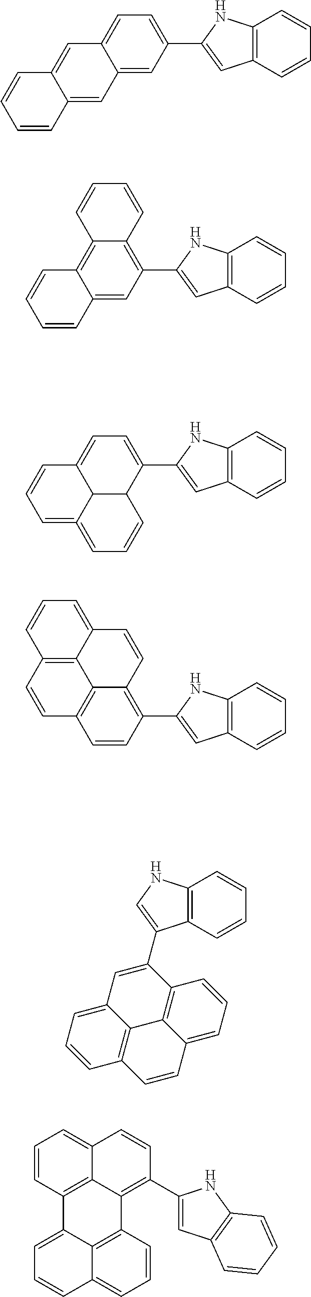

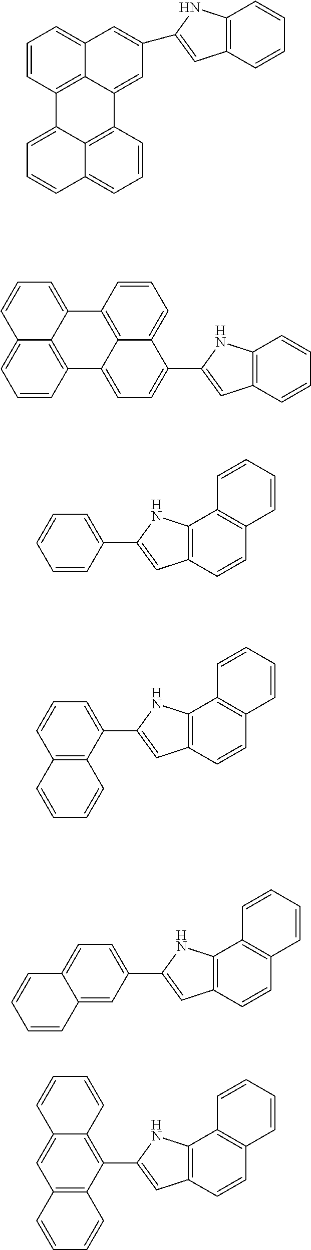

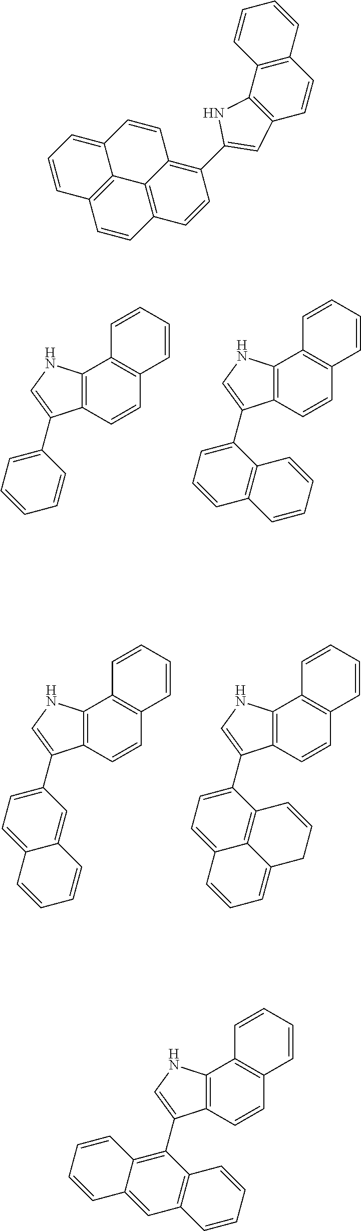 [SMILES: c1ccc2c(c1)ccc1cc(-c3ccc4ccc5cccc6ccc3c4c56)[nH]c12 ; c1ccc(-c2c[nH]c3c2ccc2ccccc23)cc1 ; c1ccc2c(-c3c[nH]c4c3ccc3ccccc34)cccc2c1 ; c1ccc2cc(-c3c[nH]c4c3ccc3ccccc34)ccc2c1 ; C1=Cc2c(-c3c[nH]c4c3ccc3ccccc34)ccc3cccc(c23)C1 ; c1ccc2c(-c3c[nH]c4c3ccc3ccccc34)c3ccccc3cc2c1]

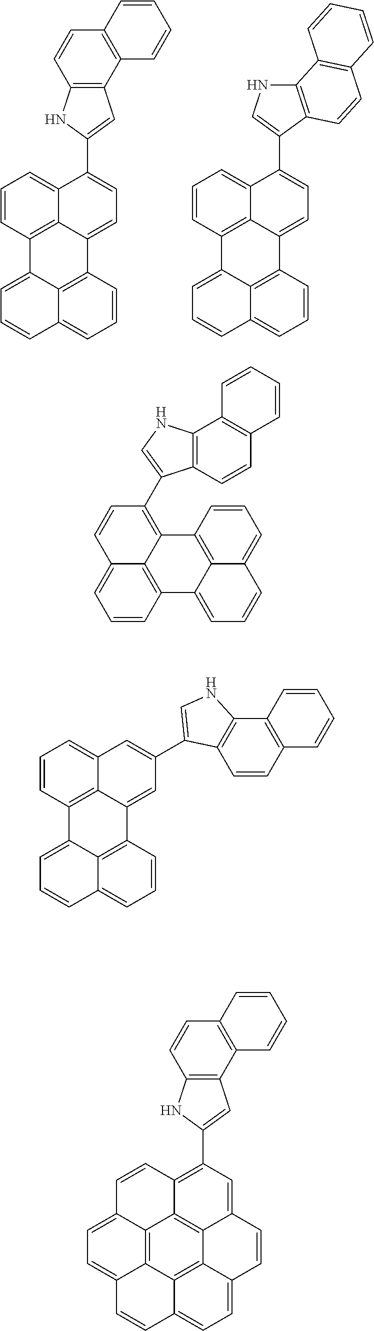

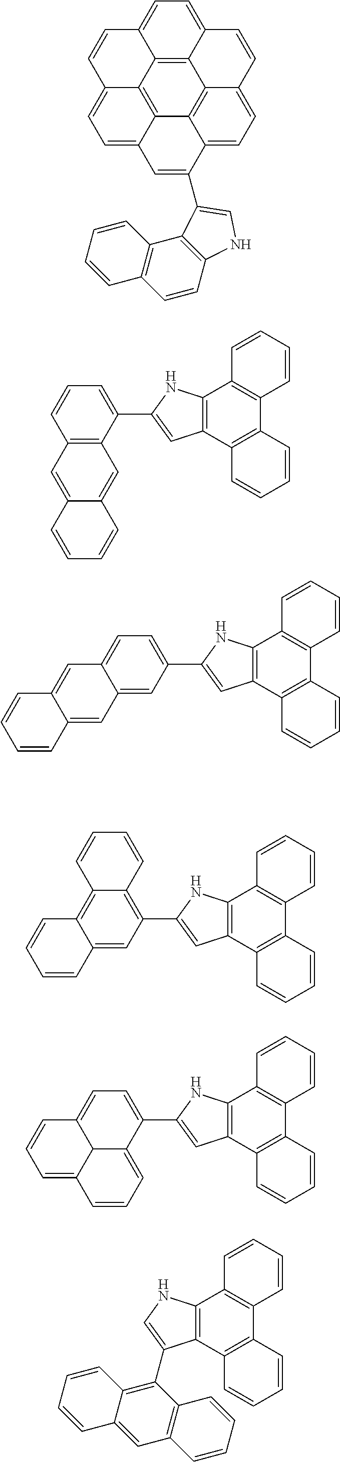

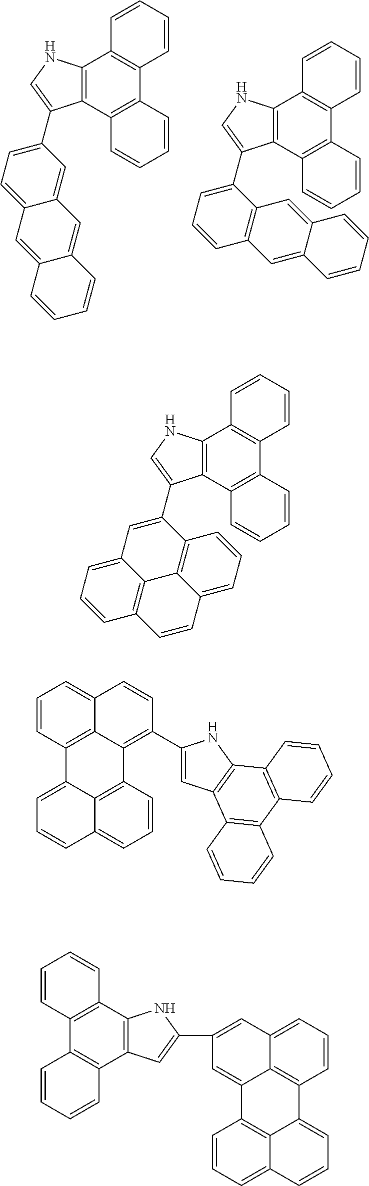 [SMILES: c1ccc2cc3cc(-c4c[nH]c5c6ccccc6c6ccccc6c45)ccc3cc2c1 ; c1ccc2cc3c(-c4c[nH]c5c6ccccc6c6ccccc6c45)cccc3cc2c1 ; c1cc2ccc3cccc4c(-c5c[nH]c6c7ccccc7c7ccccc7c56)cc(c1)c2c34 ; c1ccc2c(c1)c1ccccc1c1[nH]c(-c3ccc4cccc5c6cccc7cccc(c3c45)c76)cc21 ; c1ccc2c(c1)c1ccccc1c1[nH]c(-c3cc4cccc5c6cccc7cccc(c(c3)c45)c76)cc21]

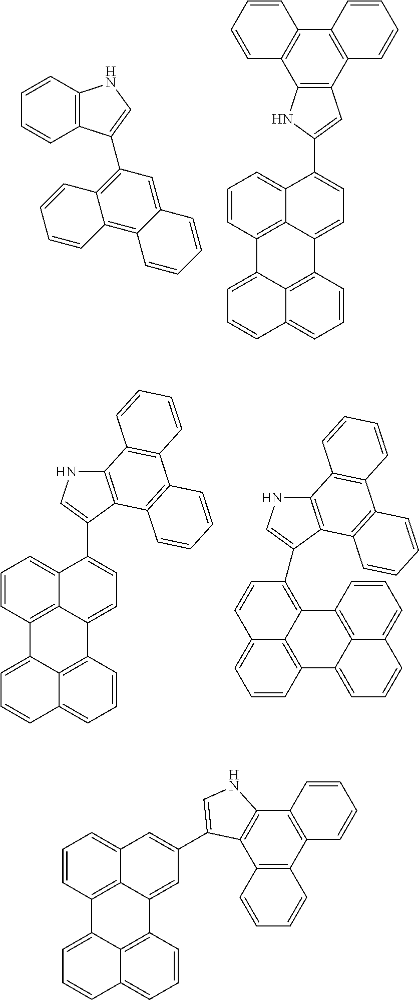

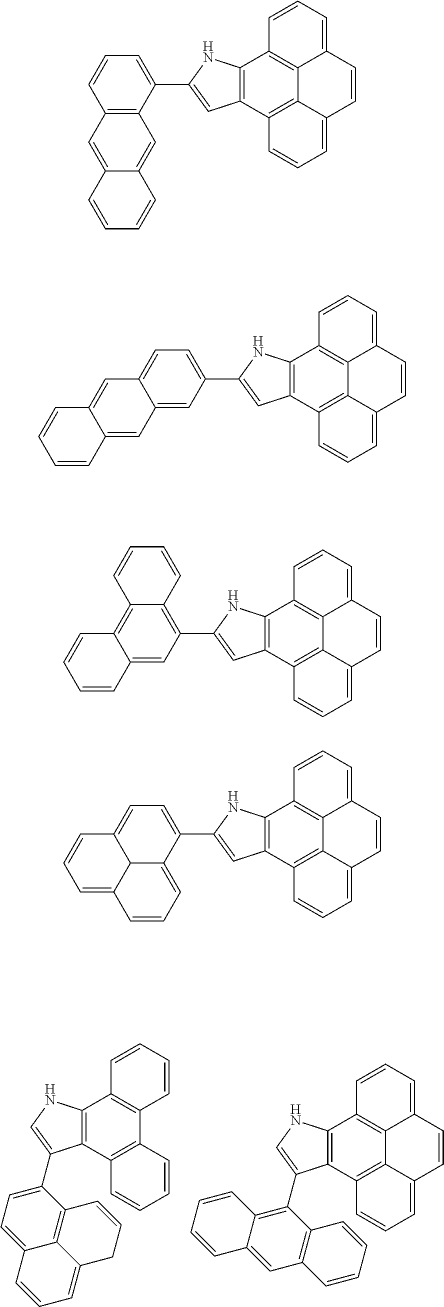

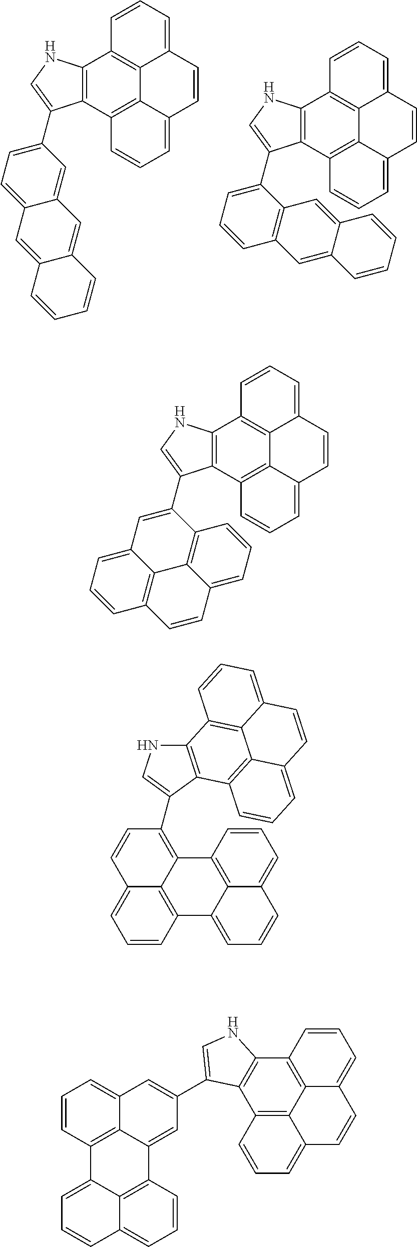 [SMILES: c1ccc2cc3cc(-c4c[nH]c5c6cccc7ccc8cccc(c45)c8c76)ccc3cc2c1 ; c1ccc2cc3c(-c4c[nH]c5c6cccc7ccc8cccc(c45)c8c76)cccc3cc2c1 ; c1cc2ccc3cccc4c(-c5c[nH]c6c7cccc8ccc9cccc(c56)c9c87)cc(c1)c2c34 ; c1cc2cccc3c4c(-c5c[nH]c6c7cccc8ccc9cccc(c56)c9c87)ccc5cccc(c(c1)c23)c54 ; c1cc2cccc3c4cc(-c5c[nH]c6c7cccc8ccc9cccc(c56)c9c87)cc5cccc(c(c1)c23)c54]

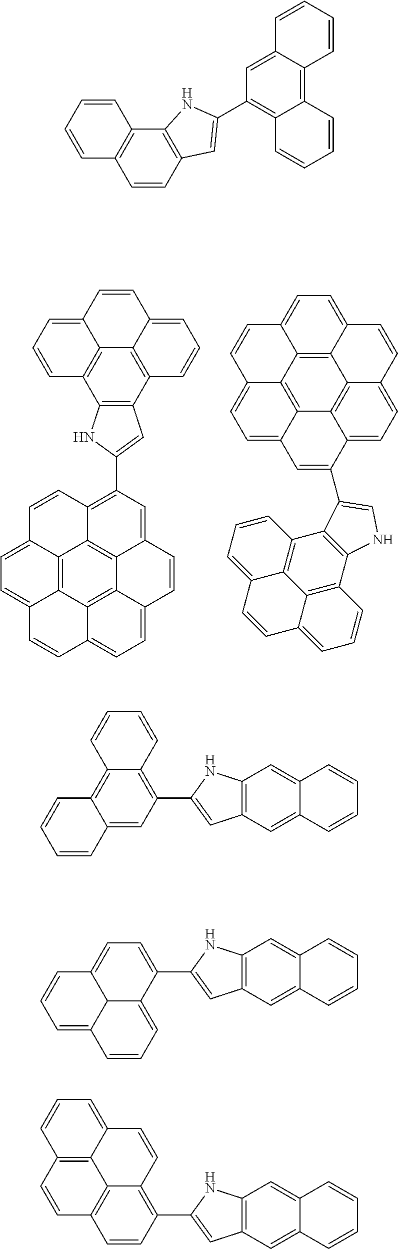

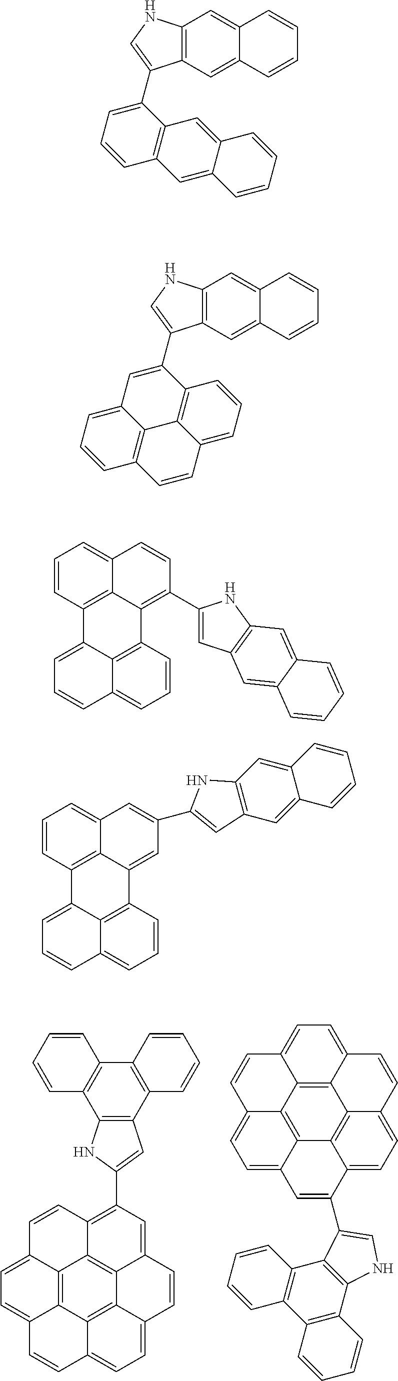

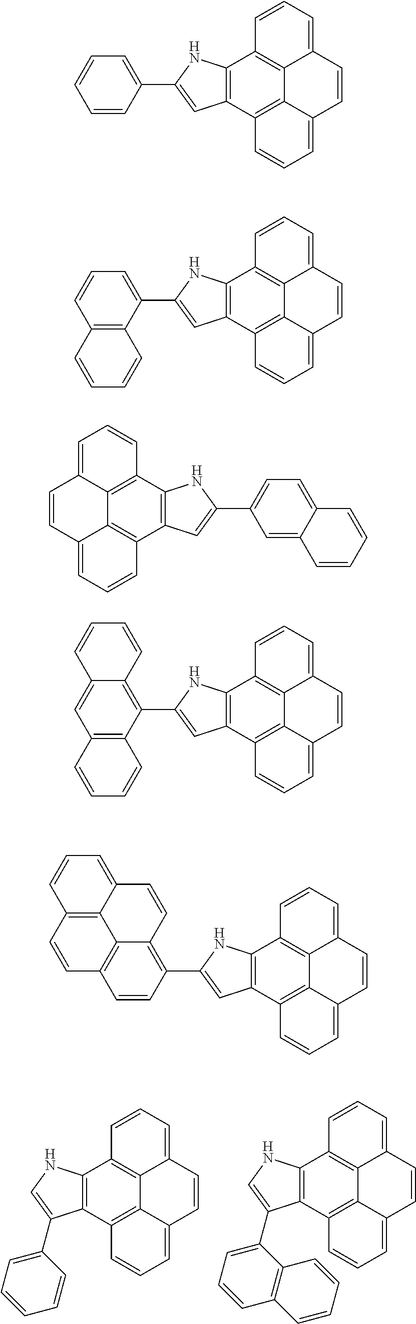

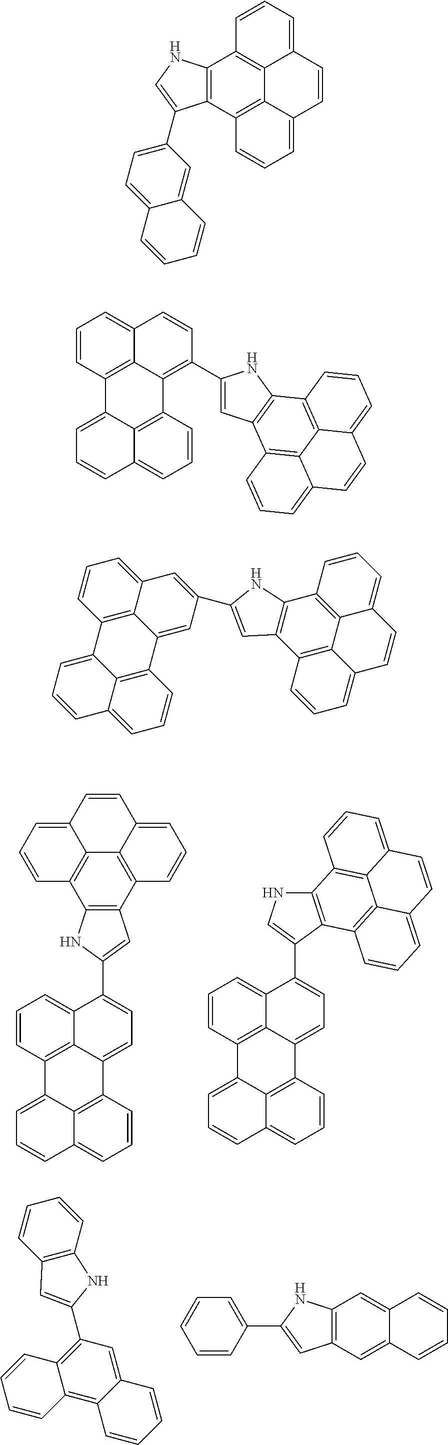

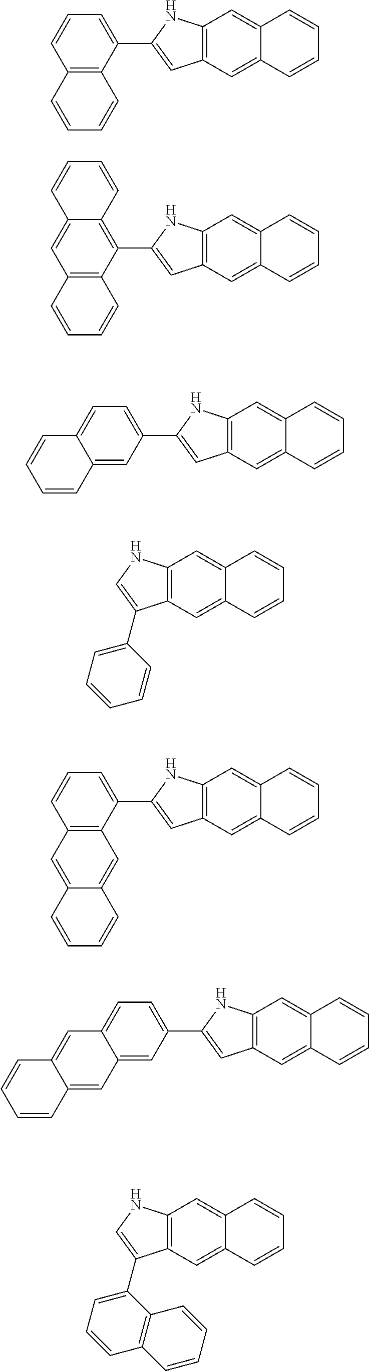

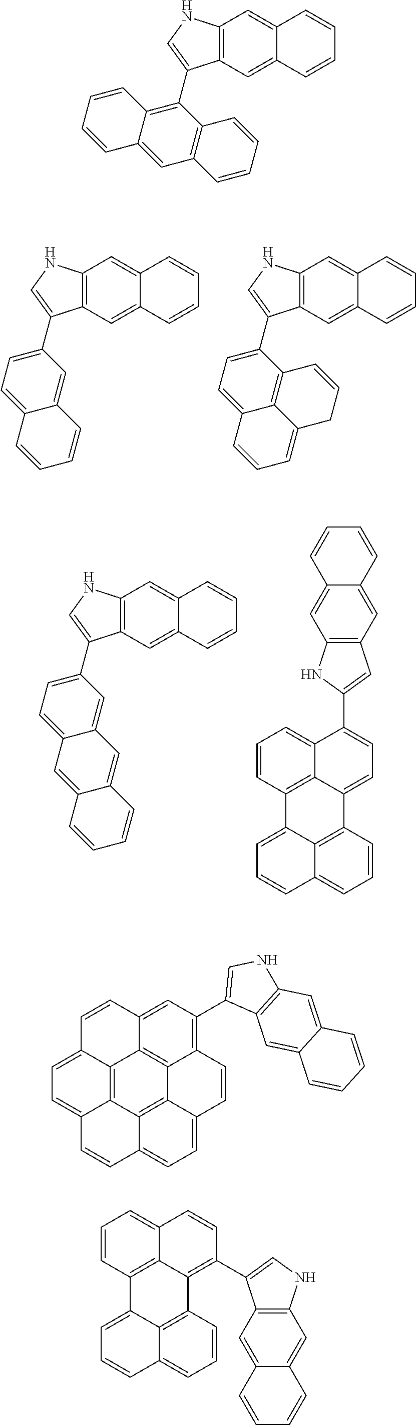

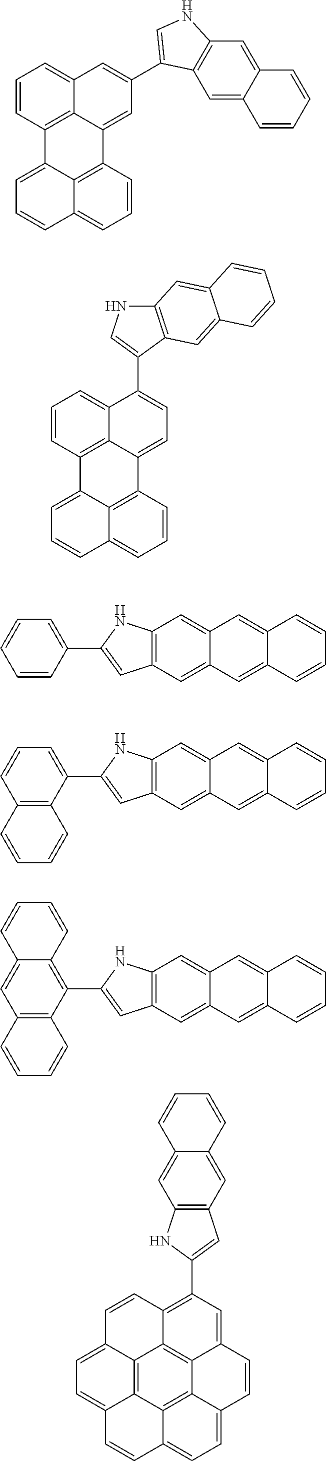

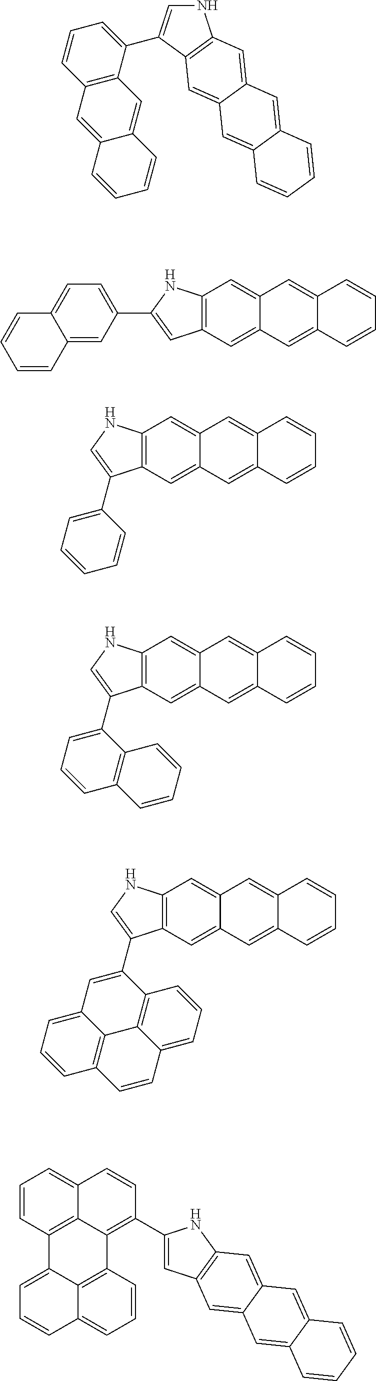 [SMILES: c1ccc2cc3cc4c(-c5cccc6cc7ccccc7cc56)c[nH]c4cc3cc2c1 ; c1ccc2cc(-c3cc4cc5cc6ccccc6cc5cc4[nH]3)ccc2c1 ; c1ccc(-c2c[nH]c3cc4cc5ccccc5cc4cc23)cc1 ; c1ccc2cc3cc4c(-c5cccc6ccccc56)c[nH]c4cc3cc2c1 ; c1ccc2cc3cc4c(-c5cc6cccc7ccc8cccc5c8c76)c[nH]c4cc3cc2c1 ; c1ccc2cc3cc4[nH]c(-c5ccc6cccc7c8cccc9cccc(c5c67)c98)cc4cc3cc2c1]

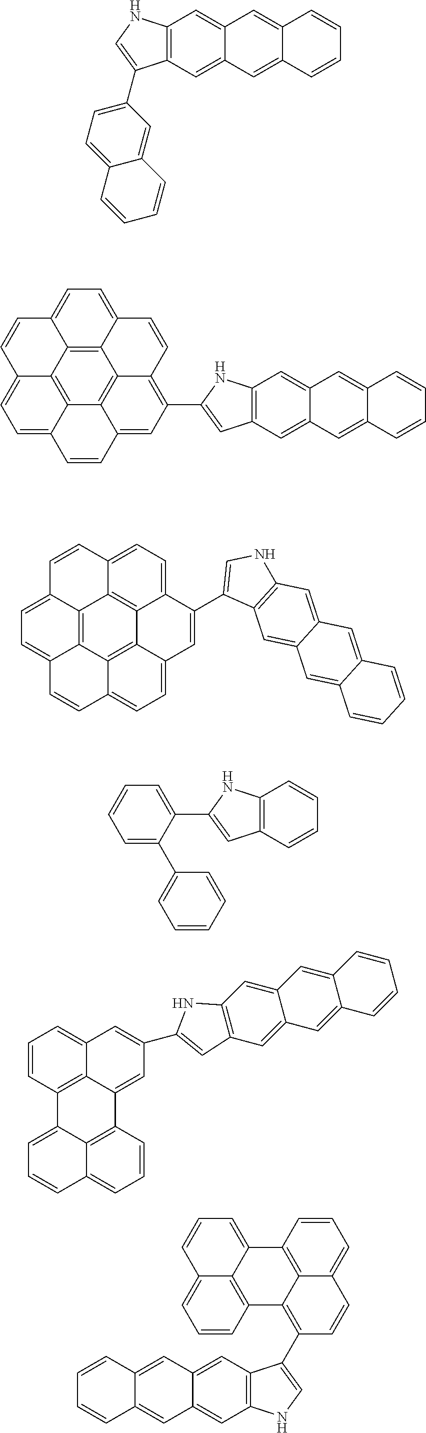 [SMILES: c1ccc2cc(-c3c[nH]c4cc5cc6ccccc6cc5cc34)ccc2c1 ; c1ccc2cc3cc4[nH]c(-c5cc6ccc7ccc8ccc9ccc%10ccc5c5c%10c9c8c7c65)cc4cc3cc2c1 ; c1ccc2cc3cc4c(-c5cc6ccc7ccc8ccc9ccc%10ccc5c5c%10c9c8c7c65)c[nH]c4cc3cc2c1 ; c1ccc(-c2ccccc2-c2cc3ccccc3[nH]2)cc1 ; c1ccc2cc3cc4[nH]c(-c5cc6cccc7c8cccc9cccc(c(c5)c67)c98)cc4cc3cc2c1 ; c1ccc2cc3cc4c(-c5ccc6cccc7c8cccc9cccc(c5c67)c98)c[nH]c4cc3cc2c1]

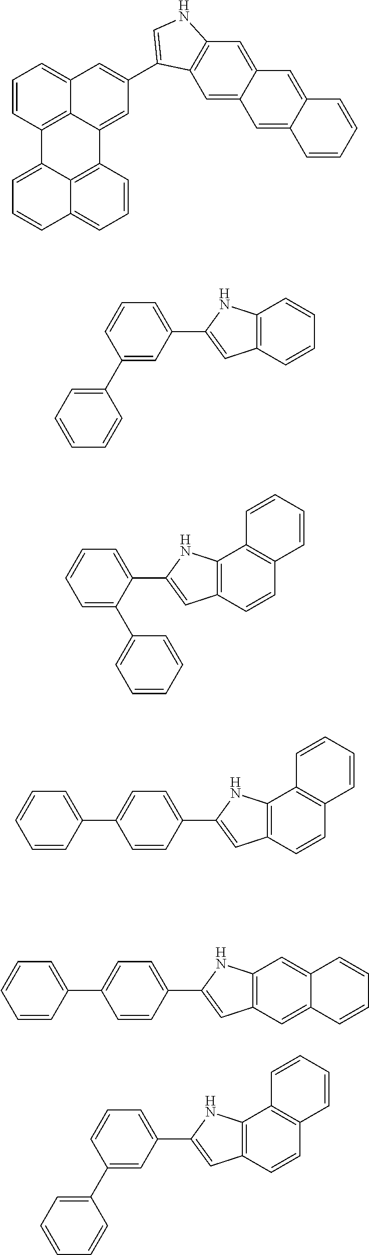

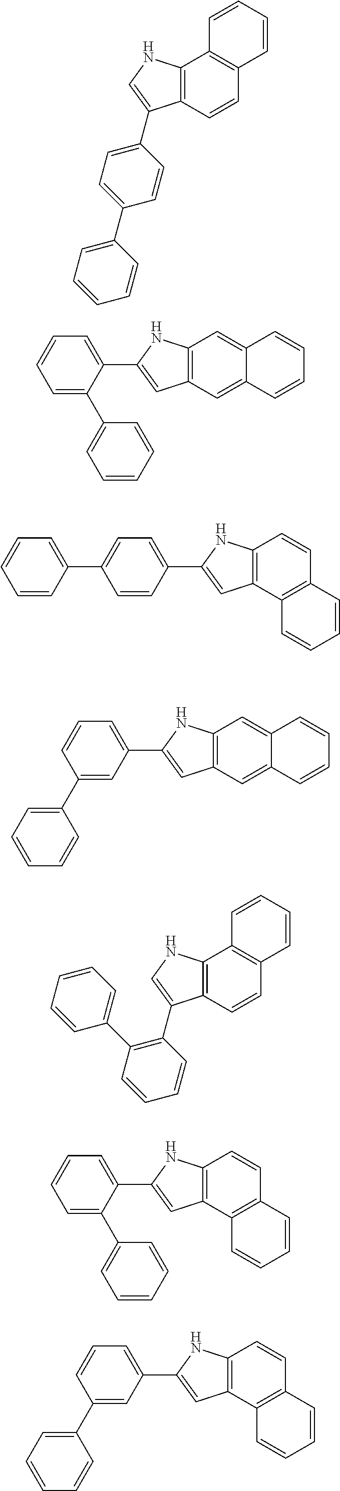

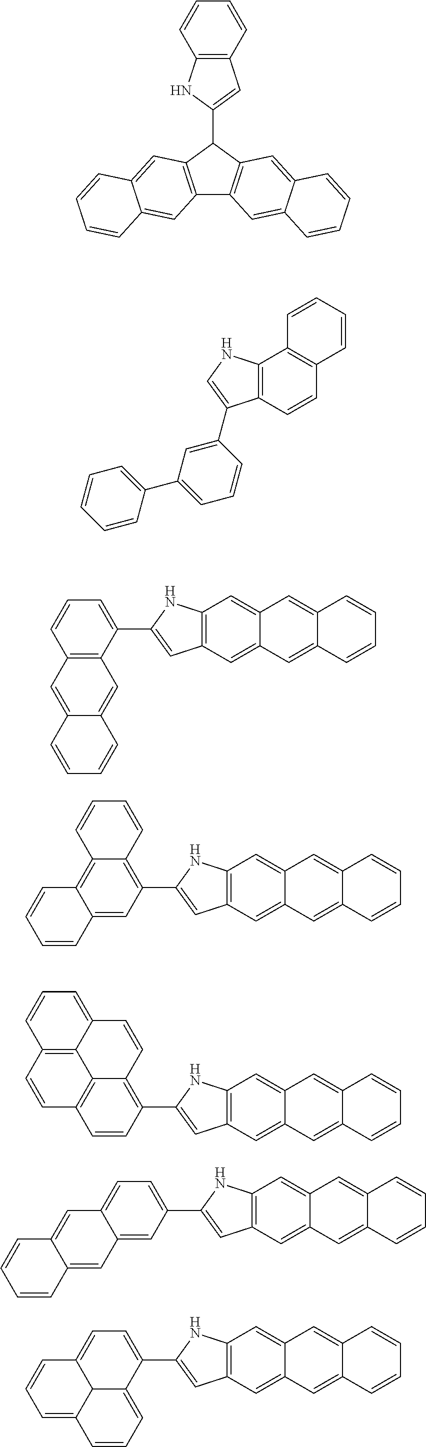

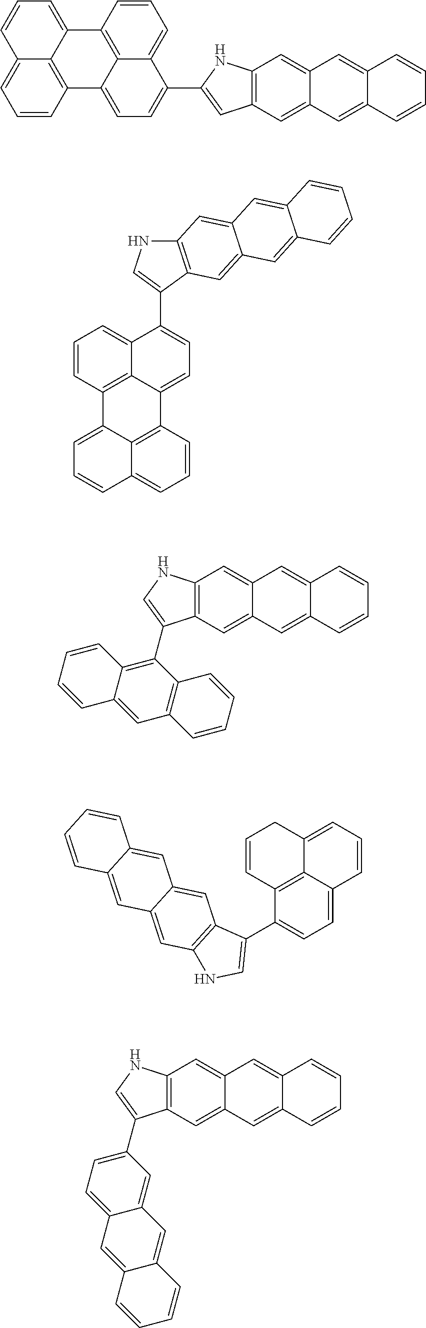 [SMILES: c1ccc2cc3cc4[nH]c(-c5ccc6c7cccc8cccc(c9cccc5c96)c87)cc4cc3cc2c1 ; c1ccc2cc3cc4c(-c5ccc6c7cccc8cccc(c9cccc5c96)c87)c[nH]c4cc3cc2c1 ; c1ccc2cc3cc4c(-c5c6ccccc6cc6ccccc56)c[nH]c4cc3cc2c1 ; C1=Cc2c(-c3c[nH]c4cc5cc6ccccc6cc5cc34)ccc3cccc(c23)C1 ; c1ccc2cc3cc(-c4c[nH]c5cc6cc7ccccc7cc6cc45)ccc3cc2c1]

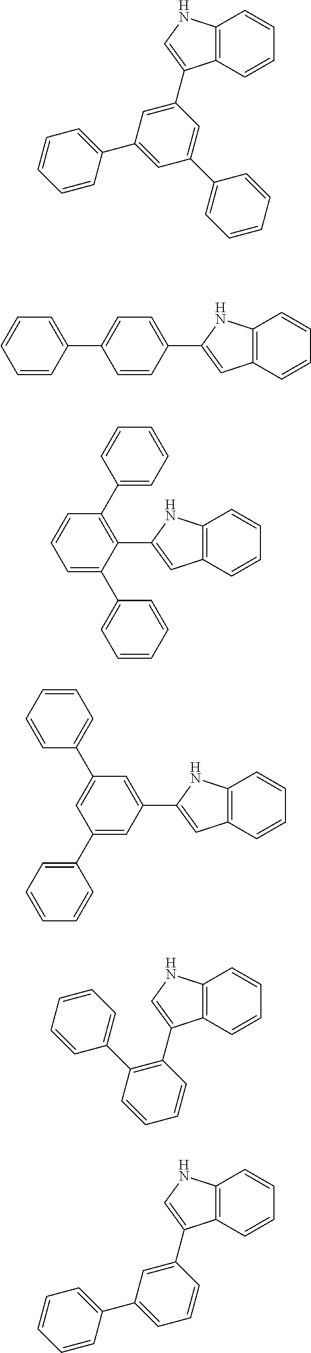 [SMILES: c1ccc(-c2cc(-c3ccccc3)cc(-c3c[nH]c4ccccc34)c2)cc1 ; c1ccc(-c2ccc(-c3cc4ccccc4[nH]3)cc2)cc1 ; c1ccc(-c2cccc(-c3ccccc3)c2-c2cc3ccccc3[nH]2)cc1 ; c1ccc(-c2cc(-c3ccccc3)cc(-c3cc4ccccc4[nH]3)c2)cc1 ; c1ccc(-c2ccccc2-c2c[nH]c3ccccc23)cc1 ; c1ccc(-c2cccc(-c3c[nH]c4ccccc34)c2)cc1]

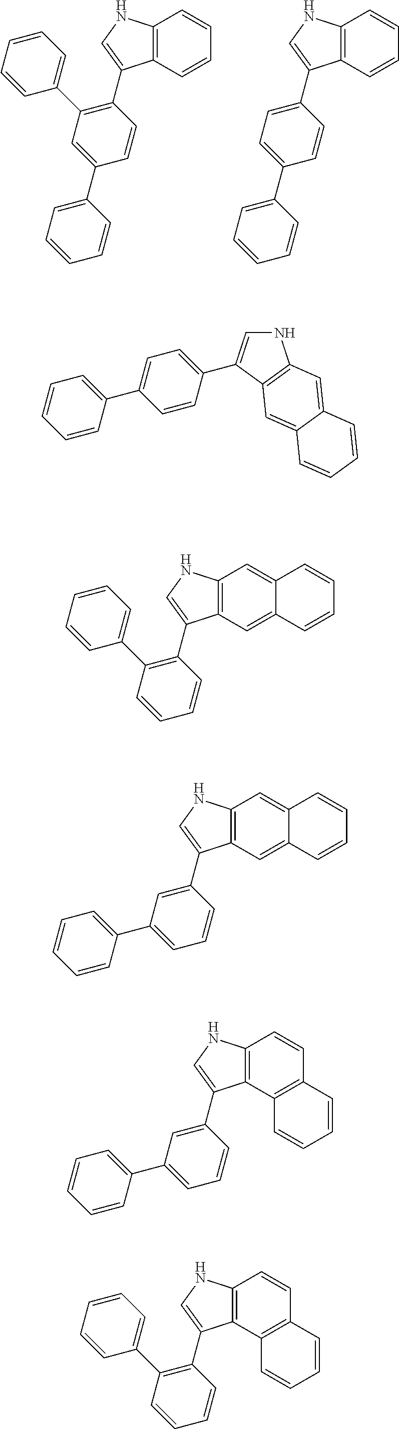

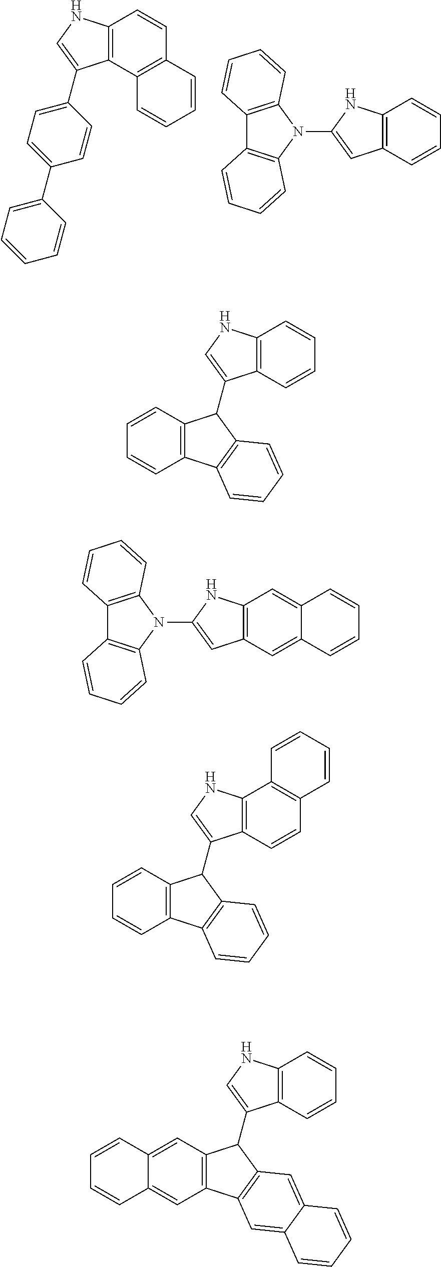

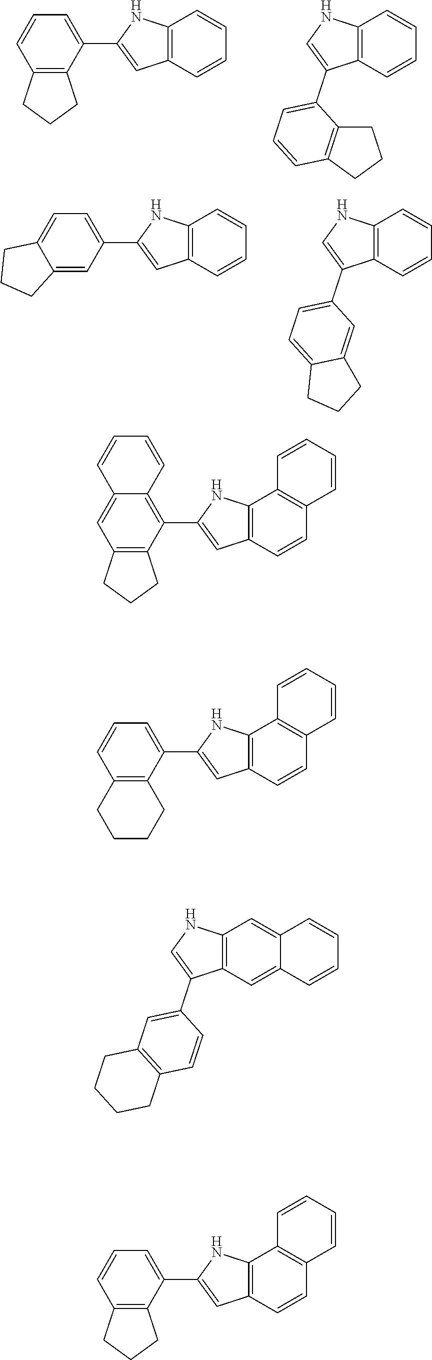

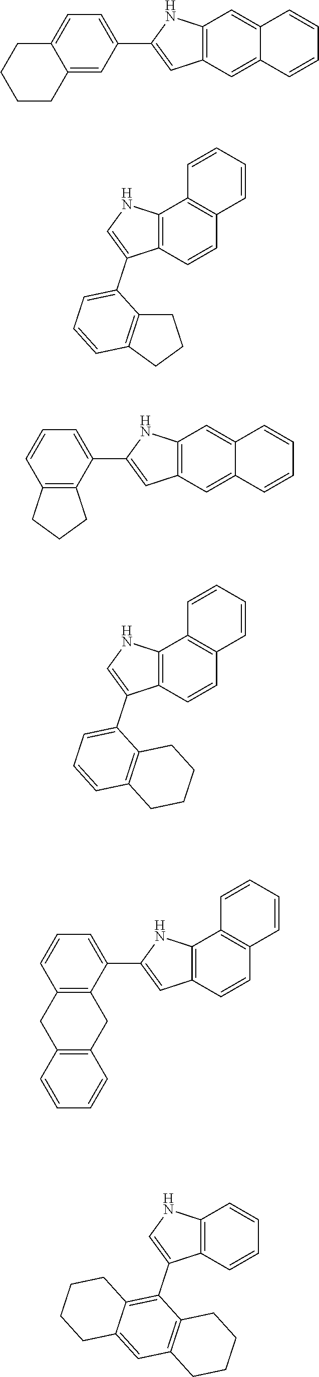 [SMILES: c1ccc2cc3[nH]c(-c4ccc5c(c4)CCCC5)cc3cc2c1 ; c1cc2c(c(-c3c[nH]c4c3ccc3ccccc34)c1)CCC2 ; c1cc2c(c(-c3cc4cc5ccccc5cc4[nH]3)c1)CCC2 ; c1cc2c(c(-c3c[nH]c4c3ccc3ccccc34)c1)CCCC2 ; c1ccc2c(c1)Cc1cccc(-c3cc4ccc5ccccc5c4[nH]3)c1C2 ; c1ccc2c(-c3c4c(cc5c3CCCC5)CCCC4)c[nH]c2c1]

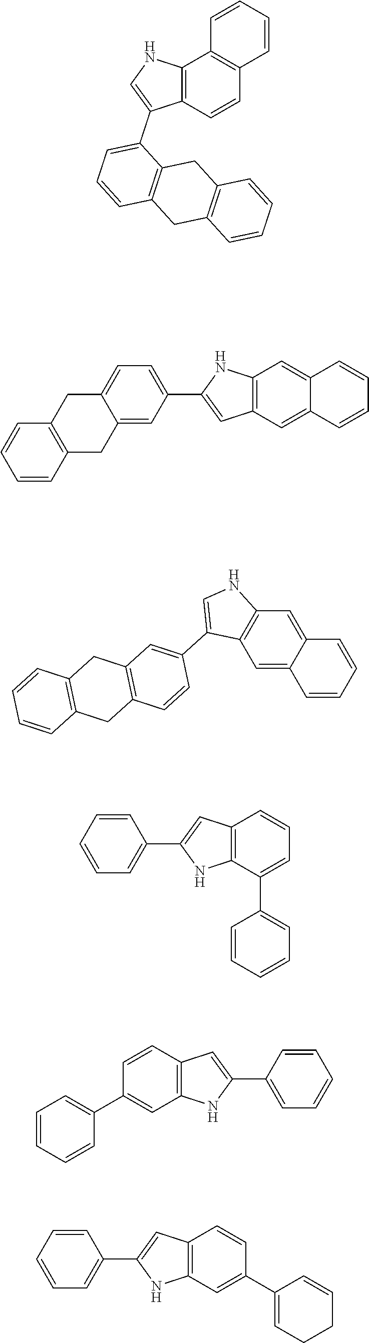 [SMILES: c1ccc2c(c1)Cc1cccc(-c3c[nH]c4c3ccc3ccccc34)c1C2 ; c1ccc2c(c1)Cc1ccc(-c3cc4cc5ccccc5cc4[nH]3)cc1C2 ; c1ccc2c(c1)Cc1ccc(-c3c[nH]c4cc5ccccc5cc34)cc1C2 ; c1ccc(-c2cc3cccc(-c4ccccc4)c3[nH]2)cc1 ; c1ccc(-c2ccc3cc(-c4ccccc4)[nH]c3c2)cc1 ; C1=CC(c2ccc3cc(-c4ccccc4)[nH]c3c2)=CCC1]

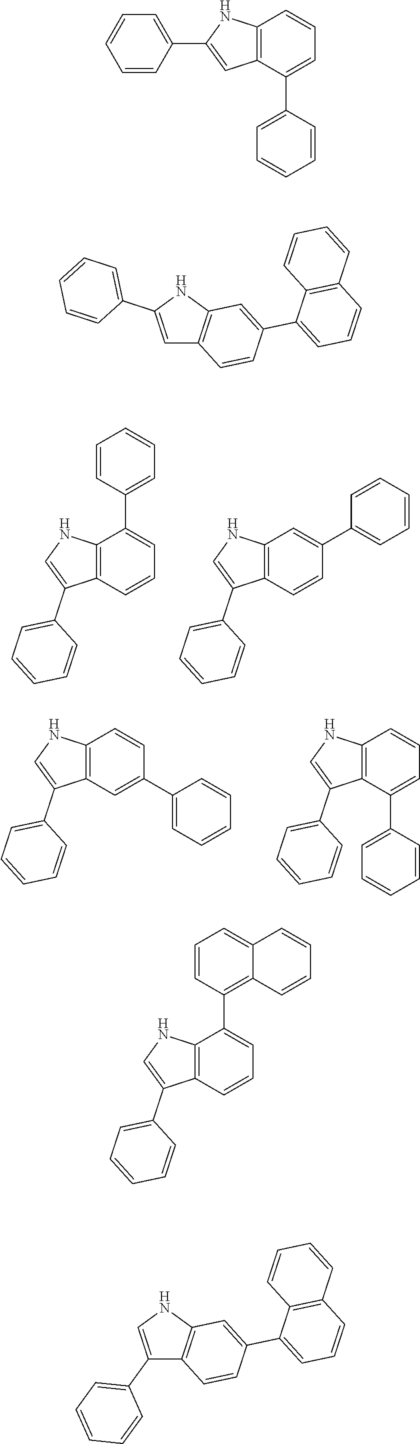

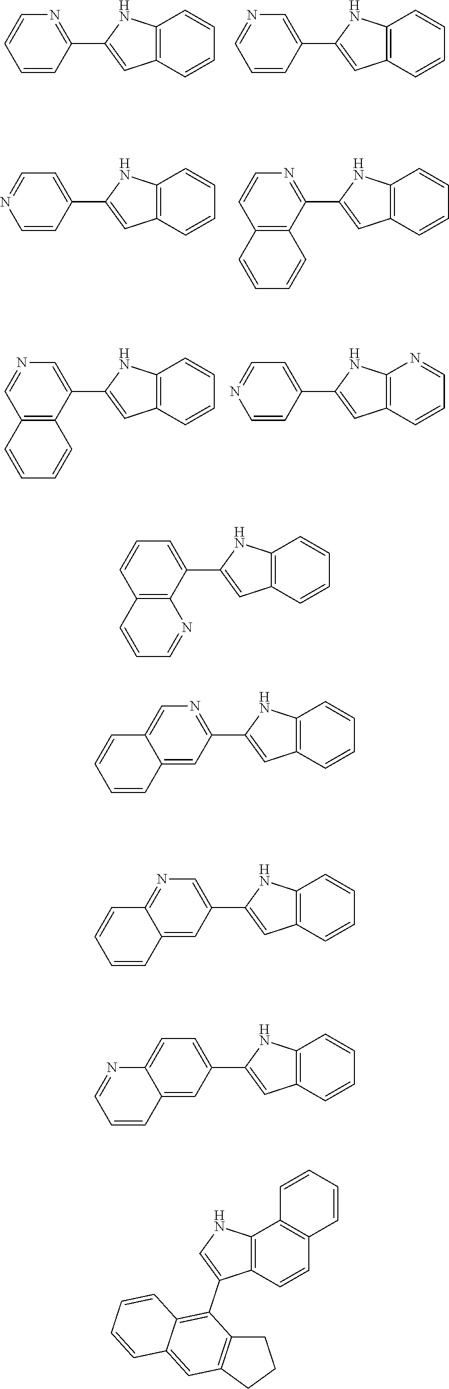

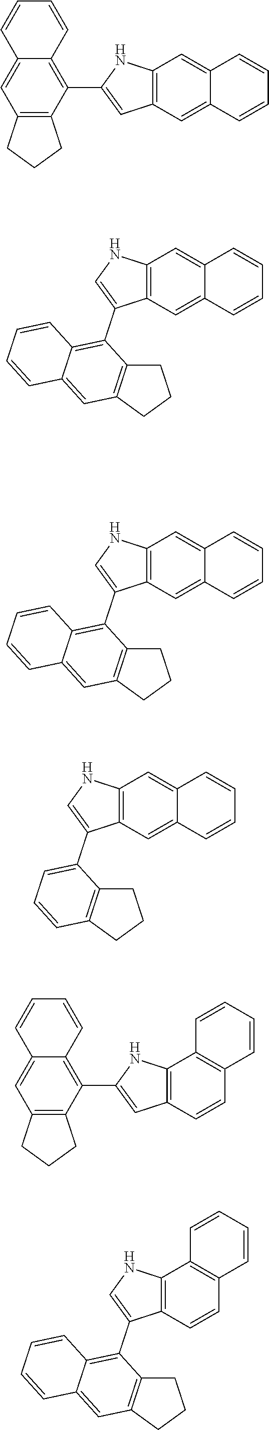 [SMILES: c1ccc2cc3[nH]c(-c4c5c(cc6ccccc46)CCC5)cc3cc2c1 ; c1ccc2cc3c(-c4c5c(cc6ccccc46)CCC5)c[nH]c3cc2c1 ; c1ccc2cc3c(-c4c5c(cc6ccccc46)CCC5)c[nH]c3cc2c1 ; c1cc2c(c(-c3c[nH]c4cc5ccccc5cc34)c1)CCC2 ; c1ccc2c(-c3cc4ccc5ccccc5c4[nH]3)c3c(cc2c1)CCC3 ; c1ccc2c(-c3c[nH]c4c3ccc3ccccc34)c3c(cc2c1)CCC3]

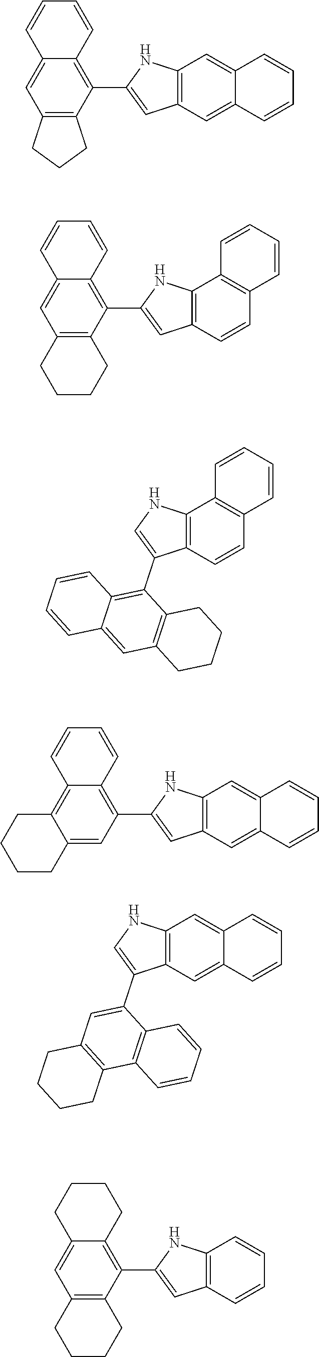 [SMILES: c1ccc2cc3[nH]c(-c4c5c(cc6ccccc46)CCC5)cc3cc2c1 ; c1ccc2c(-c3cc4ccc5ccccc5c4[nH]3)c3c(cc2c1)CCCC3 ; c1ccc2c(-c3c[nH]c4c3ccc3ccccc34)c3c(cc2c1)CCCC3 ; c1ccc2cc3[nH]c(-c4cc5c(c6ccccc46)CCCC5)cc3cc2c1 ; c1ccc2cc3c(-c4cc5c(c6ccccc46)CCCC5)c[nH]c3cc2c1 ; c1ccc2[nH]c(-c3c4c(cc5c3CCCC5)CCCC4)cc2c1]

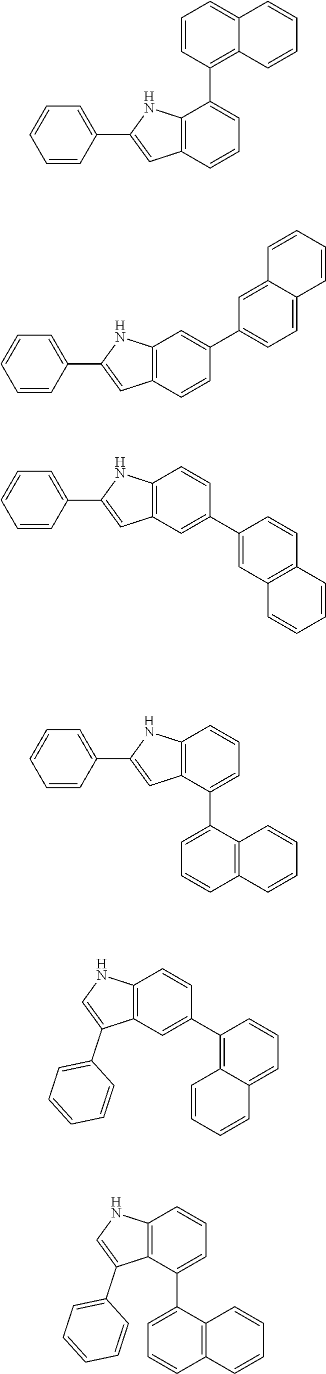 [SMILES: c1ccc(-c2cc3cccc(-c4cccc5ccccc45)c3[nH]2)cc1 ; c1ccc(-c2cc3ccc(-c4ccc5ccccc5c4)cc3[nH]2)cc1 ; c1ccc(-c2cc3cc(-c4ccc5ccccc5c4)ccc3[nH]2)cc1 ; c1ccc(-c2cc3c(-c4cccc5ccccc45)cccc3[nH]2)cc1 ; c1ccc(-c2c[nH]c3ccc(-c4cccc5ccccc45)cc23)cc1 ; c1ccc(-c2c[nH]c3cccc(-c4cccc5ccccc45)c23)cc1]

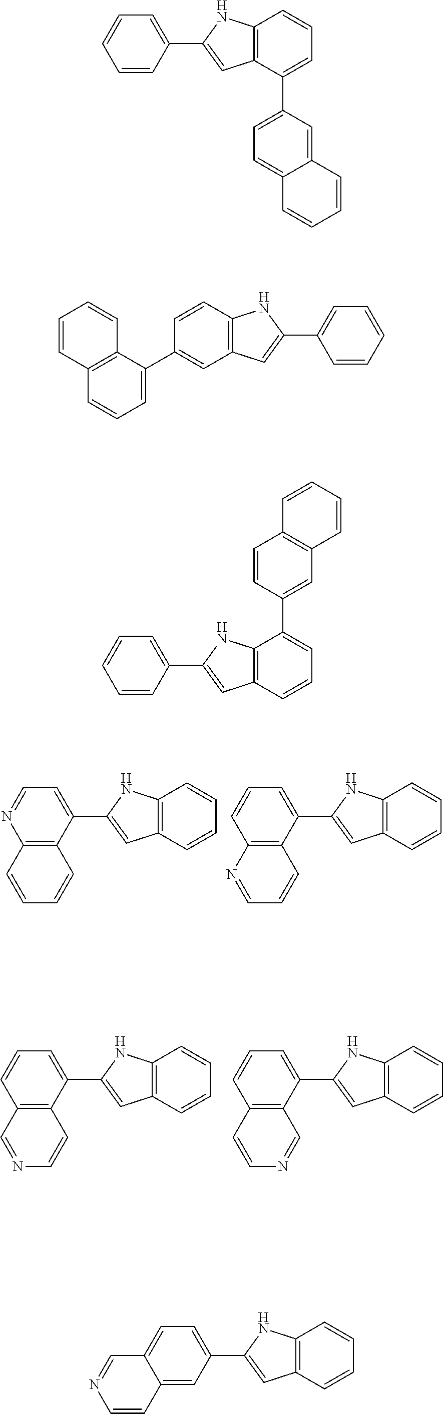

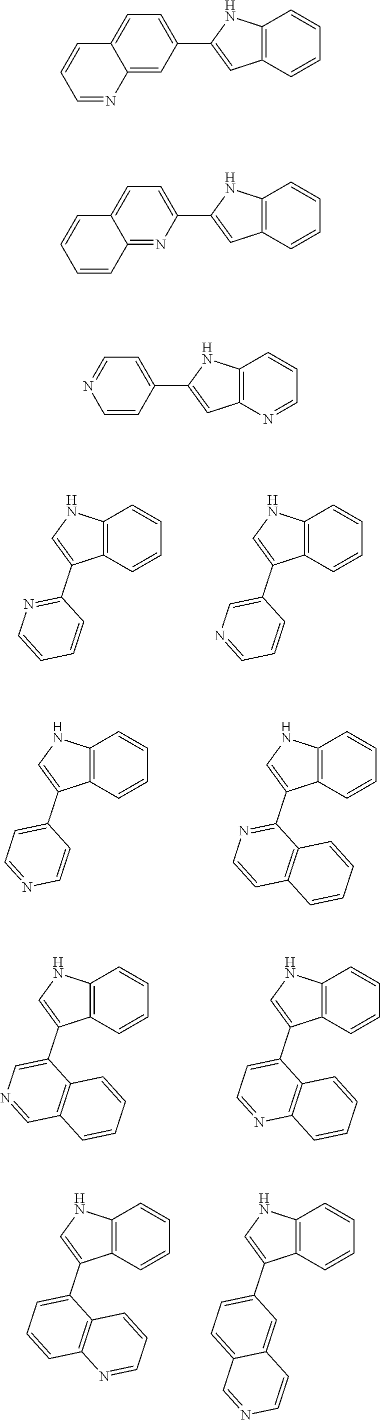

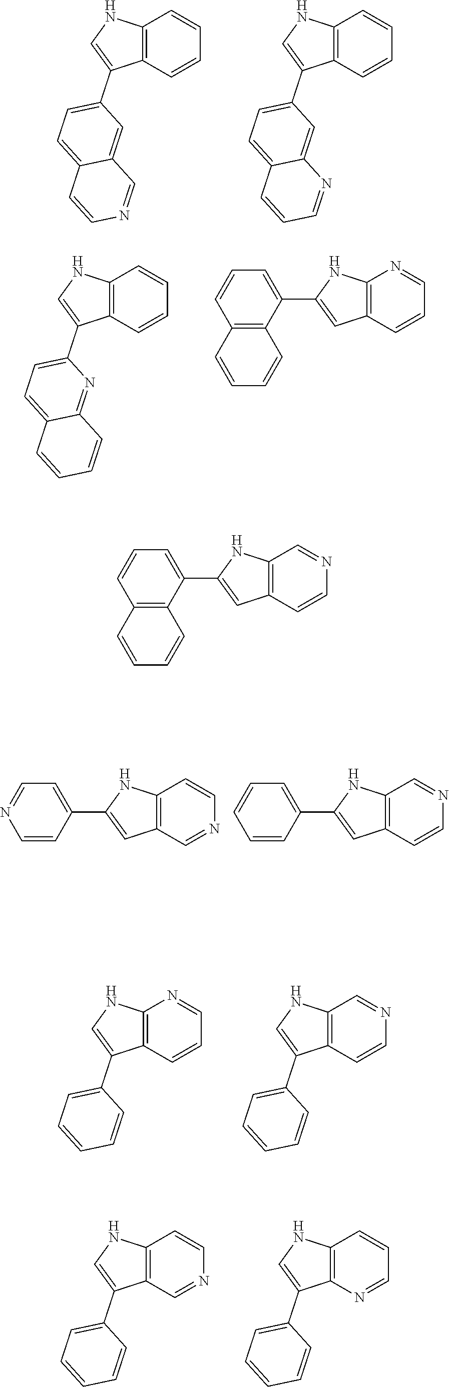

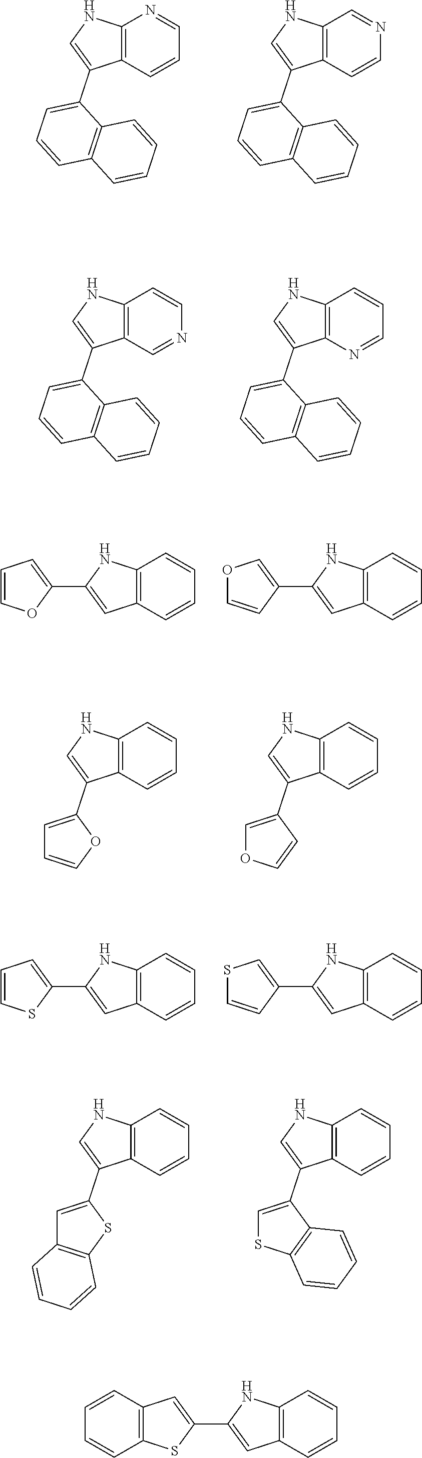

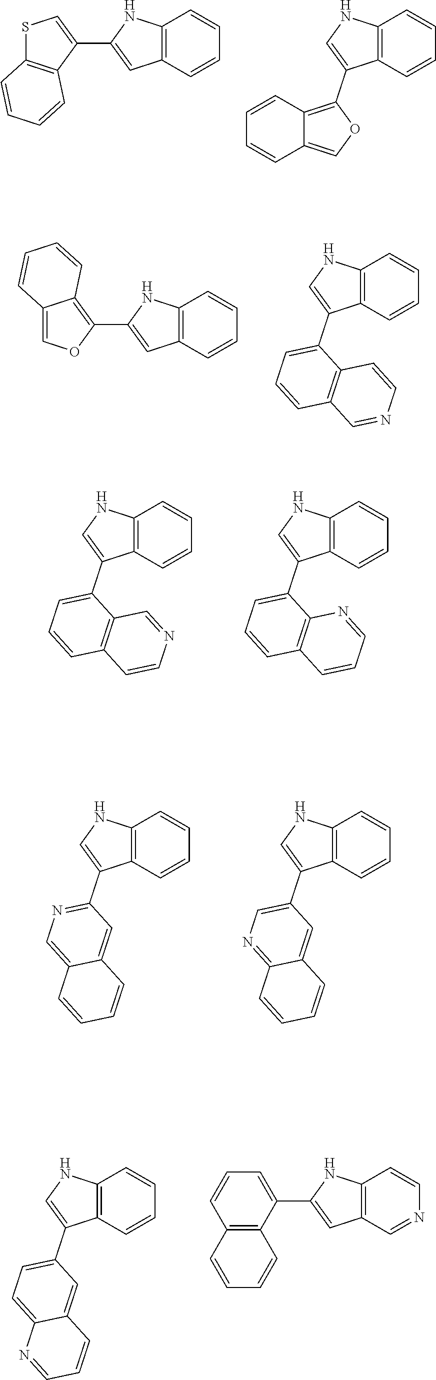

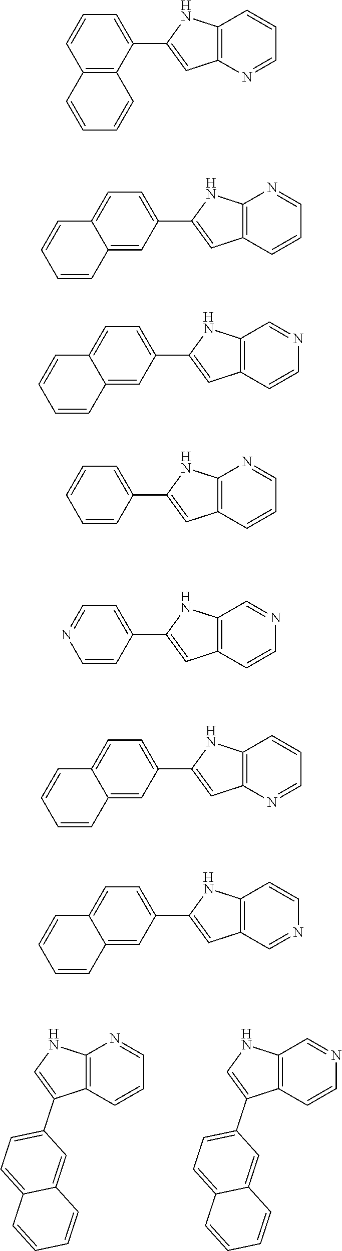

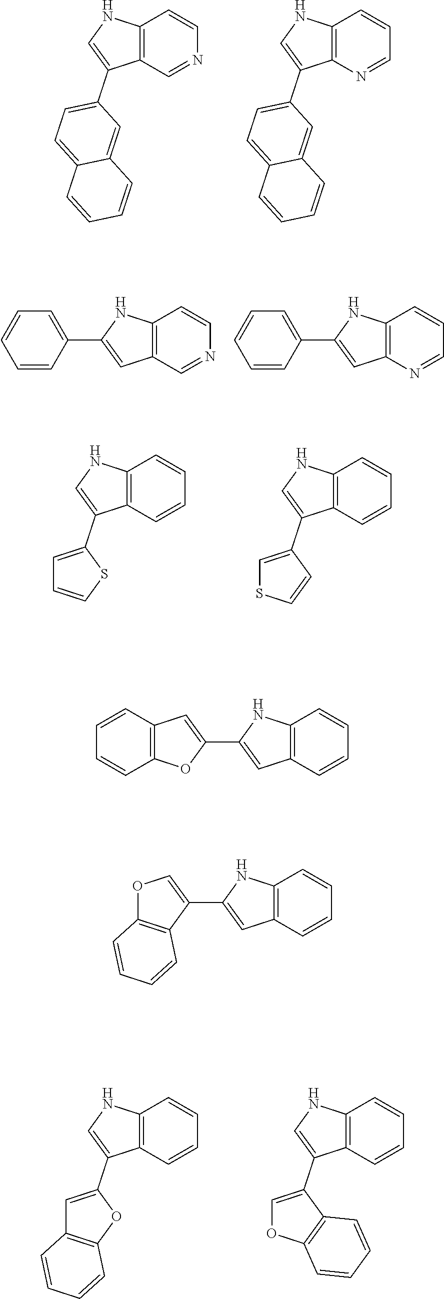

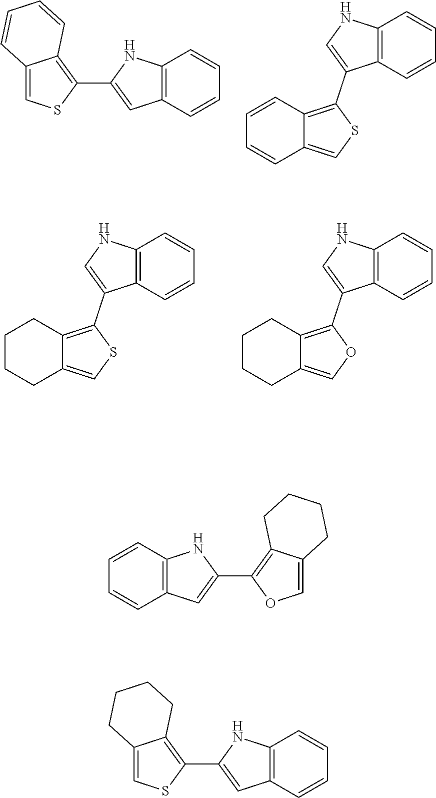

In the present invention, in the unit structure of Formula (I) or Formula (I′), a novolac resin is formed between a heterocyclic compound containing a ring A and a ring B (heterocyclic group-containing aromatic compound) and aldehydes or ketones.

5 Examples of aldehydes used in the production of the polymer of the present invention include saturated aliphatic aldehydes such as formaldehyde, paraformaldehyde, acetaldehyde, propylaldehyde, butyl aldehyde, isobutyl aldehyde, valeraldehyde, capronaldehyde, 2-methyl butyl aldehyde, hexylaldehyde, undecane aldehyde, 7-methoxy-3,7-dimethyl octyl aldehyde, cyclohexane aldehyde, 3-methyl-2-butylaldehyde, glyoxal, malonaldehyde, succinaldehyde, glutaraldehyde, glutaraldehyde, and adipic aldehyde, unsaturated aliphatic aldehydes such as acrolein and methacrolein, heterocyclic aldehydes such as furfural and pyridine aldehyde, and aromatic aldehydes such as benzaldehyde, naphthylaldehyde, anthrylaldehyde, phenanthrylaldehyde, salicylaldehyde, phenylacetaldehyde, 3-phenylpropionaldehyde, tolylaldehyde, (N,N-dimethylamino)benzaldehyde, acetoxybenzaldehyde, 1-pyrenecarboxaldehyde, anisaldehyde, and terephthalaldehyde, and aromatic aldehydes are particularly preferably used.

In addition, ketones used in the production of the polymer of the present invention are diaryl ketones, and examples thereof include diphenyl ketone, phenyl naphthyl ketone, dinaphthyl ketone, phenyl tolyl ketone, ditolyl ketone, and 9-fluorenone.

Novolac resins having repeating unit structures can be prepared by known methods. For example, novolac resins can be prepared by condensing ring-containing compounds of H-A-H and oxygen-containing compounds of OHC-B, O═C—B, HO—B—OH, RO—B—OR and the like (wherein A and B are the same as the ring A and the ring B; and R is a halogen atom or an alkyl group having about 1 to 3 carbon atoms). The ring-containing compounds and the oxygen-containing compounds each may be used alone or two or more thereof may be used in combination. In this condensation reaction, per 1 mol of the ring-containing compound, the oxygen- and nitrogen-containing compound can be used in a proportion of 0.1 to 10 mol and preferably 0.1 to 2 mol.

As the catalyst used in the condensation reaction, for example, mineral acids such as sulfuric acid, phosphoric acid, and perchloric acid, organic sulfonic acids such as p-toluenesulfonic acid, p-toluenesulfonic acid monohydrate, methanesulfonic acid, and trifluoromethanesulfonic acid, and carboxylic acids such as formic acid and oxalic acid can be used.

The amount of the catalyst used varies depending on the type of the catalyst used, but is generally 0.001 to 10,000 parts by mass, preferably 0.01 to 1,000 parts by mass, and more preferably 0.05 to 100 parts by mass with respect to 100 parts by mass of the ring-containing compound (a total amount when a plurality of types thereof is used).

The condensation reaction can be performed without a solvent, but is generally performed using a solvent. The solvent is not particularly limited as long as it can dissolve the reactant and does not inhibit the reaction. Examples thereof include 1,2-dimethoxyethane, diethylene glycol dimethyl ether, propylene glycol monomethyl ether, propylene glycol monomethyl ether acetate, tetrahydrofuran, dioxane, 1,2-dichloromethane, 1,2-dichloroethane, toluene, N-methylpyrrolidone, and dimethylformamide.

The reaction temperature during condensation is generally 40° C. to 200° C. The 5 reaction time is selected variously depending on the reaction temperature, but is generally about 30 minutes to 50 hours.

The weight average molecular weight Mw of the polymer obtained as above is generally 500 to 1,000,000, or 600 to 200,000.

Examples of polymers having a unit structure of Formula (I) or Formula (I′) are shown below.

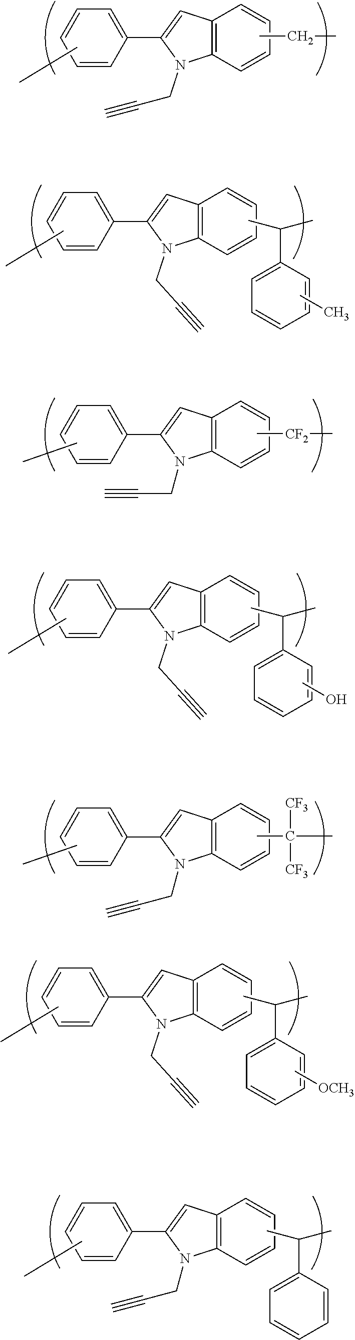

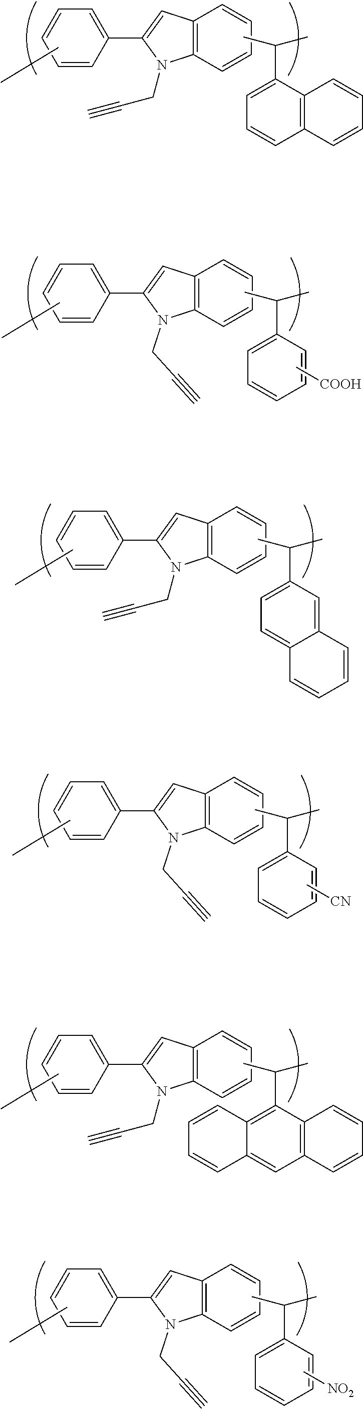

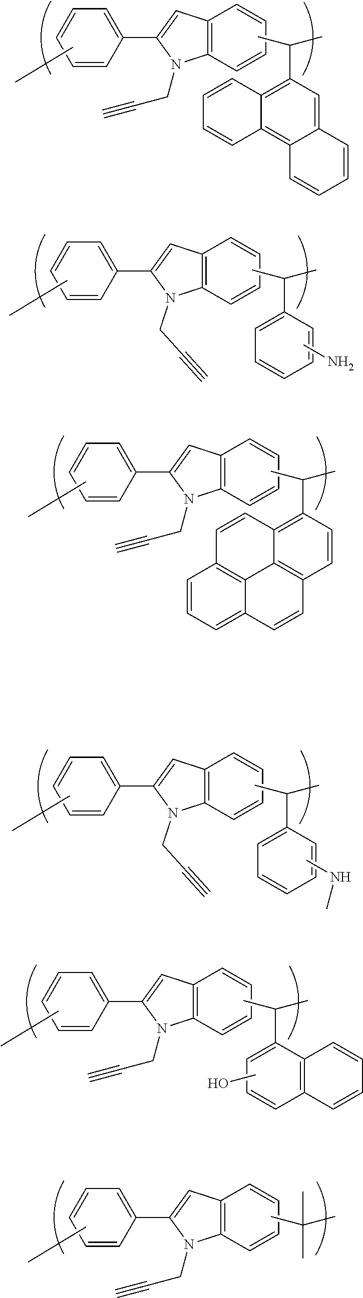

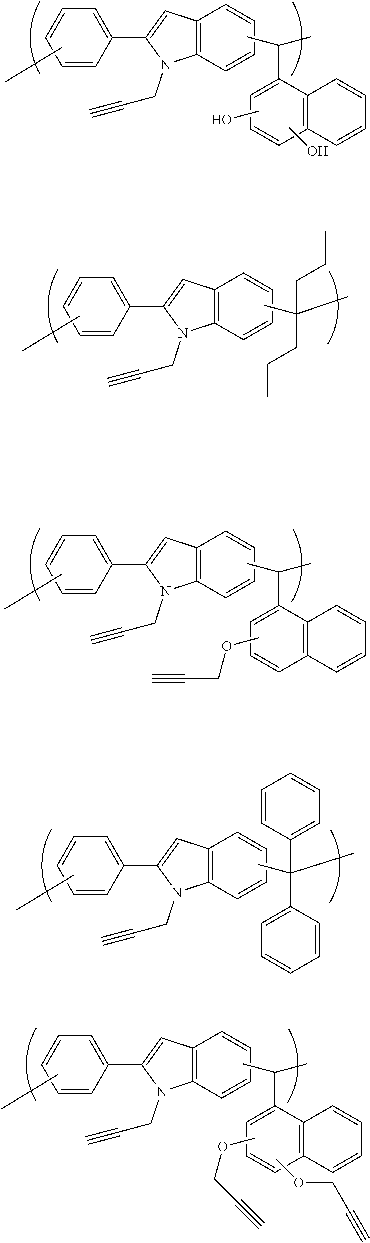

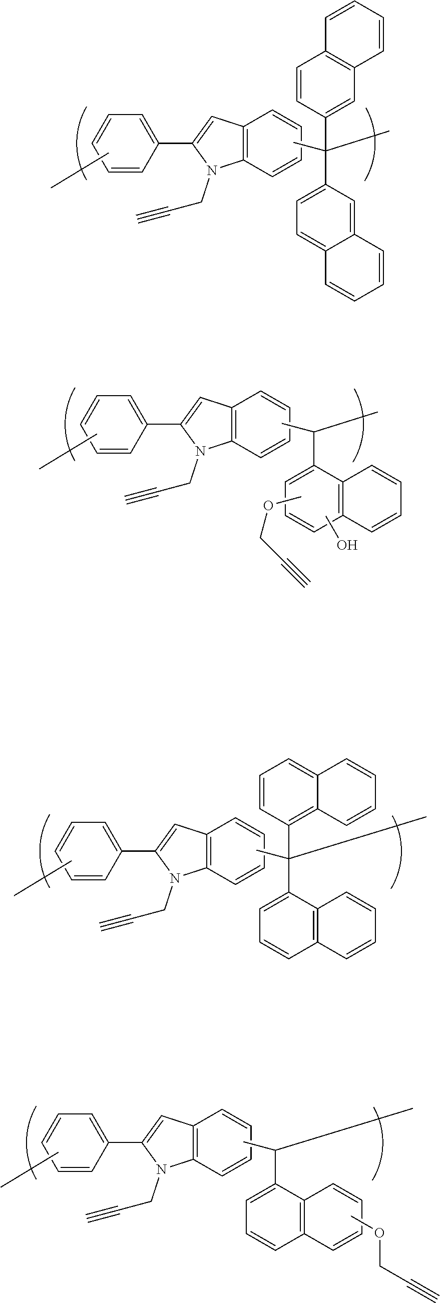

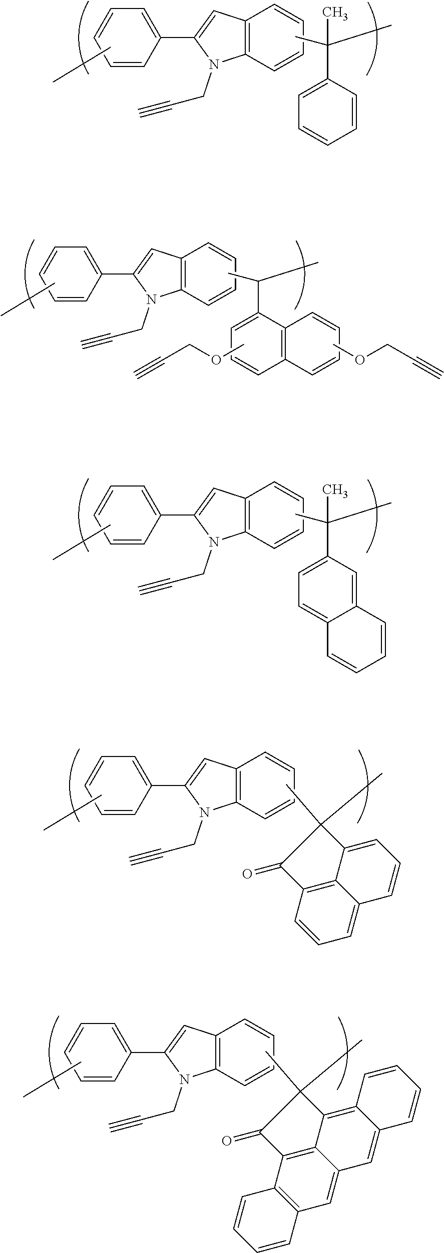

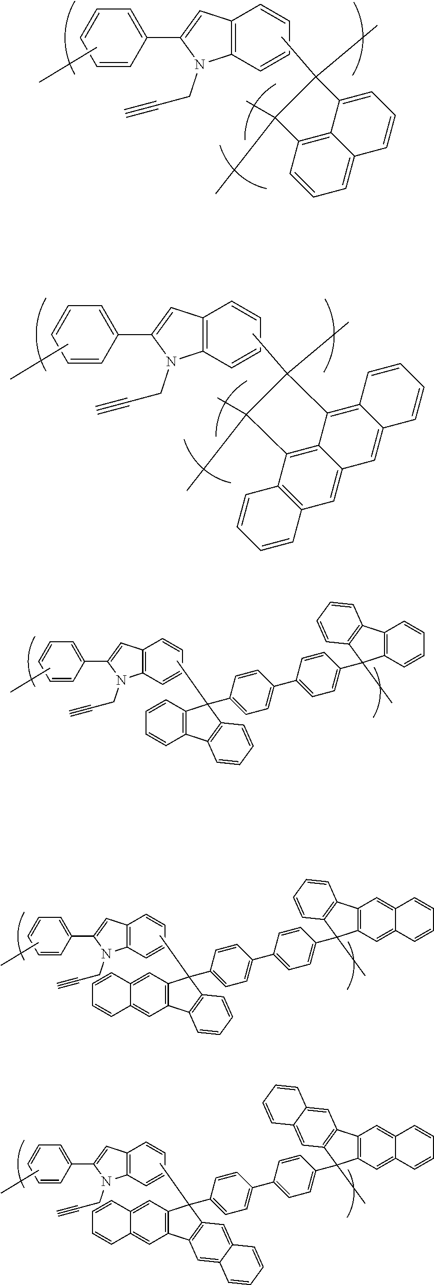

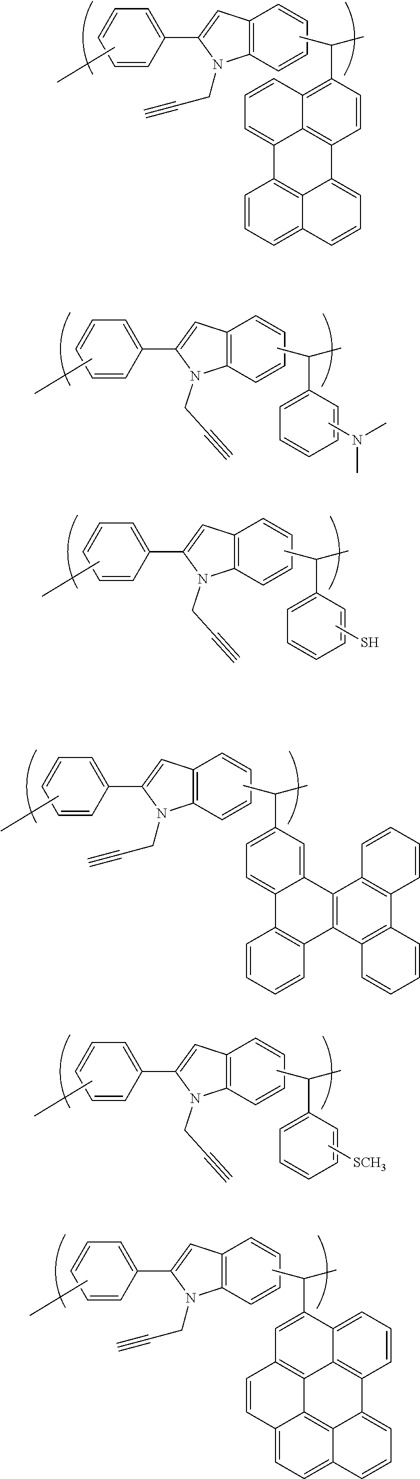

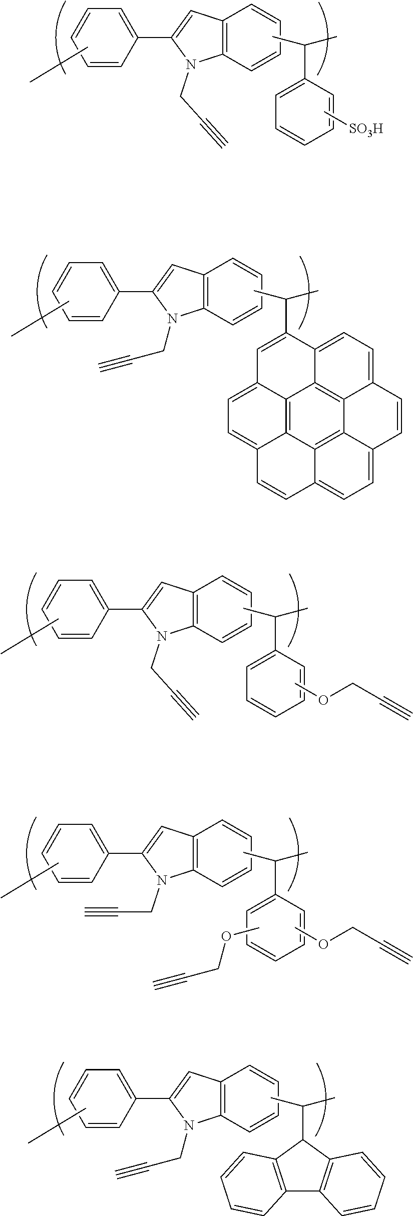

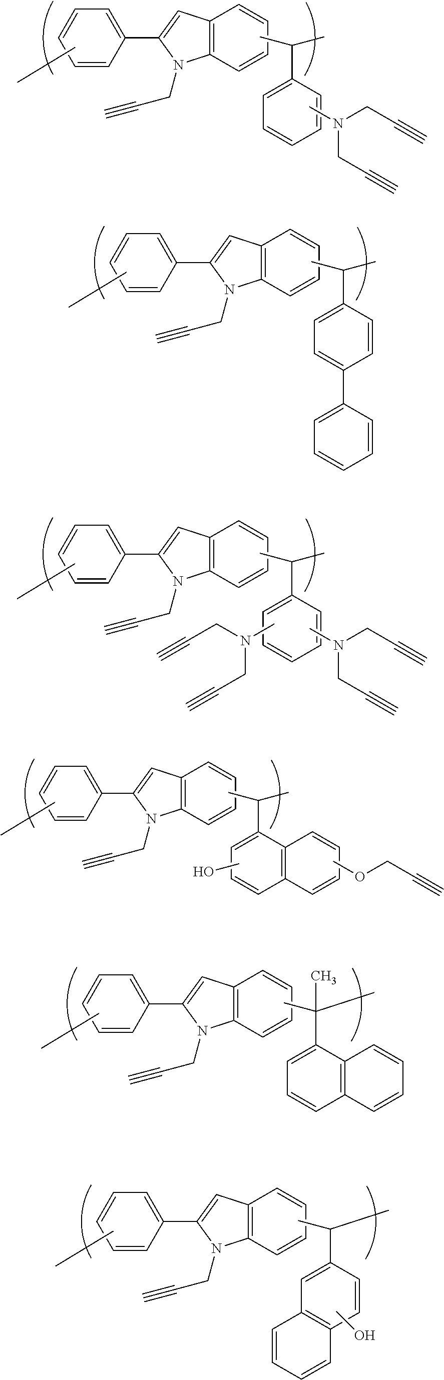

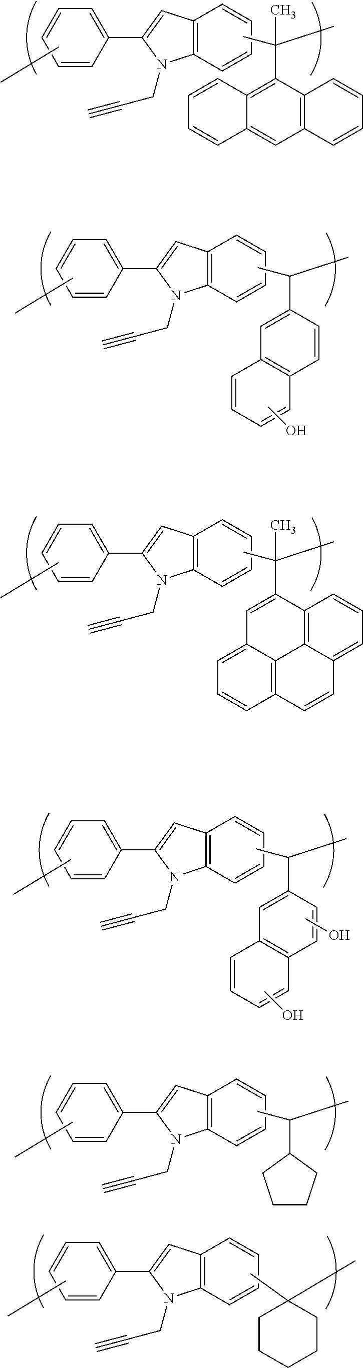

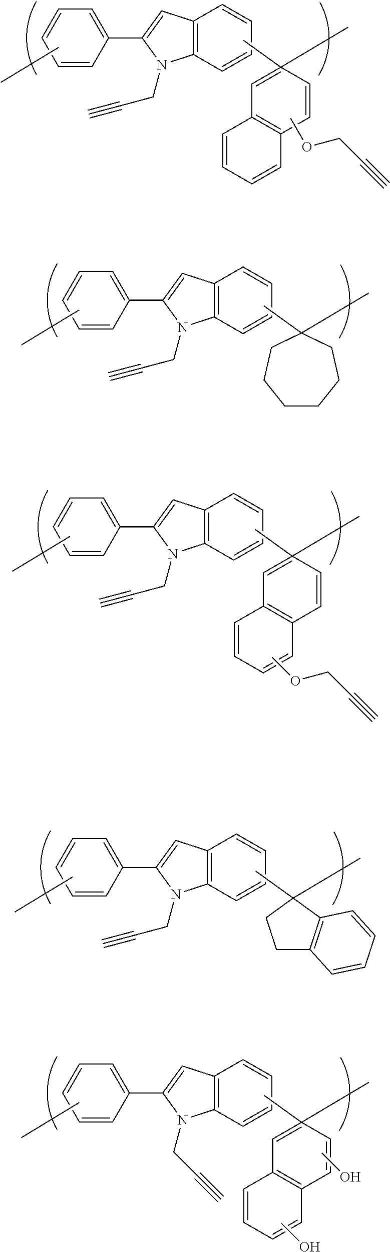

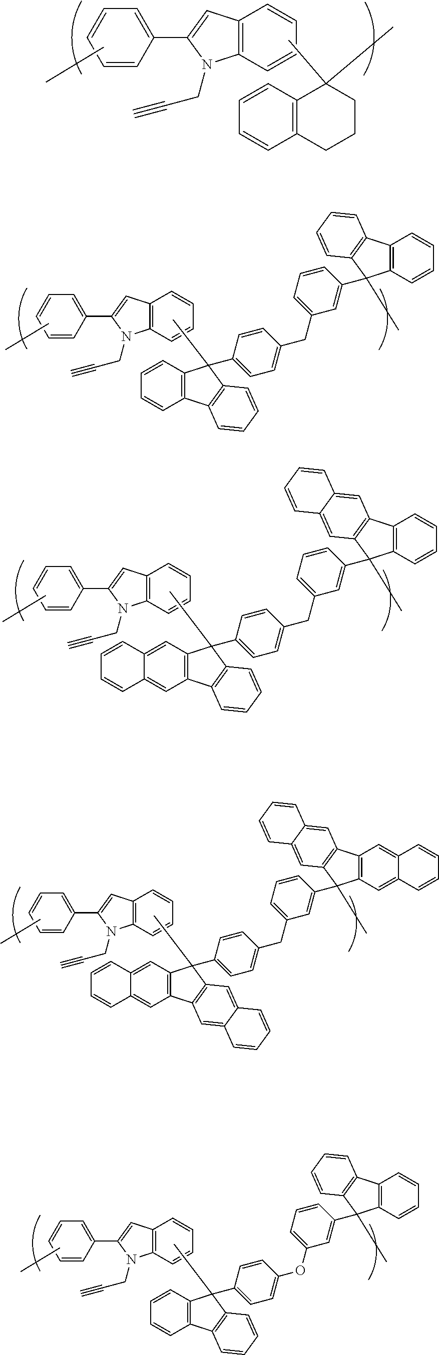

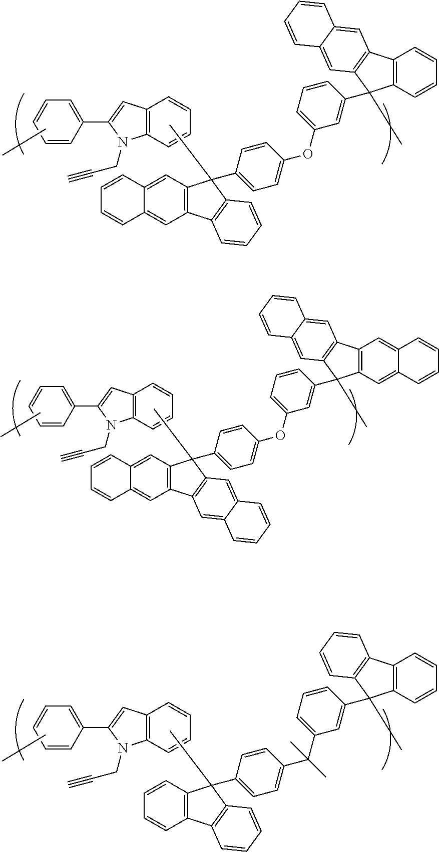

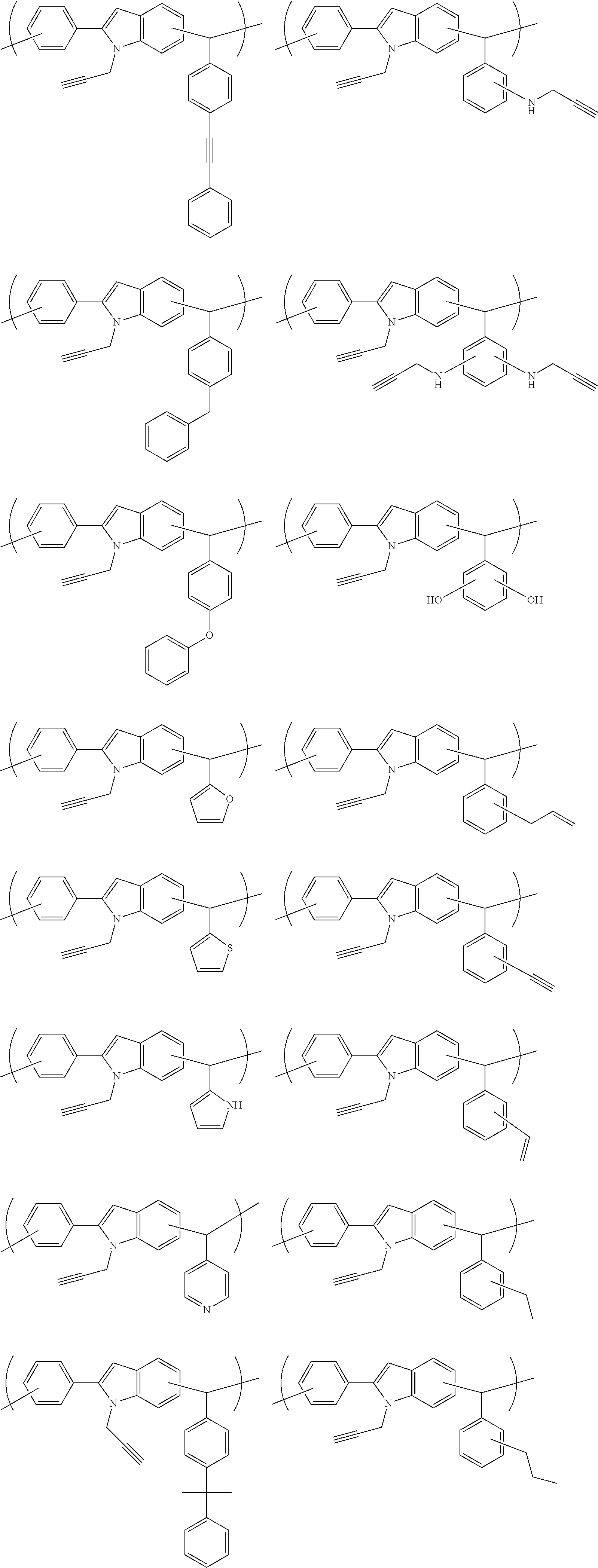

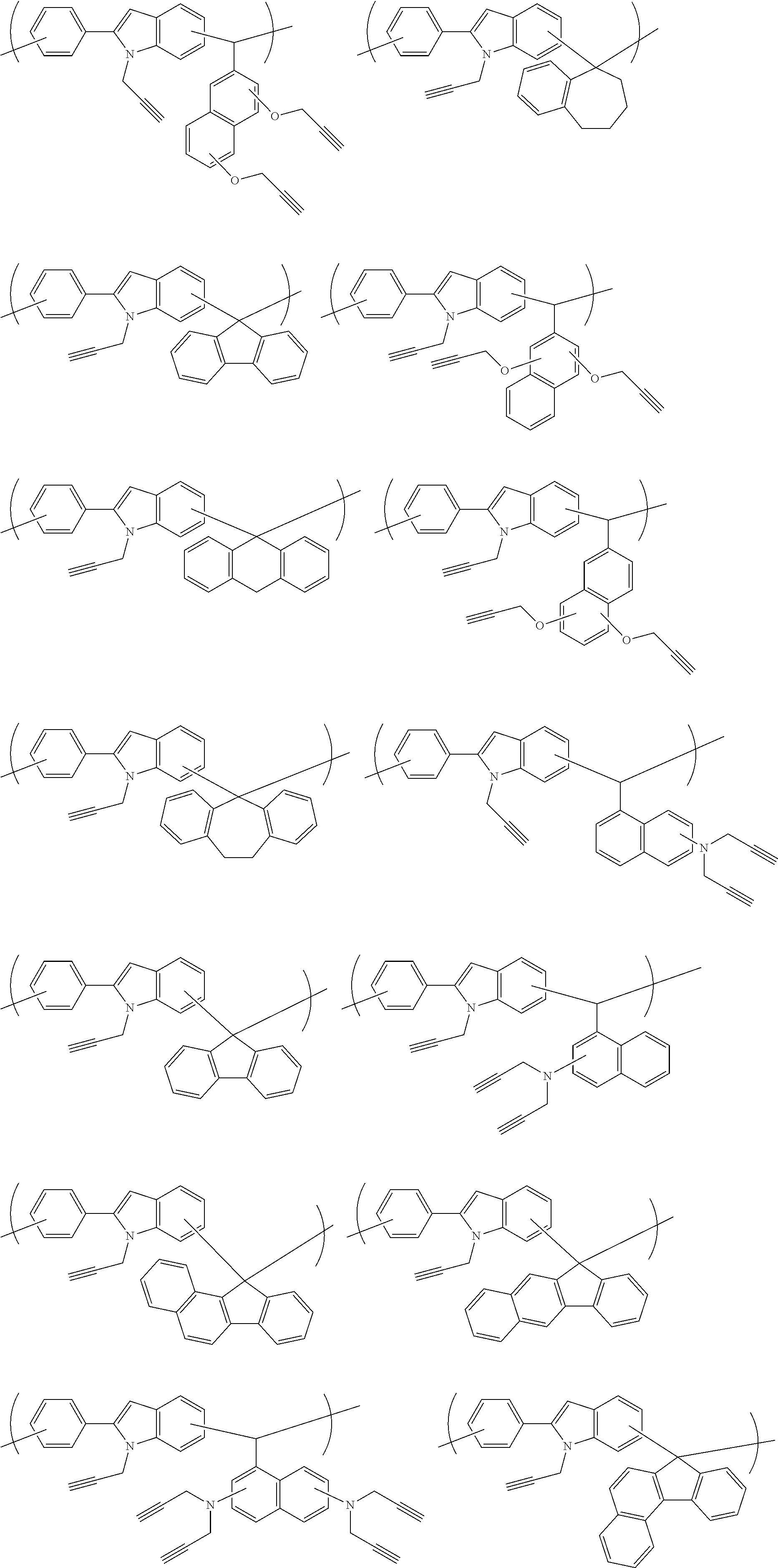

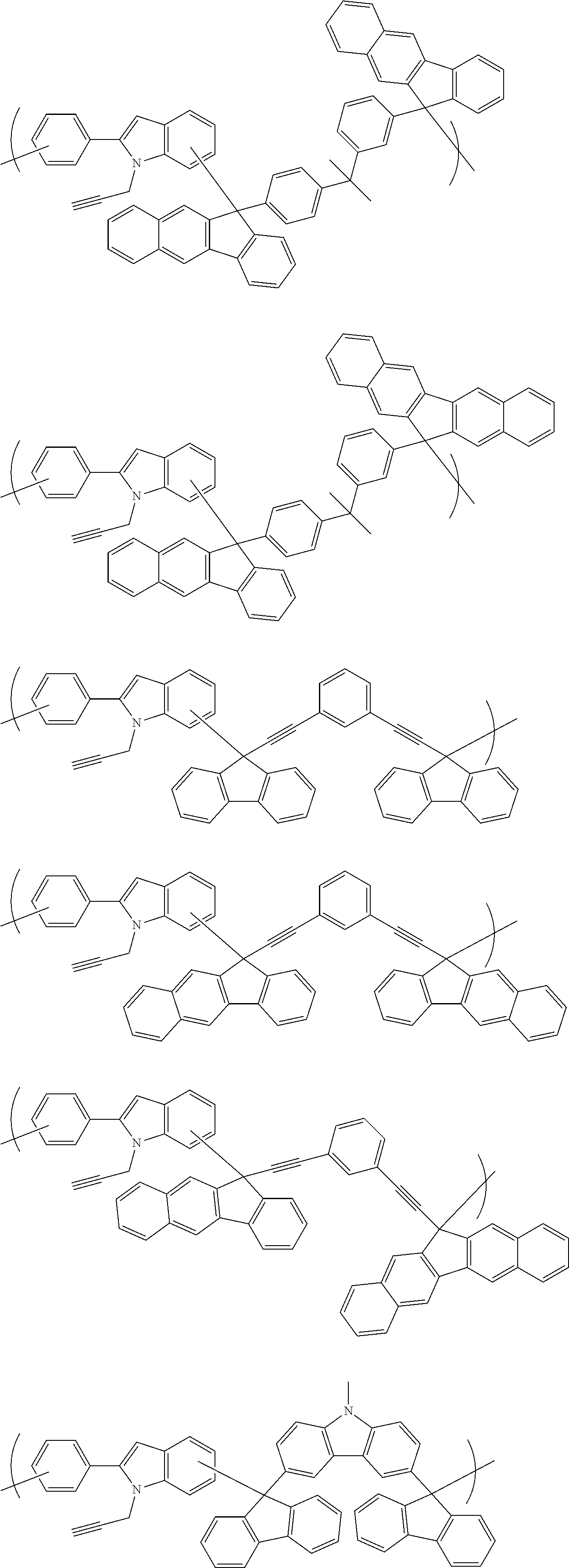

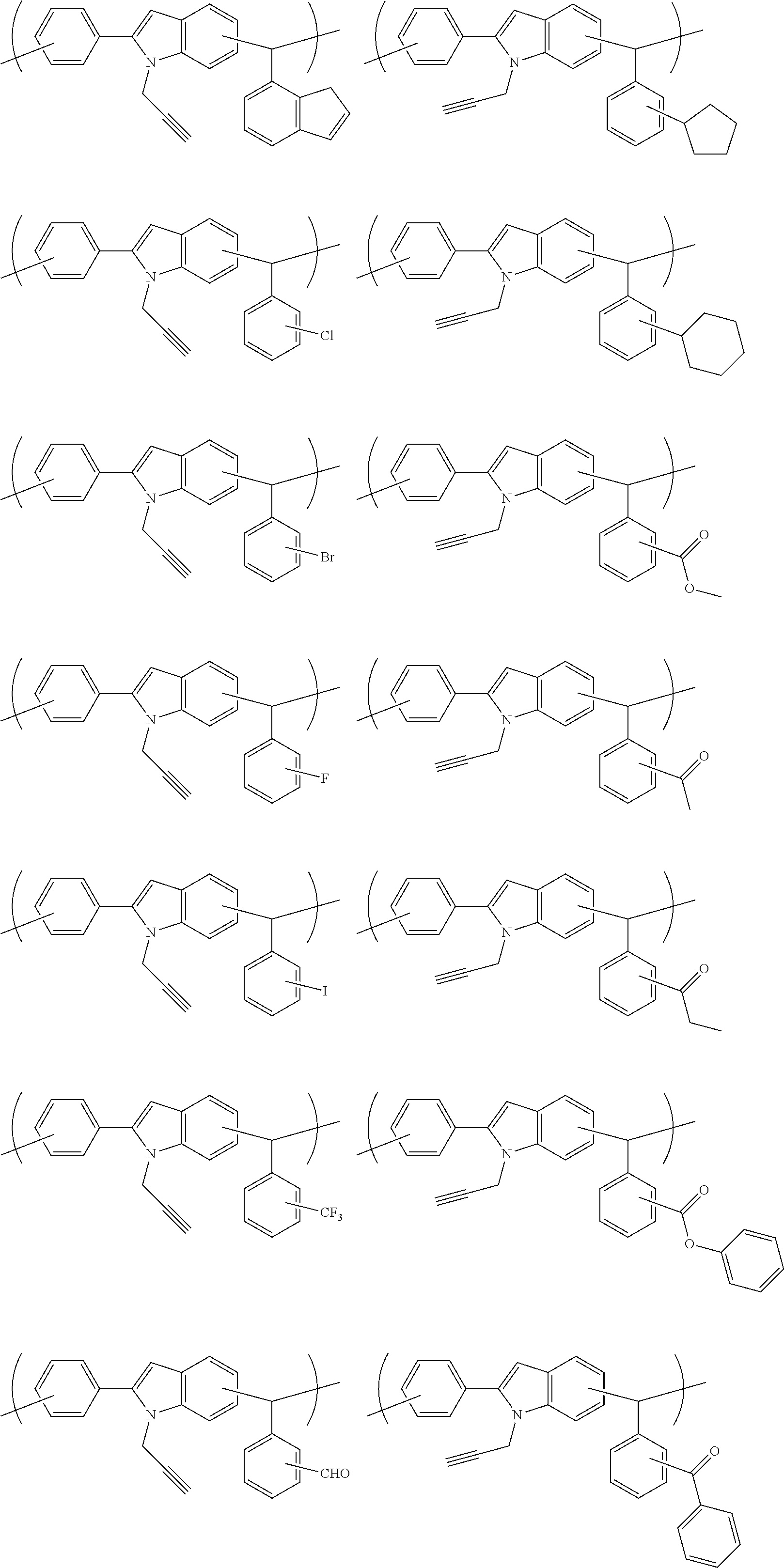

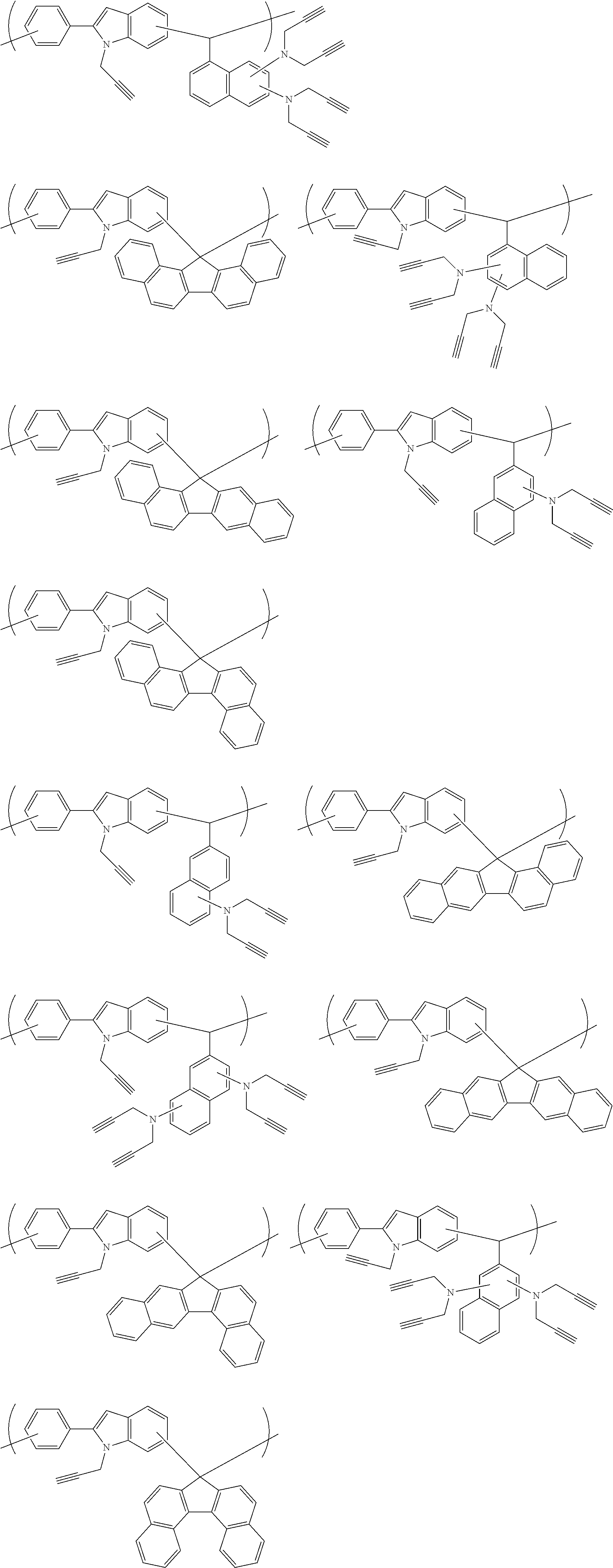

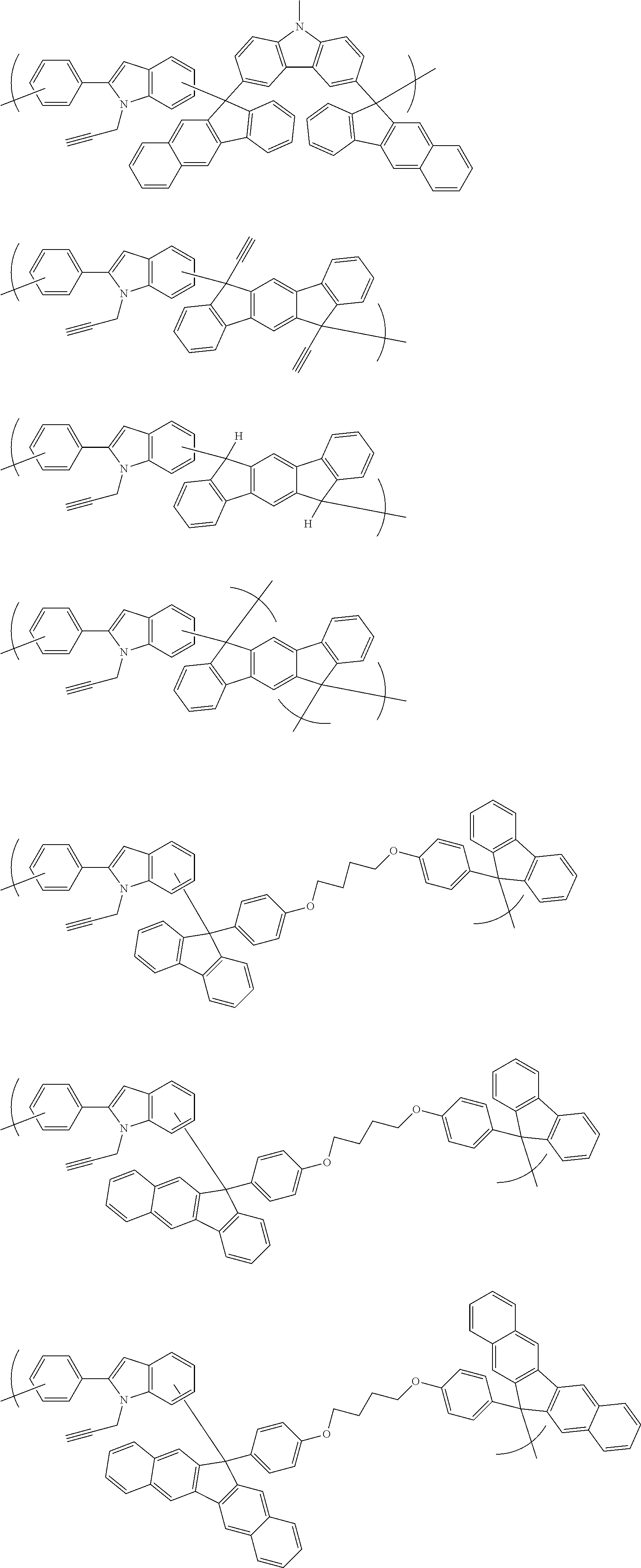

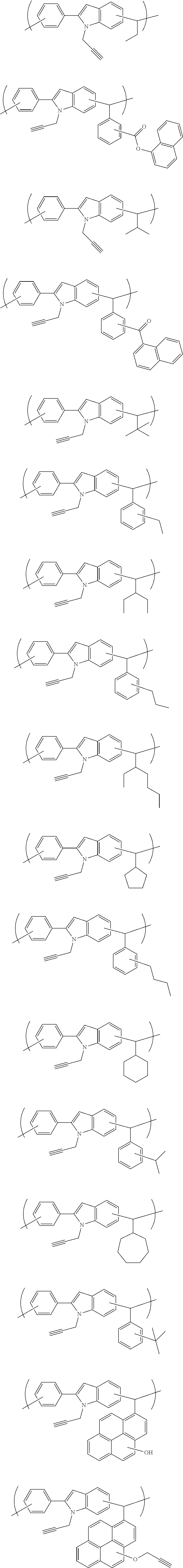

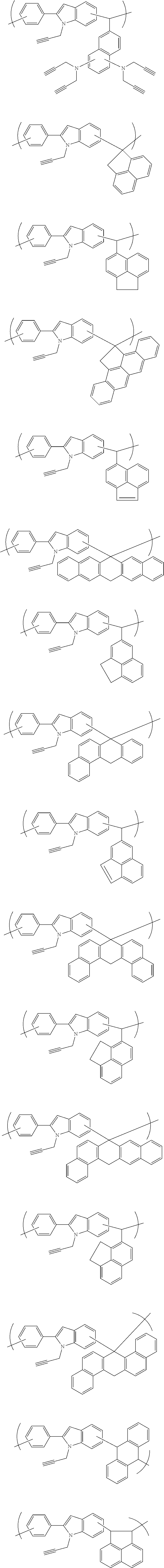

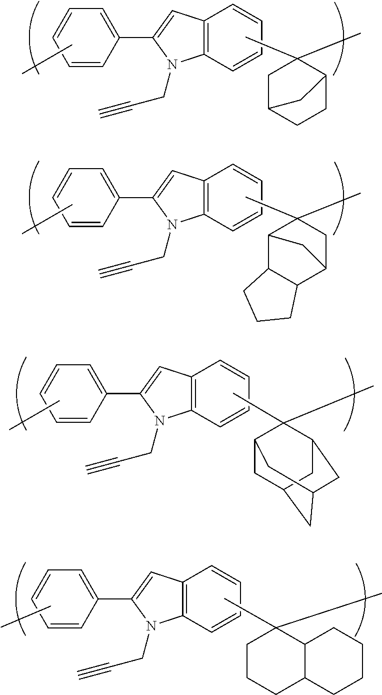

The polymer can be used by mixing other polymers in an amount within 50% by mass based on the total polymer.

Examples of these polymers include polyacrylic acid ester compounds, polymethacrylic acid ester compounds, polyacrylamide compounds, polymethacrylamide compounds, polyvinyl compounds, polystyrene compounds, polymaleimide compounds, polymaleic anhydrides, and polyacrylonitrile compounds.

Examples of raw material monomers for polyacrylic acid ester compounds include methyl acrylate, ethyl acrylate, isopropyl acrylate, benzyl acrylate, naphthyl acrylate, anthryl acrylate, anthryl methyl acrylate, phenyl acrylate, 2-hydroxyethyl acrylate, 2-hydroxypropyl acrylate, 2,2,2-trifluoroethyl acrylate, 4-hydroxybutyl acrylate, isobutyl acrylate, tert-butyl acrylate, cyclohexyl acrylate, isobornyl acrylate, 2-methoxyethyl acrylate, methoxy triethylene glycol acrylate, 2-ethoxyethyl acrylate, tetrahydrofurfuryl acrylate, 3-methoxybutyl acrylate, 2-methyl-2-adamantyl acrylate, 2-ethyl-2-adamantyl acrylate, 2-propyl-2-adamantyl acrylate, 2-methoxybutyl-2-adamantyl acrylate, 8-methyl-8-tricyclodecyl acrylate, 8-ethyl-8-tricyclodecyl acrylate, and 5-acryloyloxy-6-hydroxynorbornene-2-carboxylic-6-lactone.

Examples of raw material monomers for polymethacrylic acid ester compounds include ethyl methacrylate, n-propyl methacrylate, n-pentyl methacrylate, cyclohexyl methacrylate, benzyl methacrylate, naphthyl methacrylate, anthryl methacrylate, anthryl methyl methacrylate, phenyl methacrylate, 2-phenylethyl methacrylate, 2-hydroxyethyl methacrylate, 2-hydroxypropyl methacrylate, 2,2,2-trifluoroethyl methacrylate, 2,2,2-trichloroethyl methacrylate, methyl acrylate, isobutyl methacrylate, 2-ethylhexyl methacrylate, isodecyl methacrylate, n-lauryl methacrylate, n-stearyl methacrylate, methoxy diethylene glycol methacrylate, methoxy polyethylene glycol methacrylate, tetrahydrofurfuryl methacrylate, isobornyl methacrylate, tert-butyl methacrylate, isostearyl methacrylate, n-butoxyethyl methacrylate, 3-chloro-2-hydroxypropyl methacrylate, 2-methyl-2-adamantyl methacrylate, 2-ethyl-2-adamantyl methacrylate, 2-propyl-2-adamantyl methacrylate, 2-methoxybutyl-2-adamantyl methacrylate, 8-methyl-8-tricyclodecyl methacrylate, 8-ethyl-8-tricyclodecyl methacrylate, 5-methacryloyloxy-6-hydroxynorbornene-2-carboxylic-6-lactone, and 2,2,3,3,4,4,4-heptafluorobutyl methacrylate.

Examples of acrylamide compounds include acrylamide, N-methylacrylamide, N-ethylacrylamide, N-benzylacrylamide, N-phenylacrylamide, and N,N-dimethylacrylamide.

Examples of raw material monomers for polymethacrylamide compounds include methacrylamide, N-methylmethacrylamide, N-ethylmethacrylamide, N-benzylmethacrylamide, N-phenylmethacrylamide, and N,N-dimethylmethacrylamide.

Examples of raw material monomers for polyvinyl compounds include vinyl ether, methyl vinyl ether, benzyl vinyl ether, 2-hydroxyethyl vinyl ether, phenyl vinyl ether, and propyl vinyl ether.

Examples of raw material monomers for polystyrene compounds include styrene, methylstyrene, chlorostyrene, bromostyrene, and hydroxystyrene.

Examples of raw material monomers for polymaleimide compounds include maleimide, N-methylmaleimide, N-phenylmaleimide, and N-cyclohexylmaleimide.

These polymers can be produced by dissolving an addition polymerizable monomer and a chain transfer agent (10% or less based on the mass of the monomers) added as necessary in an organic solvent, then adding a polymerization initiator to cause a polymerization reaction, and then adding a polymerization terminator. The amount of the polymerization initiator added is 1 to 10% based on the mass of the monomers, and the amount of the polymerization terminator added is 0.01 to 0.2% by mass. Examples of organic solvents used include propylene glycol monomethyl ether, propylene glycol monopropyl ether, ethyl lactate, cyclohexanone, methyl ethyl ketone, and dimethylformamide, examples of chain transfer agents include dodecanethiol and dodecylthiol, examples of polymerization initiators include azobisisobutyronitrile and azobiscyclohexanecarbonitrile, and examples of polymerization terminators include 4-methoxyphenol. The reaction temperature is appropriately selected within 30 to 100° C., and the reaction time is appropriately selected within 1 to 48 hours.

### [Solvent]

The resist underlayer film-forming composition according to the present invention contains a solvent. The solvent is not particularly limited as long as it can dissolve a compound containing an aromatic ring and an optional component added as necessary. Particularly, since the resist underlayer film-forming composition according to the present invention is used in a uniform solution state, in consideration of its coating performance, it is recommended to use it in combination with a solvent that is generally used in a lithography step.

Examples of such solvents include methyl cellosolve acetate, ethyl cellosolve acetate, propylene glycol, propylene glycol monomethyl ether, propylene glycol monoethyl ether, propylene glycol monopropyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, methyl 2-hydroxyisobutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol, and γ-butyrolactone. These solvents can be used alone or two or more thereof can be used in combination.

Among these, propylene glycol monomethyl ether, propylene glycol monoethyl ether, propylene glycol monopropyl ether, propylene glycol monomethyl ether acetate, propylene glycol monoethyl ether acetate, propylene glycol monopropyl ether acetate, ethyl lactate, cyclohexanone, and methyl 2-hydroxyisobutyrate are more preferable, and propylene glycol monomethyl ether, and propylene glycol monomethyl ether acetate are still more preferable.

In addition, the composition may contain a solvent having a boiling point of 160° C. or higher. For example, the following compounds described in WO2018/131562A1 can be used.

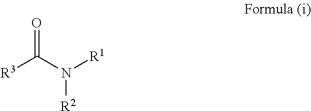

(in Formula (i), each of R¹, R² and R³ is a hydrogen atom or a C₁₋₂₀ alkyl group that may be interrupted by an oxygen atom, a sulfur atom, or an amide bond, may be identical to or different from one another, and may be bonded together to form a ring structure).

The resist underlayer film-forming composition according to the present invention may contain optional components other than those described above. Hereinafter, respective components will be described.

### [Crosslinking Agent]

The resist underlayer film-forming composition according to the present invention can contain a crosslinking agent. Examples of crosslinking agents include melamine-based agents, substituted urea-based agents and polymers thereof. A crosslinking agent having at least two crosslinkable substituents is preferable, and is a compound such as methoxymethylated glycoluril (for example, tetramethoxymethyl glycoluril), butoxymethylated glycoluril, methoxymethylated melamine, butoxymethylated melamine, methoxymethylated benzoguanamine, butoxymethylated benzoguanamine, methoxymethylated urea, butoxymethylated urea, or methoxymethylated thiourea. In addition, a condensate of these compounds can also be used.

In addition, as the crosslinking agent, a crosslinking agent having a high thermal resistance can be used. As the crosslinking agent having a high thermal resistance, a compound containing a crosslinkable substituent having an aromatic ring (for example, a benzene ring or a naphthalene ring) in the molecule can be preferably used.

The compound may be, for example, a compound having a partial structure of the following Formula (4) or a polymer or oligomer having a repeating unit of the following Formula (5).

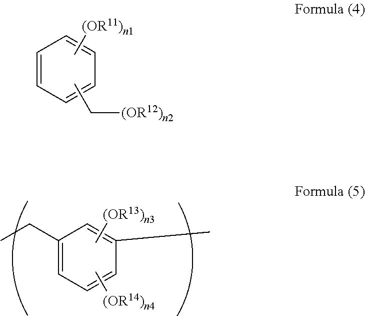

Each of R¹¹, R¹², R¹³, and R¹⁴ is a hydrogen atom or a C₁₋₁₀ alkyl group, and the above examples can be used as these alkyl groups. n1 is an integer of 1 to 4, n2 is an integer of 1 to (5-n1), and (n1+n2) is an integer of 2 to 5. n3 is an integer of 1 to 4, n4 is 0 to (4-n3), and (n3+n4) is an integer of 1 to 4. Each of the oligomer and the polymer may have 2 to 100 or 2 to 50 repeating unit structures.

10 Examples of the compound of Formula (4) and the polymer or oligomer of Formula (5) are shown below.

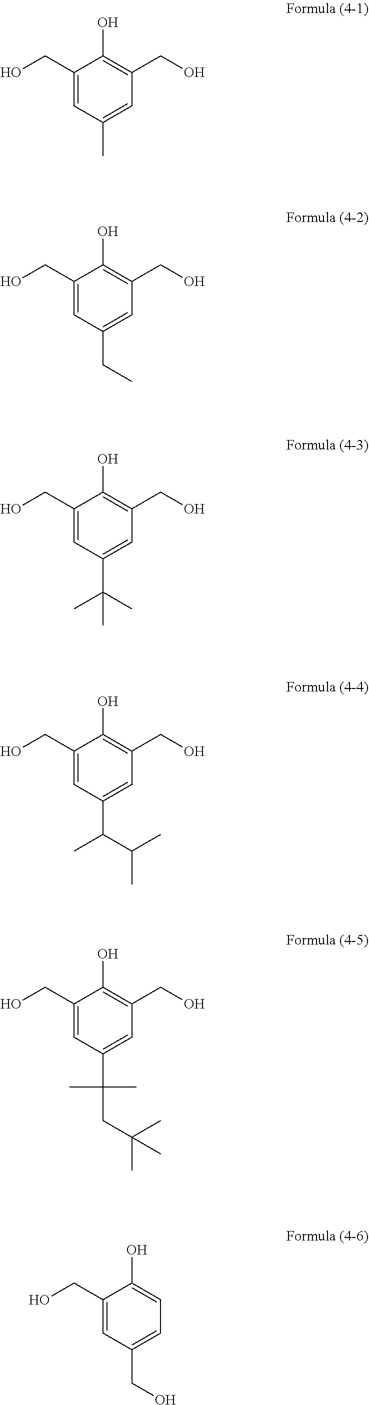 [SMILES: Cc1cc(CO)c(O)c(CO)c1 ; CCc1cc(CO)c(O)c(CO)c1 ; CC(C)(C)c1cc(CO)c(O)c(CO)c1 ; CC(C)C(C)c1cc(CO)c(O)c(CO)c1 ; CC(C)(C)CC(C)(C)c1cc(CO)c(O)c(CO)c1 ; OCc1ccc(O)c(CO)c1]

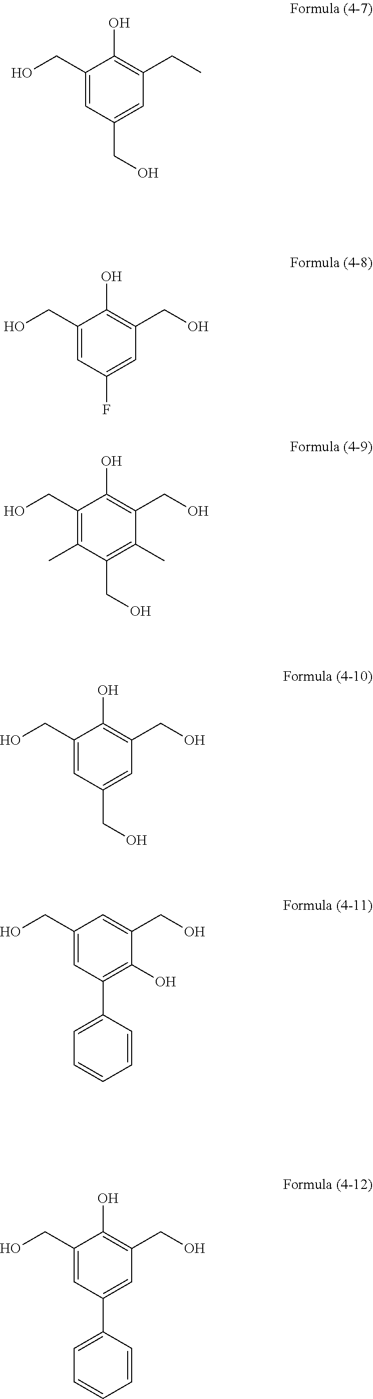 [SMILES: CCc1cc(CO)cc(CO)c1O ; OCc1cc(F)cc(CO)c1O ; Cc1c(CO)c(C)c(CO)c(O)c1CO ; OCc1cc(CO)c(O)c(CO)c1 ; OCc1cc(CO)c(O)c(-c2ccccc2)c1 ; OCc1cc(-c2ccccc2)cc(CO)c1O]

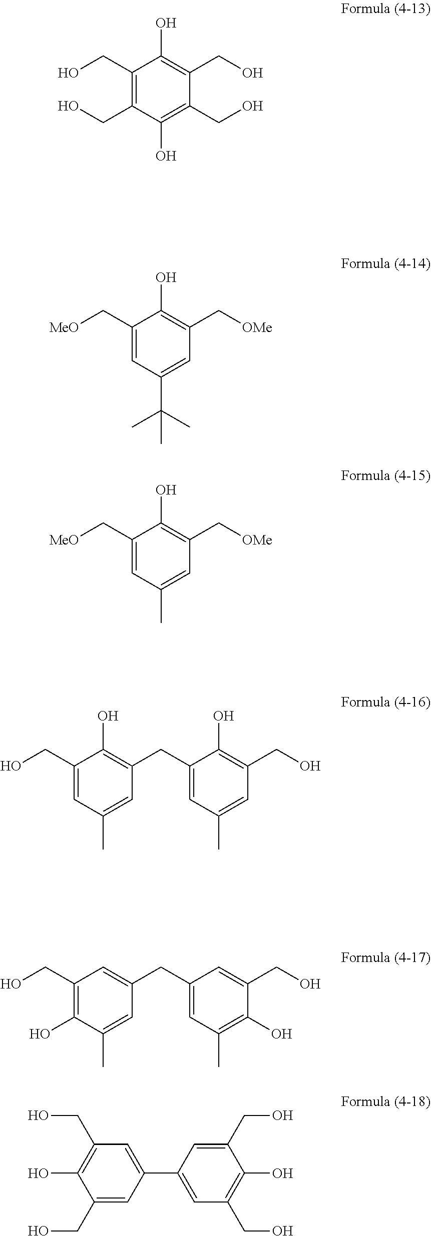

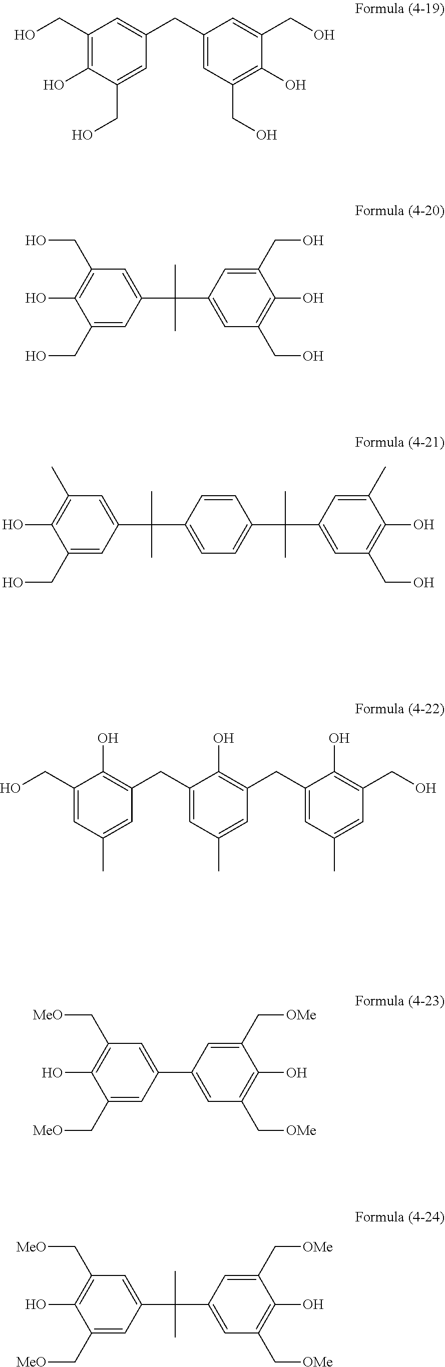 [SMILES: OCc1cc(Cc2cc(CO)c(O)c(CO)c2)cc(CO)c1O ; CC(C)(c1cc(CO)c(O)c(CO)c1)c1cc(CO)c(O)c(CO)c1 ; Cc1cc(C(C)(C)c2ccc(C(C)(C)c3cc(C)c(O)c(CO)c3)cc2)cc(CO)c1O ; Cc1cc(CO)c(O)c(Cc2cc(C)cc(Cc3cc(C)cc(CO)c3O)c2O)c1 ; COCc1cc(-c2cc(COC)c(O)c(COC)c2)cc(COC)c1O ; COCc1cc(C(C)(C)c2cc(COC)c(O)c(COC)c2)cc(COC)c1O]

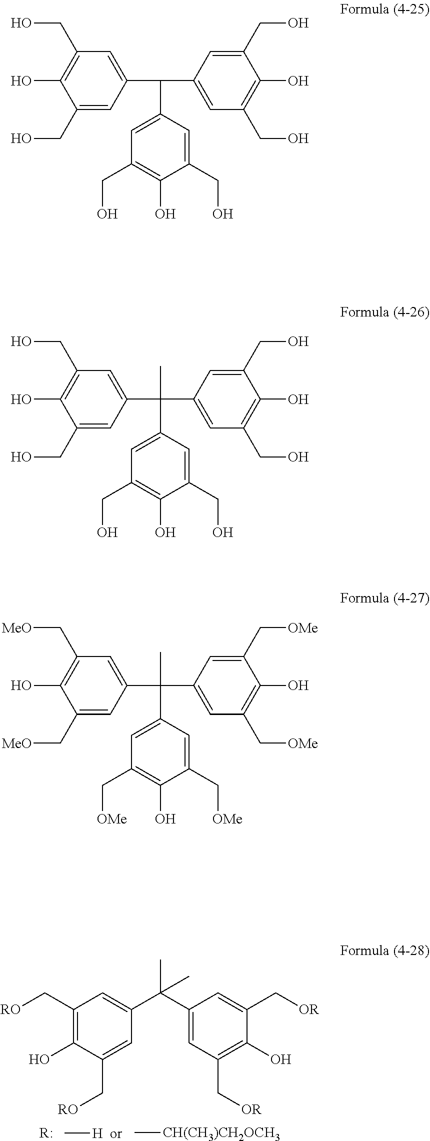

The compounds are available as products (commercially available from Asahi Yukizai Corporation and Honshu Chemical Industry Co., Ltd.). For example, among the crosslinking agents, the compound of Formula (4-23) is available as TMOM-BP (product name, commercially available from Honshu Chemical Industry Co., Ltd.), and the compound of Formula (4-20) is available as TM-BIP-A (product name, commercially available from Asahi Yukizai Corporation).

The amount of the crosslinking agent added varies depending on, for example, the type of a coating solvent used, the type of a substrate used, the viscosity of a solution required, or the shape of a film required and is 0.001% by mass or more, 0.01% by mass or more, 0.05% by mass or more, 0.5% by mass or more, or 1.0% by mass or more, or 80% by mass or less, 50% by mass or less, 40% by mass or less, 20% by mass or less, or 10% by mass or less with respect to a total solid content. These crosslinking agents may cause a crosslinking reaction due to self-condensation, but when crosslinkable substituents are present in the compound containing an aromatic ring of the present invention, a crosslinking reaction with these crosslinkable substituents may occur.

[Acid and/or Salt Thereof and/or Acid Generator]

The resist underlayer film-forming composition according to the present invention can contain an acid and/or a salt thereof and/or an acid generator.

Examples of acids include p-toluenesulfonic acid, trifluoromethanesulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, citric acid, benzoic acid, hydroxybenzoic acid, and naphthalenecarboxylic acid.

As the salt, salts of the above acids can be used. Although the salt is not limited, ammonia derivative salts such as trimethylamine salts and triethylamine salts, pyridine derivative salts, morpholine derivative salts and the like can be suitably used.

Acids and/or salts thereof can be used alone or two or more thereof can be used in combination. The amount added with respect to a total solid content is generally 0.0001 to 20% by mass, preferably 0.0005 to 10% by mass, and more preferably 0.01 to 5% by mass.

Examples of acid generators include thermal acid generators and photoacid generators.

Examples of thermal acid generators include 2,4,4,6-tetrabromocyclohexadienone, benzoin tosylate, 2-nitrobenzyl tosylate, K-PURE [registered trademark] CXC-1612, CXC-1614, TAG-2172, TAG-2179, TAG-2678, TAG2689, and TAG2700 (commercially available from King Industries, Inc.), SI-45, SI-60, SI-80, SI-100, SI-110, and SI-150 (commercially available from Sanshin Chemical Industry Co., Ltd.), and other organic sulfonic acid alkyl esters.

The photoacid generator generates an acid during the exposure of a resist. Therefore, the acidity of an underlayer film can be adjusted. This is one method for adjusting the acidity of an underlayer film to the acidity of a resist serving as an upper layer of the underlayer film. In addition, when the acidity of the underlayer film is adjusted, it is possible to adjust the pattern shape of the resist formed above the underlayer film.

Examples of photoacid generators contained in the resist underlayer film-forming composition of the present invention include onium salt compounds, sulfonimide compounds, and disulfonyldiazomethane compounds.

Examples of onium salt compounds include iodonium salt compounds such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphorsulfonate, bis(4-tert-butylphenyl) iodonium camphorsulfonate and bis(4-tert-butylphenyl) iodonium trifluoromethanesulfonate, and sulfonium salt compounds such as triphenylsulfonium hexafluoroantimonate, triphenylsulfonium nonafluoro-n-butanesulfonate, triphenylsulfonium camphorsulfonate and triphenylsulfonium trifluoromethanesulfonate.

Examples of sulfonimide compounds include N-(trifluoromethanesulfonyloxy) succinimide, N-(nonafluoro-n-butanesulfonyloxy) succinimide, N-(camphorsulfonyloxy) succinimide and N-(trifluoromethanesulfonyloxy) naphthalimide.

Examples of disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The acid generators can be used alone or two or more thereof can be used in combination.

When an acid generator is used, the proportion thereof with respect to 100 parts by mass of the solid content of the resist underlayer film-forming composition is 0.01 to 10 parts by mass, 0.1 to 8 parts by mass, or 0.5 to 5 parts by mass.

### [Other Components]

The resist underlayer film-forming composition according to the present invention can contain a surfactant for further improving the applicability of the composition to an uneven surface without causing, for example, pinholes or striations. Examples of surfactants include nonionic surfactants, for example, polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octylphenol ether, and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine-based surfactants such as EFTOP EF301, EF303, and EF352 (product name, commercially available from Tohkem Products Corporation), Megaface F171, F173, R-40, R-40N, and R-40 LM (product name, commercially available from DIC Corporation), Fluorad FC430, and FC431 (product name, commercially available from Sumitomo 3M Limited), AsahiGuard AG710, Surflon S-382, SC101, SC102, SC103, SC104, SC105, and SC106 (product name, commercially available from Asahi Glass Co., Ltd.), and organosiloxane polymer KP341 (commercially available from Shin-Etsu Chemical Co., Ltd.). The amount of these surfactants added with respect to a total solid content of the resist underlayer film-forming composition is generally 2.0% by mass or less and preferably 1.0% by mass or less. These surfactants may be used alone or two or more thereof may be used in combination. When a surfactant is used, the proportion thereof with respect to 100 parts by mass of the solid content of the resist underlayer film-forming composition is 0.0001 to 5 parts by mass, 0.001 to 1 part by mass, or 0.01 to 0.5 parts by mass.

The resist underlayer film-forming composition according to the present invention can contain a light-absorbing agent, a rheology controlling agent, an adhesion aid, etc. The rheology controlling agent is effective for improving the fluidity of the underlayer film-forming composition. The adhesion aid is effective for improving the adhesion between a semiconductor substrate or a resist and an underlayer film.

Preferred examples of the light-absorbing agent include commercially available light-absorbing agents described in “Kogyoyo Shikiso no Gijutsu to Shijo (Technology and Market of Industrial Colorant)” (CMC Publishing Co., Ltd.) and “Senryo Binran (Dye Book)” (edited by The Society of Synthetic Organic Chemistry, Japan), such as C. I. Disperse Yellow 1, 3, 4, 5, 7, 8, 13, 23, 31, 49, 50, 51, 54, 60, 64, 66, 68, 79, 82, 88, 90, 93, 102, 114, and 124; C. I. Disperse Orange 1, 5, 13, 25, 29, 30, 31, 44, 57, 72, and 73; C. I. Disperse Red 1, 5, 7, 13, 17, 19, 43, 50, 54, 58, 65, 72, 73, 88, 117, 137, 143, 199, and 210; C. I. Disperse Violet 43; C. I. Disperse Blue 96; C. I. Fluorescent Brightening Agent 112, 135, and 163; C. I. Solvent Orange 2 and 45; C. I. Solvent Red 1, 3, 8, 23, 24, 25, 27, and 49; C. I. Pigment Green 10; and C. I. Pigment Brown 2. The light-absorbing agent is added in a proportion of generally 10% by mass or less and preferably 5% by mass or less with respect to a total solid content of the resist underlayer film-forming composition.

The rheology controlling agent is added for the main purpose of improving the fluidity of the resist underlayer film-forming composition; in particular, the purpose of improving the thickness uniformity of a resist underlayer film or improving filling of the interior of a hole with the resist underlayer film-forming composition in a baking step. Specific examples thereof include phthalic acid derivatives such as dimethyl phthalate, diethyl phthalate, diisobutyl phthalate, dihexyl phthalate, and butyl isodecyl phthalate, adipic acid derivatives such as di-n-butyl adipate, diisobutyl adipate, diisooctyl adipate, and octyldecyl adipate, maleic acid derivatives such as di-n-butyl maleate, diethyl malate, and dinonyl maleate, oleic acid derivatives such as methyl oleate, butyl oleate, and tetrahydrofurfuryl oleate and stearic acid derivatives such as n-butyl stearate and glyceryl stearate. These rheology controlling agents are added in a proportion of generally less than 30% by mass with respect to a total solid content of the resist underlayer film-forming composition.

The adhesion aid is added for the main purpose of improving the adhesion between a substrate or a resist and the resist underlayer film-forming composition; in particular, the purpose of preventing peeling of the resist during development. Specific examples thereof include chlorosilanes such as trimethylchlorosilane, dimethylmethylolchlorosilane, methyldiphenylchlorosilane, and chloromethyldimethylchlorosilane, alkoxysilanes such as trimethylmethoxysilane, dimethyldiethoxysilane, methyldimethoxysilane, dimethylmethylolethoxysilane, diphenyldimethoxysilane, and phenyltriethoxysilane, silazanes such as hexamethyldisilazane, N,N′-bis(trimethylsilyl) urea, dimethyltrimethylsilylamine, and trimethylsilylimidazole, silanes such as methyloltrichlorosilane, γ-chloropropyltrimethoxysilane, γ-aminopropyltriethoxysilane, and γ-glycidoxypropyltrimethoxysilane, heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine, urea or thiourea compounds, such as 1,1-dimethylurea and 1,3-dimethylurea. These adhesive aids are added in a proportion of generally less than 5% by mass and preferably less than 2% by mass with respect to a total solid content of the resist underlayer film-forming composition.

The solid content of the resist underlayer film-forming composition according to the present invention is generally 0.1 to 70% by mass and preferably 0.1 to 60% by mass. The solid content is the content of all components excluding the solvent from the resist underlayer film-forming composition. The proportion of the compound containing an aromatic ring in the solid content is 1 to 100% by mass, 1 to 99.9% by mass, 50 to 99.9% by mass, 50 to 95% by mass, or 50 to 90% by mass (preferably in this order).

The resist used in the present invention is a photoresist or an electron beam resist.

Either a negative type or positive type photoresist can be used as the photoresist applied to the upper part of the resist underlayer film for lithography according to the present invention, and examples thereof include a positive-type photoresist composed of a novolac resin and 1,2-naphthoquinone diazide sulfonic acid ester, a chemically amplified photoresist composed of a binder having a group that decomposes with an acid and increases the alkaline dissolution rate and a photoacid generator, a chemically amplified photoresist composed of an alkali-soluble binder, a low-molecular-weight compound that decomposes with an acid and increases the alkaline dissolution rate of a photoresist, and a photoacid generator, a chemically amplified photoresist composed of a binder having a group that decomposes with an acid and increases the alkaline dissolution rate, a low-molecular-weight compound that decomposes with an acid and increases the alkaline dissolution rate of a photoresist, and a photoacid generator, and a photoresist having Si atoms in the skeleton, and for example, APEX-E (product name, commercially available from Rohm and Haas Company) can be used.

In addition, regarding the electron beam resist to be applied to the upper part of the resist underlayer film for lithography in the present invention, for example, a composition including a resin containing an Si—Si bond in the main chain and an aromatic ring at the end and an acid generator that generates an acid when an electron beam is irradiated or a composition including poly(p-hydroxystyrene) in which a hydroxyl group is substituted with an organic group containing N-carboxyamine and an acid generator that generates an acid when an electron beam is irradiated may be used. In the latter electron beam resist composition, an acid generated from the acid generator when an electron beam is irradiated, reacts with the N-carboxyaminooxy group on the polymer side chain, the polymer side chain decomposes into a hydroxyl group, becomes alkali-soluble, and dissolves in an alkaline developer, and a resist pattern is formed. Examples of acid generators that generate an acid when an electron beam is irradiated, include halogenated organic compounds such as 1,1-bis [p-chlorophenyl]-2,2,2-trichloroethane, 1,1-bis [p-methoxyphenyl]-2,2,2-trichloroethane, 1,1-bis [p-chlorophenyl]-2,2-dichloroethane, and 2-chloro-6-(trichloromethyl)pyridine, onium salts such as triphenylsulfonium salts and diphenyliodonium salts, and sulfonic acid esters such as nitrobenzyl tosylate and dinitrobenzyl tosylate.

As the developer for the resist having the resist underlayer film formed using the resist underlayer film material for lithography of the present invention, for example, inorganic alkalis such as sodium hydroxide, potassium hydroxide, sodium carbonate, sodium silicate, sodium metasilicate, and ammonia water, primary amines such as ethylamine and n-propylamine, secondary amines such as diethylamine and di-n-butylamine, tertiary amines such as triethylamine and methyl diethylamine, alcohol amines such as dimethylethanolamine and triethanolamine, quaternary ammonium salts such as tetramethylammonium hydroxide, tetraethylammonium hydroxide, and choline, and cyclic amines such as pyrrole and piperidine can be used. In addition, the aqueous solution of alkalis to which appropriate amounts of alcohols such as isopropyl alcohol and nonionic surfactants are added, can be used. Among these, the developer is preferably quaternary ammonium salts, and more preferably tetramethylammonium hydroxide and choline.

Next, a method of forming a resist pattern of the present invention will be described. A resist underlayer film-forming composition is applied onto a substrate used in the production of precisely integrated circuit devices (for example, a silicon wafer substrate, a silicon dioxide substrate (SiO₂ substrate), a silicon nitride substrate (SiN substrate), a silicon oxynitride substrate (SiON substrate), a titanium nitride substrate (TiN substrate), a tungsten substrate (W substrate), a glass substrate, an ITO substrate, a polyimide substrate, and a substrate coated with low-dielectric-constant material (low-k material)) by an appropriate coating method with, for example, a spinner or a coater, and then baked and cured to prepare a coating type underlayer film. Baking conditions are appropriately selected from among air or an inert gas atmosphere such as nitrogen or argon, a baking temperature of 80° C. to 600° C., and a baking time of 0.3 to 60 minutes. Preferably, the baking temperature is 150° C. to 400° C., and the baking time is 0.5 to 2 minutes. Here, the film thickness of the underlayer film formed is, for example, 10 to 1,000 nm, 20 to 500 nm, 30 to 400 nm, or 50 to 300 nm. Then, a favorable resist pattern can be obtained by directly applying a resist onto a resist underlayer film or by forming one or several coating material layers on a coating type underlayer film as necessary and applying the resist, irradiating light or an electron beam through a predetermined mask, and performing developing, rinsing, and drying. As necessary, after the light or electron beam exposure, baking (post exposure bake: PEB) can be performed. Then, the resist underlayer film in the portion in which the resist has been developed and removed in the step is removed by dry etching, and a desired pattern can be formed on the substrate.

The exposure light for the photoresist is actinic ray such as near ultraviolet, far ultraviolet, or extreme ultraviolet (for example, EUV, wavelength: 13.5 nm), and for example, light with a wavelength of 248 nm (KrF laser light), 193 nm (ArF laser light), 157 nm (F₂ laser light) or the like is used. For light irradiation, any method can be used without particular limitation as long as an acid can be generated from a photoacid generator, and the exposure amount is 1 to 2,000 mJ/cm², 10 to 1,500 mJ/cm², or 50 to 1,000 mJ/cm².

In addition, an electron beam is irradiated to an electron beam resist, and for example, an electron beam irradiation device can be used for irradiation.

In the present invention, a semiconductor device can be produced through a step of forming a resist underlayer film on a semiconductor substrate from the resist underlayer film-forming composition, a step of forming a resist film on the formed underlayer film, a step of forming a resist pattern by irradiating the formed resist film with light or an electron beam and developing the resist film, a step of etching the resist underlayer film using the formed resist pattern, and a step of processing the semiconductor substrate with the patterned resist underlayer film.

In the present invention, after the resist underlayer film of the present invention is formed on a substrate, the resist can be applied onto the resist underlayer film directly or after one or several coating material layers are formed on the resist underlayer film as necessary. This process can narrow the pattern width of the resist. Thus, even when the resist is applied thinly for preventing a pattern collapse, the substrate can be processed through selection of an appropriate etching gas.

That is, a semiconductor device can be produced through a step of forming a resist underlayer film on a semiconductor substrate from a resist underlayer film-forming composition, a step of forming a hard mask (for example, silicon oxynitride) using a coating material containing a silicon component and the like or a hard mask by vapor deposition on the formed resist underlayer film, a step of additionally forming a resist film on the formed hard mask, a step of forming a resist pattern by irradiating the formed resist film with light or an electron beam and developing the resist film, a step of etching the hard mask with a halogen gas using the resist pattern, a step of etching the resist underlayer film with an oxygen gas or hydrogen gas using the patterned hard mask, and a step of processing the semiconductor substrate with a halogen gas using the patterned resist underlayer film.

As resist patterns become finer, there is a demand for thinner resists. Therefore, a process in which not only the resist pattern but also the resist underlayer film formed between the resist and the semiconductor substrate to be processed can function as a mask during substrate processing, has become required. This process is a lithography process in which at least two resist underlayer film layers are formed, and the resist underlayer film is used as a mask material. Examples of materials for forming the at least two layers include organic resins (for example, acrylic resins, novolac resins, polyester resins, polyether resins, PEEK resins, and maleimide resins), organic compounds (for example, amorphous carbon), silicone resins (for example, organopolysiloxane), and inorganic silicon compounds (for example, SiON, SiO₂, and SiN). When dry etching is performed with the pattern formed from the organic layer as a mask, an excellent etching resistance with respect to an etching gas (for example, fluorocarbons and oxygen) is exhibited. In addition, due to the diversity of semiconductor producing processes, the resist underlayer film for such processes not only has the above properties, but also has favorable coating properties with a small film thickness difference for various layouts in stepped substrates (flattening properties), embedding properties for fine patterns, and sufficient curing properties under a nitrogen atmosphere. In addition, such a resist underlayer film can have an ability to effectively adsorb reflected light from the substrate when irradiated light with a wavelength of 248 nm, 193 nm, 157 nm, or the like is used for fine processing and also can have a function of conventional anti-reflective coating.

In consideration of the effect of the anti-reflective coating, since the resist underlayer film-forming composition for lithography of the present invention has light absorbing moieties incorporated into the skeleton, there is no material diffused into the photoresist during heating and drying and the light absorbing moieties have a sufficiently high light absorption ability, and thus a high effect of preventing reflected light can be obtained.

The resist underlayer film-forming composition for lithography of the present invention has a high thermal stability, can prevent contamination on an upper layer film caused by decomposition products during baking, and allows a temperature margin in the baking step.

In addition, the resist underlayer film composition for lithography of the present invention can be used depending on processing conditions, as a film having a function of preventing light reflection and also having a function of preventing interaction between the substrate and the photoresist or preventing adverse effects on the substrate, of materials used in the photoresist or substances generated during the exposure of the photoresist to light.

The step of forming the resist underlayer film can be performed by a nanoimprinting method. The method includes a step of applying a curable composition onto the formed resist underlayer film, a step of bringing the curable composition into contact with a mold, a step of irradiating light or an electron beam to the curable composition to form a cured film, and a step of separating the cured film from the mold.

### EXAMPLES

Hereinafter, the present invention will be described in more detail with reference to synthesis examples, examples and comparative examples, but the present invention is not limited to the following examples.

### [Synthesis of Polymer]

As polymers used for resist underlayer films, the following compound group A, compound group B, compound group C, catalyst group D, solvent group E, and reprecipitation solvent group F were used to synthesize Structural Formulae (S1) to (S25) and synthesize Structural Formulae (S′1) to (S′25) as comparative examples.

### (Compound Groups A to C)

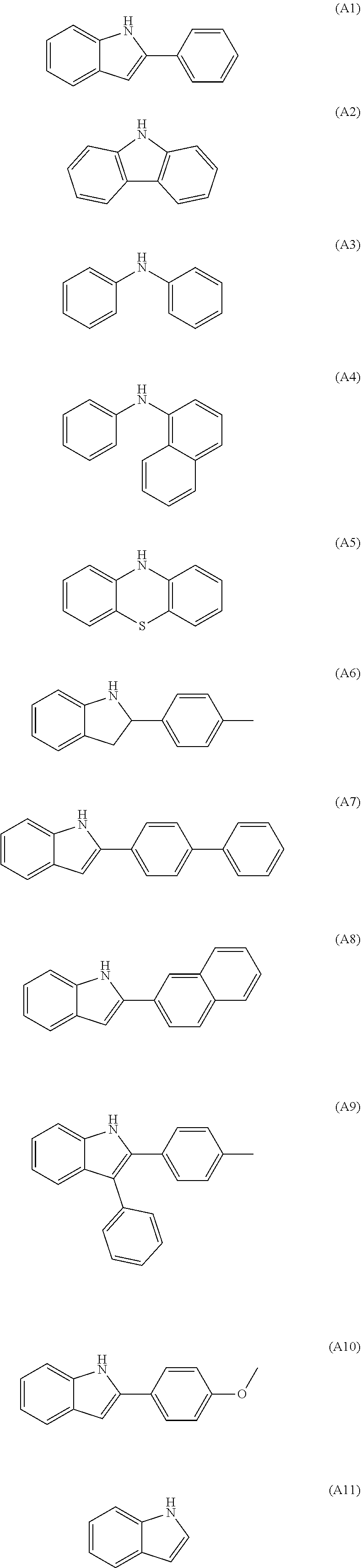

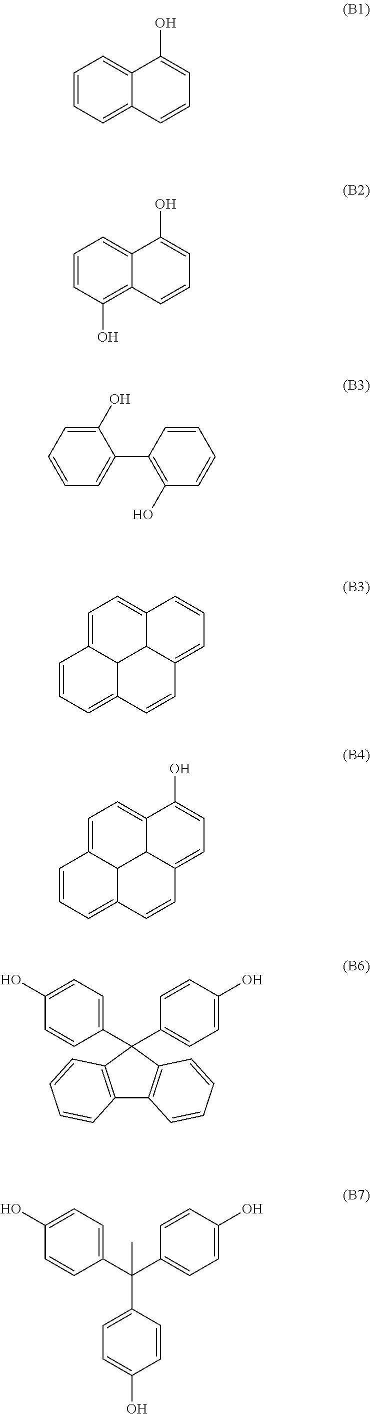

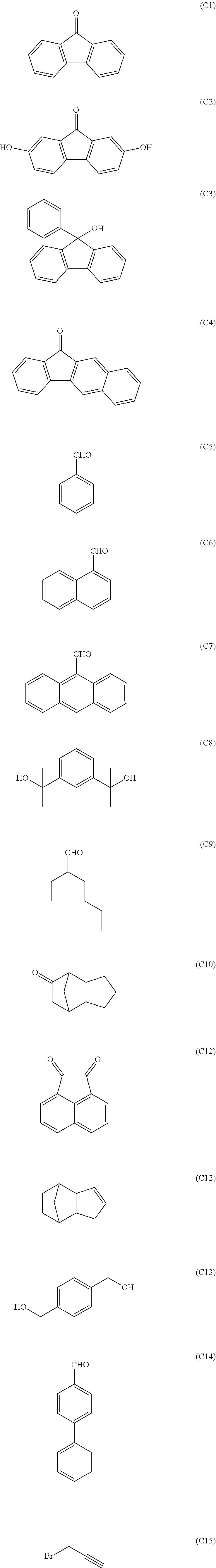

### (Catalyst Group D)

methanesulfonic acid: D1
3-mercaptopropionic acid: D2
5 tetrabutylammonium iodide: D3

### (Solvent Group E)

propylene glycol monomethyl ether acetate (=PGMEA): E1
N-methylpyrrolidone: E2
tetrahydrofuran: E3
aqueous sodium hydroxide solution: E4

### (Reprecipitation Solvent Group F)

methanol: F1
methanol/water: F2

### (Phase Separation Solvent Group G)

butyl acetate/water: G1

### Synthesis Example 1

50.0 g of phenylindole (A1), 46.7 g of 9-fluorenone (C1), 12.5 g of methanesulfonic acid (D1), and 109.1 g of PGMEA (E1) were put into a flask. Then, the mixture was heated to reflux under nitrogen and reacted for about 16 hours. After the reaction was stopped, the mixture was reprecipitated with methanol (G1) and dried to obtain a resin (S′1). The weight average molecular weight Mw measured by GPC in terms of polystyrene was about 1,400. The obtained resin was dissolved in PGMEA, and ion exchange was performed using a cation exchange resin and an anion exchange resin for 4 hours to obtain a desired compound solution.

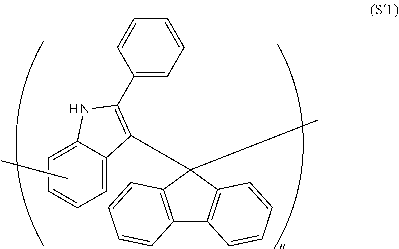

Here, the weight average molecular weight of the polymer was the result measured through gel permeation chromatography (hereinafter abbreviated as GPC). For the measurement, a GPC device (commercially available from Tosoh Corporation) was used, and measurement conditions and the like are as follows.
Device: HLC-8320 GPC (commercially available from Tosoh Corporation)
GPC column: TSKgel Super-MultiporeHZ-N (two columns)
Column temperature: 40° C.
Flow rate: 0.35 ml/min
Eluent: THF
Standard sample: polystyrene

### Synthesis Examples 2 to 25

Polymers used for resist underlayer films were synthesized by changing the compound group A, the compound group B, the compound group C, the catalyst group D, the solvent group E, and the reprecipitation solvent group F. Here, an experimental operation was the same as in Synthesis Example 1. Synthesis was performed under the following conditions, and Comparative Example Polymers (S′2) to (S′25) and their solutions were obtained.

TABLE 1

| Synthesis | Structural | | | | Temperature/ | | Molecular |
|---|---|---|---|---|---|---|---|
| Example | Formula | Compound | Catalyst | Solvent | time | Reprecipitation | weight |
| 1 | S′1 | A1/C1 | D1 | E1 | Reflux/ | F1 | 1400 |
| | | 50.0 g/46.9 g | 12.5 g | 109.1 g | 16 hours | | |
| 2 | S′2 | A1/C5 | D1 | E1 | Reflux/ | F1 | 1000 |
| | | 17.0 g/9.3 g | 4.2 g | 71.3 g | 2 hours | | |
| 3 | S′3 | A1/C6 | D1 | E1 | Reflux/ | F1 | 1000 |
| | | 15.0 g/12.1 g | 3.7 g | 72.0 g | 2 hours | | |
| 4 | S′4 | A1/C7 | D1 | E1 | Reflux/ | F1 | 1500 |
| | | 18.0 g/19.2 g | 1.8 g | 91.0 g | 2 hours | | |
| 5 | S′5 | A1/C1/C2 | D1/D2 | E1 | 80° C./ | F1 | 1900 |
| | | 16.0 g/7.5 g/ | 8.0 g/0.9 g | 95.9 g | 4.5 hours | | |
| | | 8.8 g | | | | | |
| 6 | S′6 | A1/C1/C3 | D1/D2 | E1 | 80° C./ | F1 | 1000 |
| | | 16.0 g/11.7 g/ | 7.8 g/0.9 g | 94.6 g | 6 hours | | |
| | | 4.2 g | | | | | |
| 7 | S′7 | A1/C1/C4 | D1/D2 | E1 | 80° C./ | F1 | 1300 |
| | | 16.0 g/11.2 g/ | 8.0 g/0.9 g | 95.2 g | 24 hours | | |
| | | 4.8 g | | | | | |
| 8 | S′8 | A1/C8 | D1 | E1 | 100° C./ | F2 | 3000 |
| | | 18.0 g/18.1 g | 2.7 g | 90.5 g | 16 hours | | |
| 9 | S′9 | A1/C9 | D1/D2 | E1 | 100° C./ | F1 | 1100 |
| | | 20.0 g/13.3 g | 10.0 g/1.1 g | 64.8 g | 24 hours | | |
| 10 | S′10 | A1/C10 | D1/D2 | E1 | 100° C./ | F1 | 700 |
| | | 18.0 g/14.0 g | 9.0 g/1.0 g | 61.4 g | 24 hours | | |
| 11 | S′11 | A1/C11 | D1 | E1 | 120° C./ | F1 | 1400 |
| | | 20.0 g/18.9 g | 1.0 g | 93.0 g | 24 hours | | |
| 12 | S′12 | A1/A2/C1 | D1 | E1 | 150° C./ | F1 | 900 |
| | | 25.0 g/9.3 g/ | 6.2 g | 95.7 g | 24 hours | | |
| | | 23.3 g | | | | | |
| 13 | S′13 | A1/B2/C1 | D1 | E1 | 150° C./ | F1 | 1100 |
| | | 25.0 g/8.8 g/ | 6.2 g | 95.2 g | 24 hours | | |
| | | 23.3 g | | | | | |
| 14 | S′14 | A1/A4/C1 | D1 | E1 | 150° C./ | F1 | 1100 |
| | | 25.0 g/12.2 g/ | 6.2 g | 100.0 g | 24 hours | | |
| | | 23.3 g | | | | | |
| 15 | S′15 | A1/B6/C1 | D1 | E1 | 150° C./ | F1 | 1200 |
| | | 25.0 g/19.4 g/ | 6.2 g | 110.9 g | 24 hours | | |
| | | 23.3 g | | | | | |
| 16 | S′16 | A1/B3/C1 | D1 | E1 | 150° C./ | F1 | 900 |
| | | 25.0 g/10.3 g/ | 6.2 g | 97.3 g | 24 hours | | |
| | | 23.3 g | | | | | |
| 17 | S′17 | A1/A3/C1 | D1 | E1 | 150° C./ | F1 | 1300 |
| | | 25.0 g/9.4 g/ | 6.2 g | 95.9 g | 24 hours | | |
| | | 23.3 g | | | | | |
| 18 | S′18 | A1/A5/C1 | D1 | E1 | 150° C./ | F1 | 1300 |
| | | 25.0 g/11.1 g/ | 6.2 g | 98.4 g | 24 hours | | |
| | | 23.3 g | | | | | |
| 19 | S′19 | A1/B1/C1 | D1 | E1 | 150° C./ | F1 | 1100 |
| | | 25.0 g/8.0 g/ | 6.2 g | 93.8 g | 24 hours | | |
| | | 23.3 g | | | | | |
| 20 | S′20 | A1/B5/C1/C12 | D1 | E1 | 150° C./ | F1 | 1100 |
| | | 25.0 g/7.1 g/ | 7.8 g | 80.4 g | 24 hours | | |
| | | 23.3 g/3.9 g | | | | | |
| 21 | S′21 | A1/C1/C13/C14 | D1 | E1 | 150° C./ | F1 | 2700 |
| | | 25.0 g/20.7 g/ | 8.3 g | 94.8 g | 24 hours | | |
| | | 4.0 g/5.2 g | | | | | |
| 22 | S′22 | A1/B4/B7/C1 | D1 | E1/E2 | 150° C./ | F1 | 1000 |
| | | 25.0 g/5.2 g/ | 7.5 g | 83.6 g/ | 24 hours | | |
| | | 4.0 g/28.0 g | | 20.9 g | | | |
| 23 | S′23 | A1/A6/A8/C1 | D1/D2 | E1 | 80° C./ | F1 | 900 |
| | | 15.0 g/1.6 g/ | 7.5 g/0.8 g | 95.1 g | 17 hours | | |
| | | 1.9 g/14.0 g | | | | | |
| 24 | S′24 | A1/A7/A9/C1 | D1/D2 | E1 | 80° C./ | F1 | 1000 |
| | | 14.2 g/2.0 g/ | 7.1 g/0.8 g | 91.6 g | 17 hours | | |
| | | 2.0 g/13.2 g | | | | | |
| 25 | S′25 | A1/A10/A11/C1 | D1/D2 | E1 | 80° C./ | F1 | 1100 |
| | | 15.0 g/14.0 g/ | 7.5 g/0.8 g | 93.1 g | hours | | |
| | | 1.7 g/0.9 g | | | | | |

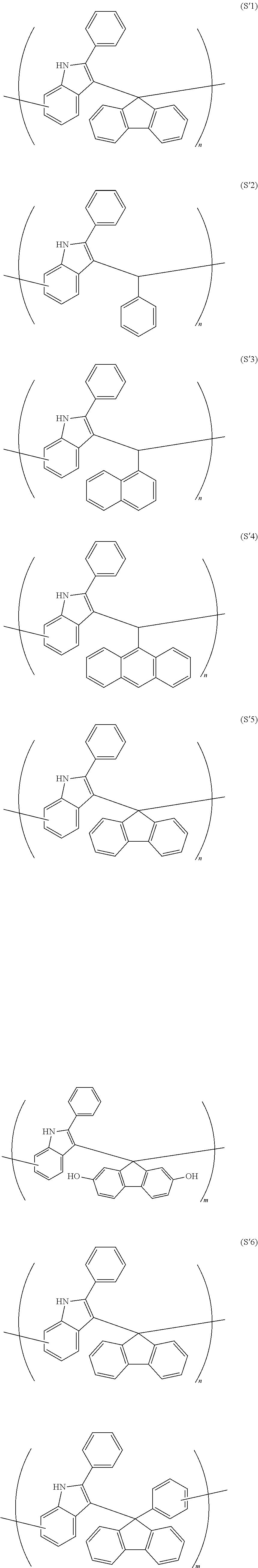

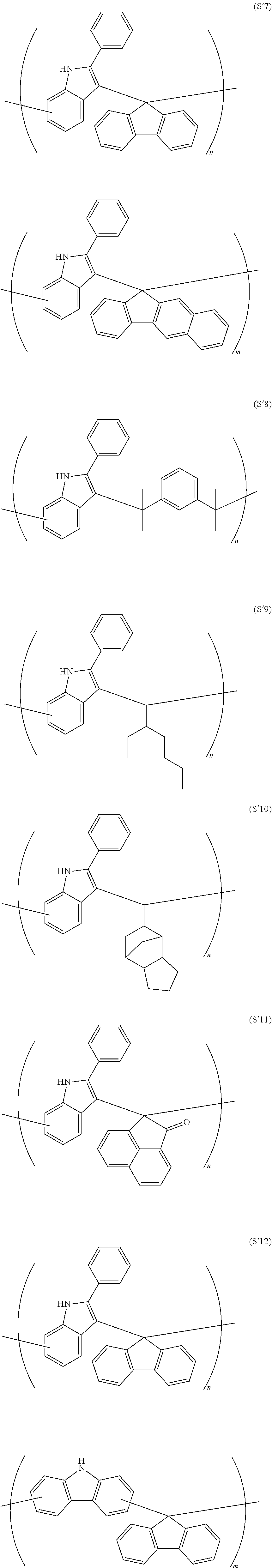

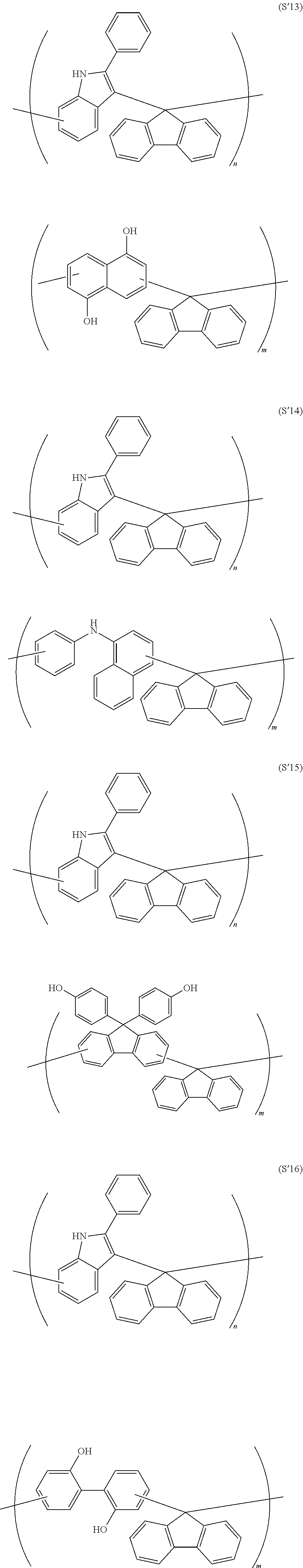

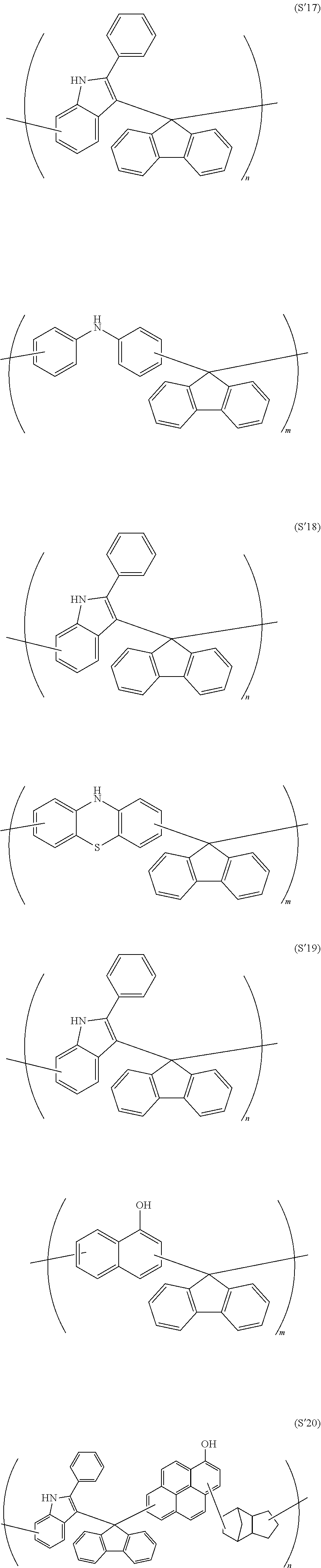

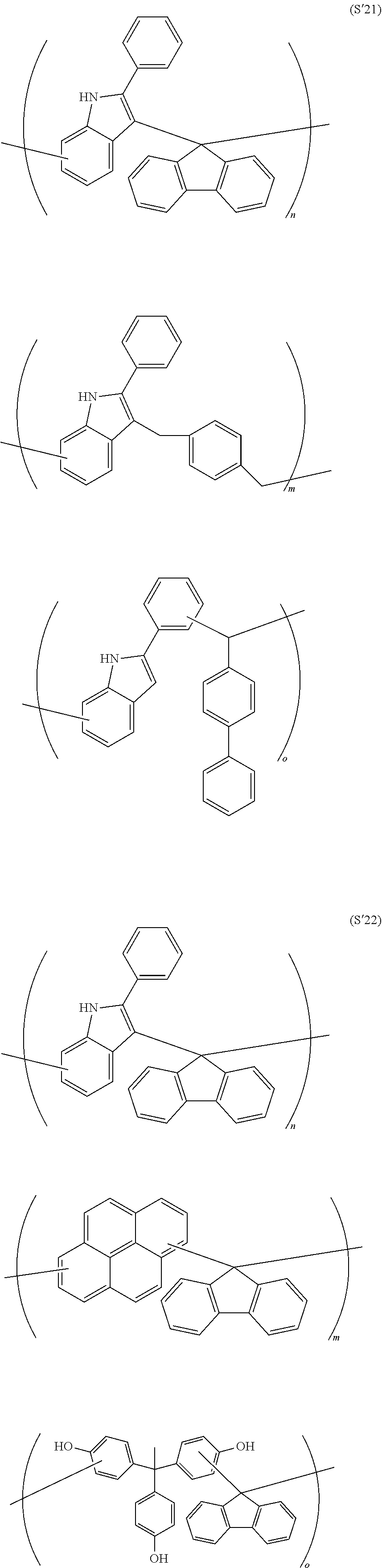

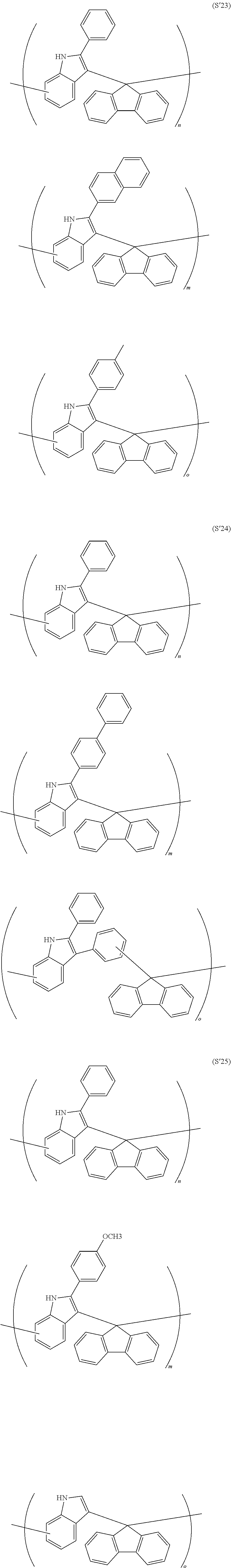

### Synthesis Example 26

10.0 g of the resin (S′1) after a reprecipitation treatment obtained in Synthesis Example 1, 10.4 g of propargyl bromide (C15), 0.5 g of tetrabutylammonium iodide (D3), 27.9 g of tetrahydrofuran (E3), and 9.0 g of a 25% aqueous sodium hydroxide solution (E4) were put into a flask. Then, the mixture was heated to 55° C. under nitrogen, and reacted for about 24 hours. After the reaction was stopped, a phase separation operation with butyl acetate and water (G1) was repeated, the organic layer was concentrated, re-dissolved in PGMEA, and reprecipitated using methanol (F1) and dried to obtain a resin (S1). The weight average molecular weight Mw measured by GPC in terms of polystyrene was about 1,600. The obtained resin was dissolved in PGMEA and ion exchange was performed using a cation exchange resin and an anion exchange resin for 4 hours to obtain a desired compound solution.

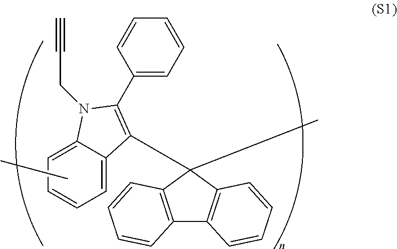

### Synthesis Examples 27 to 50

Polymers used for resist underlayer films were synthesized by changing the polymers (S′1) to (S′25), the catalyst group D, the solvent group E, the reprecipitation solvent group F, and the phase separation solvent group G. Here, an experimental operation was the same as in Synthesis Example 26. Synthesis was performed under the following condition to obtain Example Polymers (S2) to (S25) and their solutions.

TABLE 2

| Synthesis | Structural | | | | Temperature/ | Phase | | Molecular |
|---|---|---|---|---|---|---|---|---|
| Example | Formula | Compound | Catalyst | Solvent | time | separation | Reprecipitation | weight |
| 26 | S1 | S′1/C15 | D3 | E3/E4 | 55° C./ | G1 | F1 | 1600 |
| | | 10.0 g/ | 0.5 g | 27.9 g/ | 24 hours | | | |
| | | 10.4 g | | 9.0 g | | | | |
| 27 | S2 | S′2/C15 | D3 | E3/E4 | 55° C./ | G1 | F1 | 1200 |
| | | 9.0 g/ | 0.6 g | 24.4 g/ | 24 hours | | | |
| | | 11.8 g | | 20.5 g | | | | |
| 28 | S3 | S′3/C15 | D3 | E3/E4 | 55° C./ | G1 | F1 | 1300 |
| | | 10.0 g/ | 0.6 g | 25.3 g/ | 24 hours | | | |
| | | 11.0 g | | 19.3 g | | | | |
| 29 | S4 | S′4/C15 | D3 | E3/E4 | 55° C./ | G1 | F1 | 1800 |
| | | 10.0 g/ | 0.5 g | 23.9 g/ | 24 hours | | | |
| | | 9.6 g | | 16.7 g | | | | |
| 30 | S5 | S′5/C15 | D3 | E3/E4 | 55° C./ | G1 | F1 | 2800 |
| | | 10.0 g/ | 1.4 g | 41.3 g/ | 24 hours | | | |
| | | 28.5 g | | 49.6 g | | | | |
| 31 | S6 | S′6/C15 | D3 | E3/E4 | 55° C./ | G1 | F1 | 1200 |
| | | 10.0 g/ | 0.5 g | 24.6 g/ | 24 hours | | | |
| | | 10.4 g | | 18.0 g | | | | |
| 32 | S7 | S′7/C15 | D3 | E3/E4 | 55° C./ | G1 | F1 | 1700 |
| | | 10.0 g/ | 0.5 g | 24.6 g/ | 24 hours | | | |
| | | 10.4 g | | 18.0 g | | | | |
| 33 | S8 | S′8/C15 | D3 | E3/E4 | 55° C./ | G1 | F1 | 4000 |
| | | 10.0 g/ | 0.5 g | 24.7 g/ | 24 hours | | | |
| | | 10.5 g | | 18.2 g | | | | |
| 34 | S9 | S′9/C15 | D3 | E3/E4 | 55° C./ | G1 | F1 | 1300 |
| | | 10.0 g/ | 0.6 g | 26.3 g/ | 24 hours | | | |
| | | 12.2 g | | 21.2 g | | | | |
| 35 | S10 | S′10/C15 | D3 | E3/E4 | 55° C./ | G1 | F1 | 900 |
| | | 5.0 g/ | 0.3 g | 12.7 g/ | 24 hours | | | |
| | | 5.7 g | | 9.8 g | | | | |
| 36 | S11 | S′11/C15 | D3 | E3/E4 | 55° C./ | G1 | F1 | 2100 |
| | | 10.0 g/ | 0.5 g | 25.0 g/ | 24 hours | | | |
| | | 10.8 g | | 18.8 g | | | | |
| 37 | S12 | S′12/C15 | D3 | E3/E4 | 55° C./ | G1 | F1 | 1300 |
| | | 10.0 g/ | 0.5 g | 24.6 g/ | 24 hours | | | |
| | | 10.4 g | | 18.0 g | | | | |
| 38 | S13 | S′13/C15 | D3 | E3/E4 | 55° C./ | G1 | F1 | 1400 |
| | | 10.0 g/ | 0.5 g | 24.6 g/ | 24 hours | | | |
| | | 10.4 g | | 18.0 g | | | | |
| 39 | S14 | S′14/C15 | D3 | E3/E4 | 55° C./ | G1 | F1 | 1200 |
| | | 10.0 g/ | 0.5 g | 24.6 g/ | 24 hours | | | |
| | | 10.4 g | | 18.0 g | | | | |
| 40 | S15 | S′15/C15 | D3 | E3/E4 | 55° C./ | G1 | F1 | 1400 |
| | | 10.0 g/ | 0.5 g | 24.6 g/ | 24 hours | | | |
| | | 10.4 g | | 18.0 g | | | | |
| 41 | S16 | S′16/C15 | D3 | E3/E4 | 55° C./ | G1 | F1 | 1300 |
| | | 10.0 g/ | 0.5 g | 24.6 g/ | 24 hours | | | |
| | | 10.4 g | | 18.0 g | | | | |
| 42 | S17 | S′17/C15 | D3 | E3/E4 | 55° C./ | G1 | F1 | 1600 |
| | | 10.0 g/ | 0.5 g | 24.6 g/ | 24 hours | | | |
| | | 10.4 g | | 18.0 g | | | | |
| 43 | S18 | S′18/C15 | D3 | E3/E4 | 55° C./ | G1 | F1 | 1600 |
| | | 10.0 g/ | 0.5 g | 24.6 g/ | 24 hours | | | |
| | | 10.4 g | | 18.0 g | | | | |
| 44 | S19 | S′19/C15 | D3 | E3/E4 | 55° C./ | G1 | F1 | 1200 |
| | | 10.0 g/ | 0.5 g | 24.6 g/ | 24 hours | | | |
| | | 10.4 g | | 18.0 g | | | | |
| 45 | S20 | S′20/C15 | D3 | E3/E4 | 55° C./ | G1 | F1 | 1700 |
| | | 10.0 g/ | 0.5 g | 24.6 g/ | 24 hours | | | |
| | | 10.4 g | | 18.0 g | | | | |
| 46 | S21 | S′21/C15 | D3 | E3/E4 | 55° C./ | G1 | F1 | 5200 |
| | | 10.0 g/ | 0.5 g | 24.6 g/ | 24 hours | | | |
| | | 10.4 g | | 18.0 g | | | | |
| 47 | S22 | S′22/C15 | D3 | E3/E4 | 55° C./ | G1 | F1 | 1200 |
| | | 10.0 g/ | 0.5 g | 24.6 g/ | 24 hours | | | |
| | | 10.4 g | | 18.0 g | | | | |
| 48 | S23 | S′23/C15 | D3 | E3/E4 | 55° C./ | G1 | F1 | 1200 |
| | | 10.0 g/ | 0.5 g | 24.6 g/ | 24 hours | | | |
| | | 10.4 g | | 18.0 g | | | | |
| 49 | S24 | S′24/C15 | D3 | E3/E4 | 55° C./ | G1 | F1 | 1400 |
| | | 10.0 g/ | 0.5 g | 24.6 g/ | 24 hours | | | |
| | | 10.4 g | | 18.0 g | | | | |
| 50 | S25 | S′25/C15 | D3 | E3/E4 | 55° C./ | G1 | F1 | 1500 |
| | | 10.0 g/ | 0.5 g | 24.6 g/ | 24 hours | | | |
| | | 10.4 g | | 18.0 g | | | | |

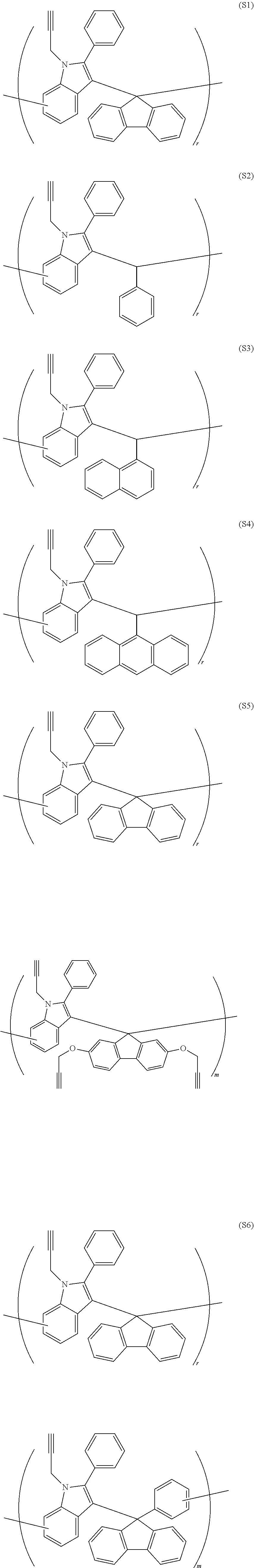

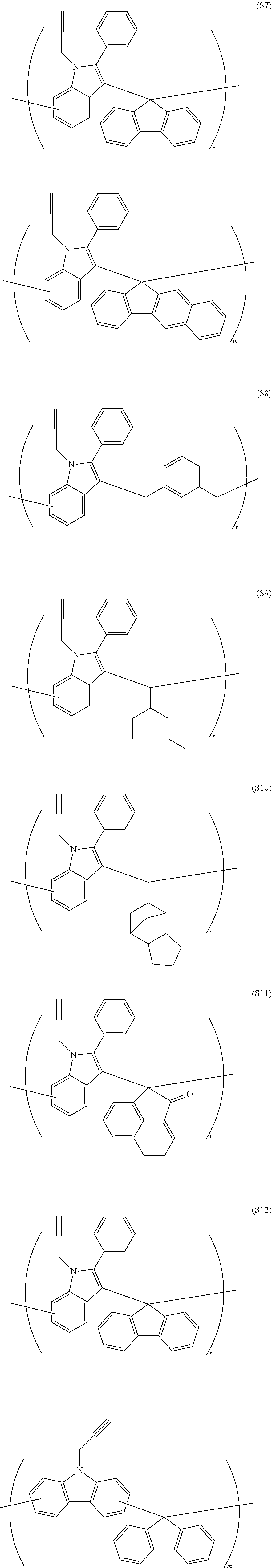

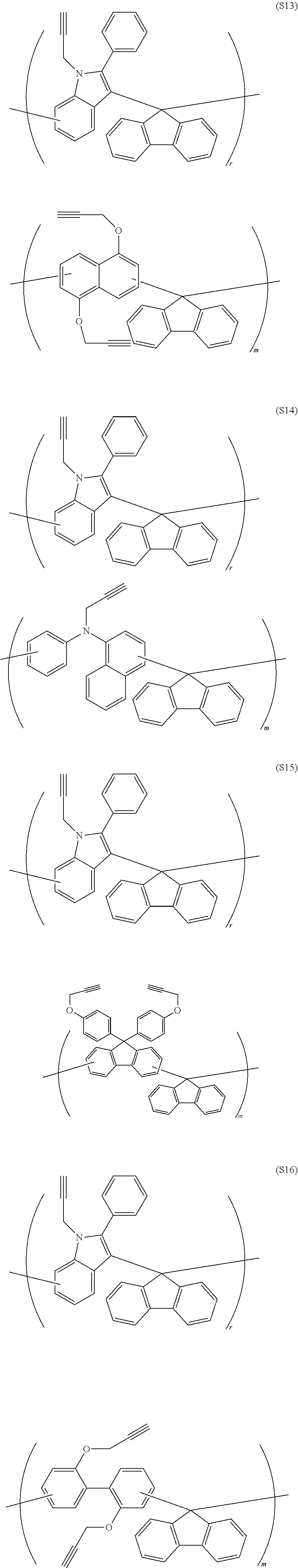

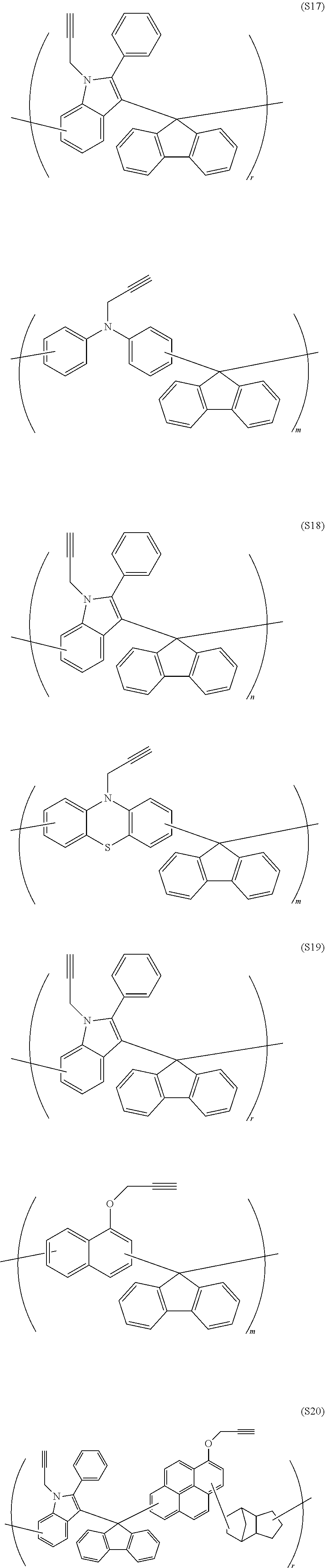

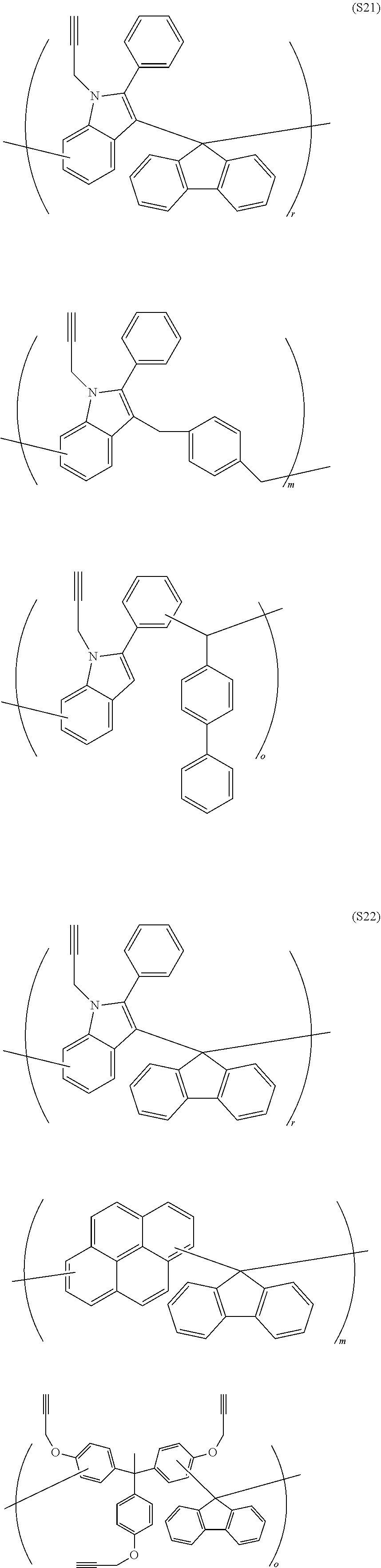

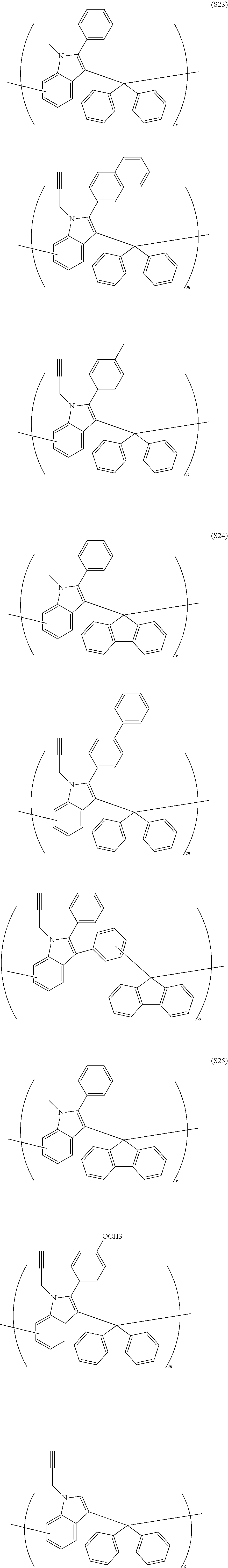

### [Preparation of Resist Underlayer Film]

Polymers (S1) to (S25), (S′1) to (S′25), a crosslinking agent (CR1), an acid generator (Ad1), solvents (propylene glycol monomethyl ether acetate (PGMEA), propylene glycol monomethyl ether (PGME), and cyclohexanone (CYH)), and Megaface R-40 (commercially available from DIC Corporation, R-40) as a surfactant were mixed in the proportions shown in the following table, and the mixture was filtered through a 0.1 μm polytetrafluoroethylene microfilter to prepare a resist underlayer film material (Examples M1 to M25 and Comparative Examples M1 to M50).

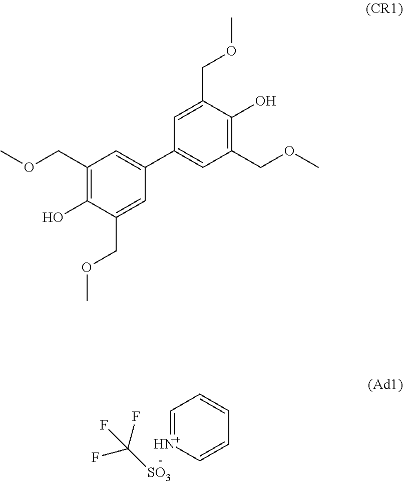

TABLE 3

| | | Crosslinking | Acid | | | | |
|---|---|---|---|---|---|---|---|
| Composition | Polymer | agent | generator | Surfactant | Solvent (total 100) | | |
| Example M1 | Synthesis | — | — | R-40 | PGMEA | PGME | CYH |
| | Example 26 | | | | | | |
| | 100 | — | — | 0.1 | 100 | 0 | 0 |
| Example M2 | Synthesis | — | — | R-40 | PGMEA | PGME | CYH |
| | Example 27 | | | | | | |
| | 100 | — | — | 0.1 | 100 | 0 | 0 |
| Example M3 | Synthesis | — | — | R-40 | PGMEA | PGME | CYH |
| | Example 28 | | | | | | |
| | 100 | — | — | 0.1 | 100 | 0 | 0 |
| Example M4 | Synthesis | — | — | R-40 | PGMEA | PGME | CYH |
| | Example 29 | | | | | | |
| | 100 | — | — | 0.1 | 100 | 0 | 0 |
| Example M5 | Synthesis | — | — | R-40 | PGMEA | PGME | CYH |
| | Example 30 | | | | | | |
| | 100 | — | — | 0.1 | 100 | 0 | 0 |
| Example M6 | Synthesis | — | — | R-40 | PGMEA | PGME | CYH |
| | Example 31 | | | | | | |
| | 100 | — | — | 0.1 | 100 | 0 | 0 |
| Example M7 | Synthesis | — | — | R-40 | PGMEA | PGME | CYH |
| | Example 32 | | | | | | |
| | 100 | — | — | 0.1 | 100 | 0 | 0 |
| Example M8 | Synthesis | — | — | R-40 | PGMEA | PGME | CYH |
| | Example 33 | | | | | | |
| | 100 | — | — | 0.1 | 100 | 0 | 0 |
| Example M9 | Synthesis | — | — | R-40 | PGMEA | PGME | CYH |
| | Example 34 | | | | | | |
| | 100 | — | — | 0.1 | 100 | 0 | 0 |
| Example M10 | Synthesis | — | — | R-40 | PGMEA | PGME | CYH |
| | Example 35 | | | | | | |
| | 100 | — | — | 0.1 | 100 | 0 | 0 |
| Example M11 | Synthesis | — | — | R-40 | PGMEA | PGME | CYH |
| | Example 36 | | | | | | |
| | 100 | — | — | 0.1 | 0 | 0 | 100 |
| Example M12 | Synthesis | — | — | R-40 | PGMEA | PGME | CYH |
| | Example 37 | | | | | | |
| | 100 | — | — | 0.1 | 100 | 0 | 0 |
| Example M13 | Synthesis | — | — | R-40 | PGMEA | PGME | CYH |
| | Example 38 | | | | | | |
| | 100 | — | — | 0.1 | 100 | 0 | 0 |
| Example M14 | Synthesis | — | — | R-40 | PGMEA | PGME | CYH |
| | Example 39 | | | | | | |
| | 100 | — | — | 0.1 | 100 | 0 | 0 |
| Example M15 | Synthesis | — | — | R-40 | PGMEA | PGME | CYH |
| | Example 40 | | | | | | |
| | 100 | — | — | 0.1 | 100 | 0 | 0 |
| Example M16 | Synthesis | — | — | R-40 | PGMEA | PGME | CYH |
| | Example 41 | | | | | | |
| | 100 | — | — | 0.1 | 100 | 0 | 0 |
| Example M17 | Synthesis | — | — | R-40 | PGMEA | PGME | CYH |
| | Example 42 | | | | | | |
| | 100 | — | — | 0.1 | 100 | 0 | 0 |
| Example M18 | Synthesis | — | — | R-40 | PGMEA | PGME | CYH |
| | Example 43 | | | | | | |
| | 100 | — | — | 0.1 | 100 | 0 | 0 |
| Example M19 | Synthesis | — | — | R-40 | PGMEA | PGME | CYH |
| | Example 44 | | | | | | |
| | 100 | — | — | 0.1 | 100 | 0 | 0 |
| Example M20 | Synthesis | — | — | R-40 | PGMEA | PGME | CYH |
| | Example 45 | | | | | | |
| | 100 | — | — | 0.1 | 100 | 0 | 0 |
| Example M21 | Synthesis | — | — | R-40 | PGMEA | PGME | CYH |
| | Example 46 | | | | | | |
| | 100 | — | — | 0.1 | 100 | 0 | 0 |
| Example M22 | Synthesis | — | — | R-40 | PGMEA | PGME | CYH |
| | Example 47 | | | | | | |
| | 100 | — | — | 0.1 | 100 | 0 | 0 |
| Example M23 | Synthesis | — | — | R-40 | PGMEA | PGME | CYH |
| | Example 48 | | | | | | |
| | 100 | — | — | 0.1 | 100 | 0 | 0 |
| Example M24 | Synthesis | — | — | R-40 | PGMEA | PGME | CYH |
| | Example 49 | | | | | | |
| | 100 | — | — | 0.1 | 100 | 0 | 0 |
| Example M25 | Synthesis | — | — | R-40 | PGMEA | PGME | CYH |
| | Example 50 | | | | | | |
| | 100 | — | — | 0.1 | 100 | 0 | 0 |
| Comparative | Synthesis | — | — | R-40 | PGMEA | PGME | CYH |
| Example M1 | Example 1 | | | | | | |
| | 100 | — | — | 0.1 | 100 | 0 | 0 |
| Comparative | Synthesis | — | — | R-40 | PGMEA | PGME | CYH |
| Example M2 | Example 2 | | | | | | |
| | 100 | — | — | 0.1 | 100 | 0 | 0 |
| Comparative | Synthesis | — | — | R-40 | PGMEA | PGME | CYH |
| Example M3 | Example 3 | | | | | | |
| | 100 | — | — | 0.1 | 100 | 0 | 0 |
| Comparative | Synthesis | — | — | R-40 | PGMEA | PGME | CYH |
| Example M4 | Example 4 | | | | | | |
| | 100 | — | — | 0.1 | 100 | 0 | 0 |
| Comparative | Synthesis | — | — | R-40 | PGMEA | PGME | CYH |
| Example M5 | Example 5 | | | | | | |
| | 100 | — | — | 0.1 | 100 | 0 | 0 |
| Comparative | Synthesis | — | — | R-40 | PGMEA | PGME | CYH |
| Example M6 | Example 6 | | | | | | |
| | 100 | — | — | 0.1 | 100 | 0 | 0 |
| Comparative | Synthesis | — | — | R-40 | PGMEA | PGME | CYH |
| Example M7 | Example 7 | | | | | | |
| | 100 | — | — | 0.1 | 100 | 0 | 0 |
| Comparative | Synthesis | — | — | R-40 | PGMEA | PGME | CYH |
| Example M8 | Example 8 | | | | | | |
| | 100 | — | — | 0.1 | 100 | 0 | 0 |
| Comparative | Synthesis | — | — | R-40 | PGMEA | PGME | CYH |
| Example M9 | Example 9 | | | | | | |
| | 100 | — | — | 0.1 | 100 | 0 | 0 |
| Comparative | Synthesis | — | — | R-40 | PGMEA | PGME | CYH |
| Example M10 | Example 10 | | | | | | |
| | 100 | — | — | 0.1 | 100 | 0 | 0 |
| Comparative | Synthesis | — | — | R-40 | PGMEA | PGME | CYH |
| Example M11 | Example 11 | | | | | | |
| | 100 | — | — | 0.1 | 0 | 0 | 100 |
| Comparative | Synthesis | — | — | R-40 | PGMEA | PGME | CYH |
| Example M12 | Example 12 | | | | | | |
| | 100 | — | — | 0.1 | 100 | 0 | 0 |
| Comparative | Synthesis | — | — | R-40 | PGMEA | PGME | CYH |
| Example M13 | Example 13 | | | | | | |
| | 100 | — | — | 0.1 | 100 | 0 | 0 |
| Comparative | Synthesis | — | — | R-40 | PGMEA | PGME | CYH |
| Example M14 | Example 14 | | | | | | |
| | 100 | — | — | 0.1 | 100 | 0 | 0 |
| Comparative | Synthesis | — | — | R-40 | PGMEA | PGME | CYH |
| Example M15 | Example 15 | | | | | | |
| | 100 | — | — | 0.1 | 100 | 0 | 0 |
| Comparative | Synthesis | — | — | R-40 | PGMEA | PGME | CYH |
| Example M16 | Example 16 | | | | | | |
| | 100 | — | — | 0.1 | 100 | 0 | 0 |
| Comparative | Synthesis | — | — | R-40 | PGMEA | PGME | CYH |
| Example M17 | Example 17 | | | | | | |
| | 100 | — | — | 0.1 | 100 | 0 | 0 |
| Comparative | Synthesis | — | — | R-40 | PGMEA | PGME | CYH |
| Example M18 | Example 18 | | | | | | |
| | 100 | — | — | 0.1 | 100 | 0 | 0 |
| Comparative | Synthesis | — | — | R-40 | PGMEA | PGME | CYH |
| Example M19 | Example 19 | | | | | | |
| | 100 | — | — | 0.1 | 100 | 0 | 0 |
| Comparative | Synthesis | — | — | R-40 | PGMEA | PGME | CYH |
| Example M20 | Example 20 | | | | | | |
| | 100 | — | — | 0.1 | 100 | 0 | 0 |
| Comparative | Synthesis | — | — | R-40 | PGMEA | PGME | CYH |
| Example M21 | Example 21 | | | | | | |
| | 100 | — | — | 0.1 | 100 | 0 | 0 |
| Comparative | Synthesis | — | — | R-40 | PGMEA | PGME | CYH |
| Example M22 | Example 22 | | | | | | |
| | 100 | — | — | 0.1 | 100 | 0 | 0 |
| Comparative | Synthesis | — | — | R-40 | PGMEA | PGME | CYH |
| Example M23 | Example 23 | | | | | | |
| | 100 | — | — | 0.1 | 100 | 0 | 0 |
| Comparative | Synthesis | — | — | R-40 | PGMEA | PGME | CYH |
| Example M24 | Example 24 | | | | | | |
| | 100 | — | — | 0.1 | 100 | 0 | 0 |
| Comparative | Synthesis | — | — | R-40 | PGMEA | PGME | CYH |
| Example M25 | Example 25 | | | | | | |
| | 100 | — | — | 0.1 | 100 | 0 | 0 |
| Comparative | Synthesis | CR1 | Ad1 | R-40 | PGMEA | PGME | CYH |
| Example M26 | Example 1 | | | | | | |
| | 100 | 30 | 4 | 0.1 | 70 | 30 | 0 |
| Comparative | Synthesis | CR1 | Ad1 | R-40 | PGMEA | PGME | CYH |
| Example M27 | Example 2 | | | | | | |
| | 100 | 30 | 4 | 0.1 | 70 | 30 | 0 |
| Comparative | Synthesis | CR1 | Ad1 | R-40 | PGMEA | PGME | CYH |
| Example M28 | Example 3 | | | | | | |
| | 100 | 30 | 4 | 0.1 | 70 | 30 | 0 |
| Comparative | Synthesis | CR1 | Ad1 | R-40 | PGMEA | PGME | CYH |
| Example M29 | Example 4 | | | | | | |
| | 100 | 30 | 4 | 0.1 | 70 | 30 | 0 |
| Comparative | Synthesis | CR1 | Ad1 | R-40 | PGMEA | PGME | CYH |
| Example M30 | Example 5 | | | | | | |
| | 100 | 30 | 4 | 0.1 | 70 | 30 | 0 |
| Comparative | Synthesis | CR1 | Ad1 | R-40 | PGMEA | PGME | CYH |
| Example M31 | Example 6 | | | | | | |
| | 100 | 30 | 4 | 0.1 | 70 | 30 | 0 |
| Comparative | Synthesis | CR1 | Ad1 | R-40 | PGMEA | PGME | CYH |
| Example M32 | Example 7 | | | | | | |
| | 100 | 30 | 4 | 0.1 | 70 | 30 | 0 |
| Comparative | Synthesis | CR1 | Ad1 | R-40 | PGMEA | PGME | CYH |
| Example M33 | Example 8 | | | | | | |
| | 100 | 30 | 4 | 0.1 | 70 | 30 | 0 |
| Comparative | Synthesis | CR1 | Ad1 | R-40 | PGMEA | PGME | CYH |
| Example M34 | Example 9 | | | | | | |
| | 100 | 30 | 4 | 0.1 | 70 | 30 | 0 |
| Comparative | Synthesis | CR1 | Ad1 | R-40 | PGMEA | PGME | CYH |
| Example M35 | Example 10 | | | | | | |
| | 100 | 30 | 4 | 0.1 | 70 | 30 | 0 |
| Comparative | Synthesis | CR1 | Ad1 | R-40 | PGMEA | PGME | CYH |
| Example M36 | Example 11 | | | | | | |
| | 100 | 30 | 4 | 0.1 | 0 | 30 | 70 |
| Comparative | Synthesis | CR1 | Ad1 | R-40 | PGMEA | PGME | CYH |
| Example M37 | Example 12 | | | | | | |
| | 100 | 30 | 4 | 0.1 | 70 | 30 | 0 |
| Comparative | Synthesis | CR1 | Ad1 | R-40 | PGMEA | PGME | CYH |
| Example M38 | Example 13 | | | | | | |
| | 100 | 30 | 4 | 0.1 | 70 | 30 | 0 |
| Comparative | Synthesis | CR1 | Ad1 | R-40 | PGMEA | PGME | CYH |
| Example M39 | Example 14 | | | | | | |
| | 100 | 30 | 4 | 0.1 | 70 | 30 | 0 |
| Comparative | Synthesis | CR1 | Ad1 | R-40 | PGMEA | PGME | CYH |
| Example M40 | Example 15 | | | | | | |
| | 100 | 30 | 4 | 0.1 | 70 | 30 | 0 |
| Comparative | Synthesis | CR1 | Ad1 | R-40 | PGMEA | PGME | CYH |
| Example M41 | Example 16 | | | | | | |
| | 100 | 30 | 4 | 0.1 | 70 | 30 | 0 |
| Comparative | Synthesis | CR1 | Ad1 | R-40 | PGMEA | PGME | CYH |
| Example M42 | Example 17 | | | | | | |
| | 100 | 30 | 4 | 0.1 | 70 | 30 | 0 |
| Comparative | Synthesis | CR1 | Ad1 | R-40 | PGMEA | PGME | CYH |
| Example M43 | Example 18 | | | | | | |
| | 100 | 30 | 4 | 0.1 | 70 | 30 | 0 |
| Comparative | Synthesis | CR1 | Ad1 | R-40 | PGMEA | PGME | CYH |
| Example M44 | Example 19 | | | | | | |
| | 100 | 30 | 4 | 0.1 | 70 | 30 | 0 |
| Comparative | Synthesis | CR1 | Ad1 | R-40 | PGMEA | PGME | CYH |
| Example M45 | Example 20 | | | | | | |
| | 100 | 30 | 4 | 0.1 | 70 | 30 | 0 |
| Comparative | Synthesis | CR1 | Ad1 | R-40 | PGMEA | PGME | CYH |
| Example M46 | Example 21 | | | | | | |
| | 100 | 30 | 4 | 0.1 | 70 | 30 | 0 |
| Comparative | Synthesis | CR1 | Ad1 | R-40 | PGMEA | PGME | CYH |
| Example M47 | Example 22 | | | | | | |
| | 100 | 30 | 4 | 0.1 | 70 | 30 | 0 |
| Comparative | Synthesis | CR1 | Ad1 | R-40 | PGMEA | PGME | CYH |
| Example M48 | Example 23 | | | | | | |
| | 100 | 30 | 4 | 0.1 | 70 | 30 | 0 |
| Comparative | Synthesis | CR1 | Ad1 | R-40 | PGMEA | PGME | CYH |
| Example M49 | Example 24 | | | | | | |
| | 100 | 30 | 4 | 0.1 | 70 | 30 | 0 |
| Comparative | Synthesis | CR1 | Ad1 | R-40 | PGMEA | PGME | CYH |
| Example M50 | Example 25 | | | | | | |
| | 100 | 30 | 4 | 0.1 | 70 | 30 | 0 |

### [Sublimate Measurement]

The resist underlayer film materials of Comparative Examples M1 to M25 and Examples M1 to M25 were baked at 400° C. for 60 seconds and adjusted to a concentration of about 100 nm, and applied onto a silicon wafer respectively using a spin coater. The wafer was set in a sublimate measuring device integrated with a hot plate adjusted to 300° C., baked for 60 seconds and collected and quantified using a sublimate QCM sensor. For the measurement, the hot plate was heated to 300° C., the pump flow rate was set to 0.24 m³/s, the sample was left for the first 60 seconds for aging, immediately after that, the film-coated wafer was quickly placed on the hot plate from the slide opening (the measurement object was installed), and the sublimate was collected from the 60 second point to the 120 second point (for 60 seconds). The QCM sensor using an electrode made of material of a compound containing silicon and aluminum, having a crystal resonator diameter (sensor diameter) of 14 mm, an electrode diameter on the crystal resonator surface of 5 mm, and a resonance frequency of 9 MHz was used. Compositions in which the sublimate detected in Examples M1 to M25 after the introduction of propargyl groups was smaller than the sublimate of Comparative Examples M1 to M25 before the introduction of propargyl groups were determined to be ◯ (Table 4).

### [Test of Elution in Resist Solvent]

The resist underlayer film materials of Comparative Examples M1 to M50 and Examples M1 to M25 were applied as a resist underlayer film material onto a silicon wafer using ACT-8 (commercially available from Tokyo Electron Ltd.), and baked at a predetermined temperature for a predetermined time shown in the table under air and N₂ to form a 100 nm resist underlayer film. The formed resist underlayer film was immersed in a general-purpose thinner, PGME/PGMEA=7/3 for 60 seconds, and resistance to the solvent was confirmed. When the rate of reduction in the film thickness before and after immersion in the thinner was 1% or less, it was determined to be ◯ (Table 4). Here, since it was difficult, as a resist underlayer film, to evaluate a sample that did not exhibit solvent resistance under baking conditions in air and N₂, the sample was not evaluated in the following tests.

### [Measurement of Etching Rate]

The etcher and etching gas used in etching measurement are as follows. RIE-200NL (commercially available from SAMCO Inc.): CF₄ 50 sccm

The resist underlayer film materials of Comparative Examples M26 to M50 and Examples M1 to M25 were applied onto a silicon wafer using a spin coater. Baking was performed on a hot plate at a predetermined temperature for a predetermined time shown in the table to form a 100 nm resist underlayer film. The dry etching rate was measured using a CF₄ gas as an etching gas. For the polymers, compositions in which the etching resistance of Examples M1 to M25 after the introduction of propargyl groups was higher than the etching resistance of Comparative Examples M26 to M50 cured with a crosslinking agent and an acid catalyst before the introduction of propargyl groups were determined to be ◯ (Table 4).

### [Embedding Property Test for Stepped Substrate]

As a coating test for a stepped substrate, it was confirmed on an SiO₂ substrate with a film thickness of 100 nm, whether the resist underlayer film was filled in an open area (OPEN) in which no pattern was formed and in a 50 nm width trench. The resist underlayer film-forming compositions of Comparative Examples 26 to 29 and Examples M1 to M25 were applied onto the substrate, and then baked at 400° C. for 60 seconds to form a resist underlayer film with about 100 nm. The flattening properties of the substrate were observed using a scanning electron microscope (S-4800) (commercially available from Hitachi High-Technologies Corporation), and when there were no voids and the film filled the space, the embedding properties were deemed favorable and determined to be ◯ (Table 4).

TABLE 4

| | | | | | CF₄ | |
|---|---|---|---|---|---|---|
| Example/ | | | Solvent | | etching | Embed- |
| Comparative | Baking | Subli- | resistance | | resis- | ding |
| Example | temperature | mate | Air | N₂ | tance | property |
| Example 1 | 400° C./60 sec | ∘ | ∘ | ∘ | ∘ | ∘ |
| Example 2 | 400° C./60 sec | ∘ | ∘ | ∘ | ∘ | ∘ |
| Example 3 | 400° C./60 sec | ∘ | ∘ | ∘ | ∘ | ∘ |
| Example 4 | 400° C./60 sec | ∘ | ∘ | ∘ | ∘ | ∘ |
| Example 5 | 400° C./60 sec | ∘ | ∘ | ∘ | ∘ | ∘ |
| Example 6 | 400° C./60 sec | ∘ | ∘ | ∘ | ∘ | ∘ |
| Example 7 | 400° C./60 sec | ∘ | ∘ | ∘ | ∘ | ∘ |
| Example 8 | 400° C./60 sec | ∘ | ∘ | ∘ | ∘ | ∘ |
| Example 9 | 400° C./60 sec | ∘ | ∘ | ∘ | ∘ | ∘ |
| Example 10 | 400° C./60 sec | ∘ | ∘ | ∘ | ∘ | ∘ |
| Example 11 | 400° C./60 sec | ∘ | ∘ | ∘ | ∘ | ∘ |
| Example 12 | 400° C./60 sec | ∘ | ∘ | ∘ | ∘ | ∘ |
| Example 13 | 400° C./60 sec | ∘ | ∘ | ∘ | ∘ | ∘ |
| Example 14 | 400° C./60 sec | ∘ | ∘ | ∘ | ∘ | ∘ |
| Example 15 | 400° C./60 sec | ∘ | ∘ | ∘ | ∘ | ∘ |
| Example 16 | 400° C./60 sec | ∘ | ∘ | ∘ | ∘ | ∘ |
| Example 17 | 400° C./60 sec | ∘ | ∘ | ∘ | ∘ | ∘ |
| Example 18 | 400° C./60 sec | ∘ | ∘ | ∘ | ∘ | ∘ |
| Example 19 | 400° C./60 sec | ∘ | ∘ | ∘ | ∘ | ∘ |
| Example 20 | 400° C./60 sec | ∘ | ∘ | ∘ | ∘ | ∘ |
| Example 21 | 400° C./60 sec | ∘ | ∘ | ∘ | ∘ | ∘ |
| Example 22 | 400° C./60 sec | ∘ | ∘ | ∘ | ∘ | ∘ |
| Example 23 | 400° C./60 sec | ∘ | ∘ | ∘ | ∘ | ∘ |
| Example 24 | 400° C./60 sec | ∘ | ∘ | ∘ | ∘ | ∘ |
| Example 25 | 400° C./60 sec | ∘ | ∘ | ∘ | ∘ | ∘ |
| Comparative | 400° C./60 sec | — | x | x | — | — |
| Example 1 | | | | | | |
| Comparative | 400° C./60 sec | — | x | x | — | — |
| Example 2 | | | | | | |
| Comparative | 400° C./60 sec | — | x | x | — | — |
| Example 3 | | | | | | |
| Comparative | 400° C./60 sec | — | x | x | — | — |
| Example 4 | | | | | | |
| Comparative | 400° C./60 sec | — | ∘ | x | — | — |
| Example 5 | | | | | | |
| Comparative | 400° C./60 sec | — | x | x | — | — |
| Example 6 | | | | | | |
| Comparative | 400° C./60 sec | — | x | x | — | — |
| Example 7 | | | | | | |
| Comparative | 400° C./60 sec | — | x | x | — | — |
| Example 8 | | | | | | |
| Comparative | 400° C./60 sec | — | ∘ | x | — | — |
| Example 9 | | | | | | |
| Comparative | 400° C./60 sec | — | ∘ | x | — | — |
| Example 10 | | | | | | |
| Comparative | 400° C./60 sec | — | x | x | — | — |
| Example 11 | | | | | | |
| Comparative | 400° C./60 sec | — | x | x | — | — |
| Example 12 | | | | | | |
| Comparative | 400° C./60 sec | — | x | x | — | — |
| Example 13 | | | | | | |
| Comparative | 400° C./60 sec | — | x | x | — | — |
| Example 14 | | | | | | |
| Comparative | 400° C./60 sec | — | x | x | — | — |
| Example 15 | | | | | | |
| Comparative | 400° C./60 sec | — | x | x | — | — |
| Example 16 | | | | | | |
| Comparative | 400° C./60 sec | — | ∘ | x | — | — |
| Example 17 | | | | | | |
| Comparative | 400° C./60 sec | — | ∘ | x | — | — |
| Example 18 | | | | | | |
| Comparative | 400° C./60 sec | — | x | x | — | — |
| Example 19 | | | | | | |
| Comparative | 400° C./60 sec | — | ∘ | x | — | — |
| Example 20 | | | | | | |
| Comparative | 400° C./60 sec | — | ∘ | x | — | — |
| Example 21 | | | | | | |
| Comparative | 400° C./60 sec | — | x | x | — | — |
| Example 22 | | | | | | |
| Comparative | 400° C./60 sec | — | x | x | — | — |
| Example 23 | | | | | | |
| Comparative | 400° C./60 sec | — | x | x | — | — |
| Example 24 | | | | | | |
| Comparative | 400° C./60 sec | — | x | x | — | — |
| Example 25 | | | | | | |
| Comparative | 400° C./60 sec | — | ∘ | ∘ | — | x |
| Example 26 | | | | | | |
| Comparative | 400° C./60 sec | — | ∘ | ∘ | — | x |
| Example 27 | | | | | | |
| Comparative | 400° C./60 sec | — | ∘ | ∘ | — | x |
| Example 28 | | | | | | |
| Comparative | 400° C./60 sec | — | ∘ | ∘ | — | x |
| Example 29 | | | | | | |
| Comparative | 400° C./60 sec | — | ∘ | ∘ | — | — |
| Example 30 | | | | | | |
| Comparative | 400° C./60 sec | — | ∘ | ∘ | — | — |
| Example 31 | | | | | | |
| Comparative | 400° C./60 sec | — | ∘ | ∘ | — | — |
| Example 32 | | | | | | |
| Comparative | 400° C./60 sec | — | ∘ | ∘ | — | — |
| Example 33 | | | | | | |
| Comparative | 400° C./60 sec | — | ∘ | ∘ | — | — |
| Example 34 | | | | | | |
| Comparative | 400° C./60 sec | — | ∘ | ∘ | — | — |
| Example 35 | | | | | | |
| Comparative | 400° C./60 sec | — | ∘ | ∘ | — | — |
| Example 36 | | | | | | |
| Comparative | 400° C./60 sec | — | ∘ | ∘ | — | — |
| Example 37 | | | | | | |
| Comparative | 400° C./60 sec | — | ∘ | ∘ | — | — |
| Example 38 | | | | | | |
| Comparative | 400° C./60 sec | — | ∘ | ∘ | — | — |
| Example 39 | | | | | | |
| Comparative | 400° C./60 sec | — | ∘ | ∘ | — | — |
| Example 40 | | | | | | |
| Comparative | 400° C./60 sec | — | ∘ | ∘ | — | — |
| Example 41 | | | | | | |
| Comparative | 400° C./60 sec | — | ∘ | ∘ | — | — |
| Example 42 | | | | | | |
| Comparative | 400° C./60 sec | — | ∘ | ∘ | — | — |
| Example 43 | | | | | | |
| Comparative | 400° C./60 sec | — | ∘ | ∘ | — | — |
| Example 44 | | | | | | |
| Comparative | 400° C./60 sec | — | ∘ | ∘ | — | — |
| Example 45 | | | | | | |
| Comparative | 400° C./60 sec | — | ∘ | ∘ | — | — |
| Example 46 | | | | | | |
| Comparative | 400° C./60 sec | — | ∘ | ∘ | — | — |
| Example 47 | | | | | | |
| Comparative | 400° C./60 sec | — | ∘ | ∘ | — | — |
| Example 48 | | | | | | |
| Comparative | 400° C./60 sec | — | ∘ | ∘ | — | — |
| Example 49 | | | | | | |
| Comparative | 400° C./60 sec | — | ∘ | ∘ | — | — |
| Example 50 | | | | | | |

As above, the propargyl group can function as a crosslinking group, and thus the amount of sublimates can be reduced compared to the original polymer. In addition, the polymer into which the propargyl group is introduced, not only exhibits a sufficient solvent resistance in air but also exhibits a favorable solvent resistance under N₂, regardless of the presence or absence of a crosslinking agent or an acid catalyst, and it is considered to have the advantage of obtaining sufficient curing properties as a resist underlayer film. In addition, when the propargyl group is introduced, a sufficient etching resistance is exhibited against an F-based gas, which is a general-purpose etching gas. Further, since the propargyl group in the polymer can increase the crosslinking initiation temperature, a sufficient reflowability is obtained, and favorable embedding properties are provided for the patterned substrate. From these points, application to a wide range of semiconductor devices can be expected.

### INDUSTRIAL APPLICABILITY

The resist underlayer film material used in the lithography process using the multilayer film of the present invention can provide a resist underlayer film which exhibits an excellent etching resistance, has favorable flattening properties and embedding properties with respect to a finely processed substrate, allows an excellent resist pattern to be obtained, is resistant to a solvent even in a nitrogen atmosphere, exhibits sufficient curing properties, and also has the effect of the anti-reflective coating. In addition, it has been found that the underlayer film material of the present invention has a thermal resistance that allows a hard mask to be formed on the upper layer by vapor deposition.

1. A resist underlayer film-forming composition containing a polymer having a unit structure of the following Formula (I) or Formula (I′): 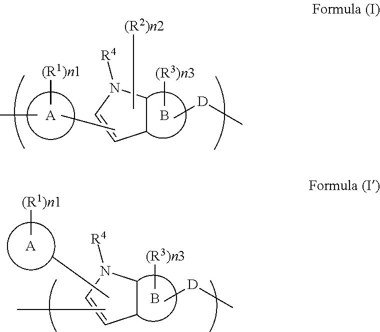
(in Formula (I) or Formula (I′), each of a ring A and a ring B is a C₆₋₈₀ aryl group which possibly contains a heteroatom and possibly has a ring structure containing an alkyl chain; each of R¹, R², and R³ is a substituent of hydrogen atoms in the ring, and is independently a halogen atom, a nitro group, a cyano group, an amino group, a hydroxyl group, a C₁₋₁₀ alkyl group, a C₁₋₁₀ alkoxy group, a C₂₋₁₀ alkenyl group, a C₂₋₁₀ alkynyl group, a C₆₋₈₀ aryl group, or any combination of these possibly containing an ether bond, a ketone bond, a sulfide bond, a sulfonyl group, a carboxyl group, or an ester bond; R⁴ is a C₂₋₁₀ alkynyl group; each of n1, n2, and n3 is an integer of 0 or more, and is an integer up to the possible maximum number of the substituents substituted on the ring; and D is a divalent organic group containing a structure of the following Formula (II) and/or (III): 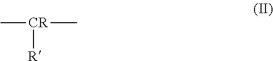
(in Formula (II), each of R and R′ is independently a hydrogen atom, a C₆₋₃₀ aromatic hydrocarbon group which possibly has a substituent, a C₃₋₃₀ heterocyclic group which possibly has a substituent, or a linear, branched, or cyclic alkyl group which possibly has a substituent and has a carbon atom number of 10 or less) 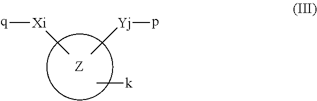
(in Formula (III), X and Y are possibly bonded to the same carbon atom on Z or possibly bonded to different carbon atoms, and each of X and Y is independently a C₆₋₃₀ aromatic hydrocarbon group which possibly has a substituent, a heteroatom, or a linear, branched, or cyclic alkyl group which possibly has a substituent and has a carbon atom number of 10 or less, Z is a 4- to 12-membered monocyclic, bicyclic, or tricyclic ring which is possibly condensed with an aromatic ring, possibly has a substituent, and possibly contains a heteroatom, each of i and j is independently 0 or 1, p, q, and k are the number of bonding hands, each of p and q is independently 0 or 1, p and q are not 0 at the same time, and k is an integer of 0 to 2)).

2. The resist underlayer film-forming composition according to claim 1,
wherein the ring A and the ring B are benzene rings or naphthalene rings, n1+n2+n3 is 0 to 2, and R⁴ is a propargyl group.

3. The resist underlayer film-forming composition according to claim 2,
wherein D is a divalent organic group containing a fluorene or fluorene derivative structure, and/or a C₆₋₃₀ aromatic hydrocarbon group which possibly has a substituent.

4. The resist underlayer film-forming composition according to claim 1, wherein the composition further contains a surfactant.

5. The resist underlayer film-forming composition according to claim 1, wherein the composition further contains a crosslinking agent.

6. The resist underlayer film-forming composition according to claim 1, wherein the composition further contains a surfactant and a crosslinking agent.

7. The resist underlayer film-forming composition according to claim 1, wherein the composition further contains an acid, and/or a salt thereof, and/or an acid generator.

8. The resist underlayer film-forming composition according to claim 1, wherein the composition further contains a surfactant, and an acid, and/or a salt thereof, and/or an acid generator.

9. The resist underlayer film-forming composition according to claim 1, wherein the composition further contains a crosslinking agent, and an acid, and/or a salt thereof, and/or an acid generator.

10. The resist underlayer film-forming composition according to claim 1, wherein the composition further contains a surfactant, a crosslinking agent, and an acid, and/or a salt thereof, and/or an acid generator.

11. A resist underlayer film obtained by applying the resist underlayer film-forming composition according to claim 1 onto a semiconductor substrate and baking the composition.

12. A method of producing a semiconductor device, comprising:
a step of forming an underlayer film on a semiconductor substrate from the resist underlayer film-forming composition according to claim 1;
a step of forming a resist film on the formed underlayer film;
a step of forming a resist pattern by irradiating the formed resist film with light or an electron beam and developing the resist film;
a step of etching the underlayer film with the formed resist pattern; and
a step of processing the semiconductor substrate with the patterned underlayer film.

13. The method of producing a semiconductor device according to claim 12,
wherein the resist film is patterned by a nanoimprinting method or a self-assembled film.

14. A method of producing a semiconductor device, comprising:
a step of forming an underlayer film on a semiconductor substrate from the resist underlayer film-forming composition according to claim 1;
a step of forming a hard mask on the formed underlayer film;
a step of additionally forming a resist film on the formed hard mask;
a step of forming a resist pattern by irradiating the formed resist film with light or an electron beam and developing the resist film;
a step of etching the hard mask with the formed resist pattern;
a step of etching the underlayer film with the patterned hard mask;
a step of removing the hard mask; and
a step of processing the semiconductor substrate with the patterned underlayer film.

15. The method of producing a semiconductor device according to claim 14,
wherein the resist film is patterned by a nanoimprinting method or a self-assembled film.

16. The method of producing a semiconductor device according to claim 15, further comprising:
a step of forming a vapor-deposited film (spacer) on the underlayer film from which the hard mask has been removed;
a step of processing the formed vapor-deposited film (spacer) by etching;
a step of removing the underlayer film; and
a step of processing the semiconductor substrate with the spacer.

17. The method of producing a semiconductor device according to claim 16,
wherein the step of removing the hard mask is performed by etching or with an alkaline chemical solution.
